(19) United States
(12) Patent Application Publication
(10) Pub. No.: US 2016/0353616 A1
(43) Pub. Date: Dec. 1, 2016

(54) ELECTRONIC SUBASSEMBLIES FOR ELECTRONIC DEVICES

(71) Applicant: Apple Inc., Cupertino, CA (US)

(72) Inventors: Richard Hung Minh Dinh, San Jose, CA (US); Shayan Malek, San Jose, CA (US); Scott A. Myers, San Francisco, CA (US); Ronald W. Dimpflmaier, Los Gatos, CA (US)

(21) Appl. No.: 15/236,255

(22) Filed: Aug. 12, 2016

Related U.S. Application Data
(63) Continuation of application No. 14/712,024, filed on May 14, 2015.
Application No. 14/712,024 is a continuation of application No. 12/794,599, filed on Jun. 4, 2010, now abandoned.
(60) Provisional application No. 61/325,741, filed on Apr. 19, 2010.

(51) Int. Cl. H05K 9/00; H05K 1/02; H05K 3/34; H01L 23/552; H01L 23/29; H01M 2/02; H01L 23/373; H01L 23/66; H03F 3/195; H03F 3/213; G06F 1/16; H05K 1/18; H01L 23/24

(52) U.S. Cl. CPC H05K 9/0024; H05K 1/181; H05K 1/0203; H05K 3/341; H05K 1/189; H01L 23/552; H01L 23/296; H01L 23/24; H01L 23/3737; H01L 23/66; H03F 3/195; H03F 3/213; G06F 1/1656; H01M 2/026; H05K 2201/10371; H05K 2201/0162; H05K 2203/1316; H05K 2201/0116; H05K 2201/10106; H05K 2201/10121; H05K 2201/10409; H05K 2201/056; H03F 2200/451; H01L 2223/6644; H01M 2220/30

(57) ABSTRACT

Electronic devices may be provided that include mechanical and electronic components. Connectors may be used to interconnect printed circuits and devices mounted to printed circuits. Printed circuits may include rigid printed circuit boards and flexible printed circuit boards. Heat sinks and other thermally conductive structures may be used to remove excess component heat. Structures may also be provided in an electronic device to detect moisture. Integrated circuits and other circuitry may be mounted on a printed circuit board under a radio-frequency shielding can.

This application is a continuation of patent application Ser. No. 14/712,024, filed May 14, 2015, which is a continuation of patent application Ser. No. 12/794,599, filed Jun. 4, 2010, which claims the benefit of provisional patent application No. 61/325,741, filed Apr. 19, 2010, all of which are hereby incorporated by reference herein in their entireties. This application claims the benefit of and claims priority to patent application Ser. No. 14/712,024, filed May 14, 2015, patent application Ser. No. 12/794,599, filed Jun. 4, 2010, and provisional patent application No. 61/325,741, filed Apr. 19, 2010.

### BACKGROUND

This relates generally to electronic devices and components for electronic devices.

Electronic devices such as cellular telephones include numerous electronic and mechanical components. Care should be taken that these components are durable, attractive in appearance, and exhibit good performance. Tradeoffs must often be made. For example, it may be difficult to design a robust mechanical part that is attractive in appearance. The designs for attractive and compact parts and parts that perform well under a variety of operating environments also pose challenges.

It would therefore be desirable to be able to provide improved electronic devices and parts for electronic devices.

### SUMMARY

Electronic devices may be provided that include mechanical and electronic components. These components may include mechanical structures such as mounting structures and electrical components such as integrated circuits, printed circuit boards, and electrical devices that are mounted to printed circuit boards. Optical components, connectors, antennas, buttons, and other structures may be included in an electronic device.

An electronic device may have a housing. Electronic components and mechanical structures may be formed within the housing. To ensure that the electronic device is attractive, attractive materials such as metal and plastic may be used to form parts of an electronic device. Compact size may be achieved by using compact internal mounting structures. Good electrical performance may be achieved by designing an electronic device to handle a variety of thermal and electrical loads.

Connectors may be used to interconnect printed circuits and devices mounted to printed circuits. Printed circuits may include rigid printed circuit boards and flexible printed circuit boards. Heat sinks and other thermally conductive structures may be used to remove excess component heat. Cosmetic structures such as cowlings may be used to improve device aesthetics. Structures may also be provided in an electronic device to detect moisture.

### BRIEF DESCRIPTION OF THE DRAWINGS

FIG. 1 is a schematic diagram of an illustrative electronic device in accordance with an embodiment of the present invention.

FIG. 2A is a front perspective view of an illustrative electronic device that may be provided with connector mounting structures in accordance with an embodiment of the present invention.

FIG. 2B is a rear perspective view of an illustrative electronic device that may be provided with connector mounting structures in accordance with an embodiment of the present invention.

FIG. 3 is a cross-sectional side view of an electronic device that may be provided with connector mounting structures in accordance with an embodiment of the present invention.

FIG. 4 is cross-sectional side view of a conventional connector support structure in a cellular telephone.

FIG. 5 is a cross-sectional side view of an illustrative connector and surrounding portions of an electronic device showing how a cowling may be used in securing the connector within the electronic device under a glass panel or other housing structure in accordance with an embodiment of the present invention.

FIG. 6 is a perspective view of an interior portion of an electronic device showing how flexible printed circuit boards may be connected to different locations on a rigid printed circuit board using respective printed circuit board connectors and showing how cowlings may be mounted over the printed circuit board connectors to help retain the printed circuit board connectors on the rigid printed circuit board in accordance with an embodiment of the present invention.

FIG. 7 is a perspective view of an illustrative cowling structure showing how a recess may be formed on an underside portion of the cowling in accordance with an embodiment of the present invention.

FIG. 8 is a partly exploded perspective view of an illustrative printed circuit board to which several flexible printed circuits have been attached with printed circuit board connectors showing how the printed circuit board connectors may be secured using a cowling in accordance with an embodiment of the present invention.

FIG. 9 is a perspective view of an illustrative connector of the type that may be provided with a plastic insert and a moisture indicator in accordance with an embodiment of the present invention.

FIG. 10 is an exploded perspective view of a portion of a metal connector shell and a corresponding portion of a plastic insert showing how the metal shell and plastic insert may be provided with mating engagement features such as tabs and recesses in accordance with an embodiment of the present invention.

FIG. 11 is a cross-sectional side view of an illustrative connector with a plastic insert in accordance with an embodiment of the present invention.

FIG. 12 is a perspective view of an illustrative metal grounding plate structure that may be used to ensure that a connector with a plastic insert is able to properly ground mating plugs in accordance with an embodiment of the present invention.

FIG. 13 is a perspective view of a portion of an illustrative plastic connector insert showing how the insert may be provided with an opening that receives a metal pad of the type shown in FIG. 12 in accordance with the present invention.

FIG. 14 is a front view of an illustrative connector showing how a rear wall of a connector housing may be provided with an opening for a moisture indicator such as a dye-based water dot in accordance with the present invention.

FIG. 15 is a cross-sectional side view of a connector with a plastic insert showing how the rear wall of the connector may be provided with an opening that is covered by a moisture indicator in accordance with an embodiment of the present invention.

FIG. 16 is a cross-sectional side view of a connector with a metal shell and no plastic insert showing how the rear wall of the connector may be provided with an opening that is covered by a moisture indicator in accordance with an embodiment of the present invention.

FIG. 17 is a cross-sectional side view of an illustrative moisture indicator of the type that may be used to cover the rear wall opening in a connector of the types shown in FIGS. 14, 15, and 16 in accordance with an embodiment of the present invention.

FIG. 18 is a cross-sectional side view of a printed circuit board that may be provided with a threaded fastener in accordance with an embodiment of the present invention.

FIG. 19 is a cross-sectional side view of the printed circuit board of FIG. 18 following through-hole formation in accordance with an embodiment of the present invention.

FIG. 20 is a cross-sectional side view of the printed circuit board of FIG. 19 following through-hole plating operations to form conductive through-hole lining structures in accordance with an embodiment of the present invention.

FIG. 21 is a cross-sectional side view of the printed circuit board of FIG. 20 following removal of protruding portions of the conductive through-hole structures on the rear surface of the printed circuit board in accordance with an embodiment of the present invention.

FIG. 22 is a cross-sectional side view of the printed circuit board of FIG. 21 showing how a fastener may be soldered into the through-hole and how conductive rear-surface traces can be formed under the fastener in accordance with an embodiment of the present invention.

FIG. 23 is a cross-sectional side view of a printed circuit board in which a fastener mounting hole has been formed in accordance with an embodiment of the present invention.

FIG. 24 is a cross-sectional side view of the printed circuit board of FIG. 23 showing how the fastener mounting hole may be filled with metal in accordance with an embodiment of the present invention.

FIG. 25 is a cross-sectional side view of the printed circuit board of FIG. 24 following removal of a central portion of the metal to form a solder pad ring in accordance with an embodiment of the present invention.

FIG. 26 is a cross-sectional side view of the printed circuit board of FIG. 25 showing how a fastener such as a threaded nut may be soldered onto the solder pad ring of FIG. 25 in accordance with an embodiment of the present invention.

FIG. 27 is a cross-sectional side view of a printed circuit board formed from a first board layer having a hole and a second board layer without a hole in accordance with an embodiment of the present invention.

FIG. 28 is a cross-sectional side view of a printed circuit board of the type shown in FIG. 27 showing how a fastener such as a threaded nut may be soldered onto a solder pad ring that is formed around the periphery of the hole of FIG. 27 in accordance with an embodiment of the present invention.

FIG. 29 is a cross-sectional side view of a printed circuit board into which a fastener such as a threaded nut has been soldered showing how the nut may be provided with bevels to prevent the nut from catching on sloped sidewall portions of the hole in the printed circuit board in accordance with an embodiment of the present invention.

FIG. 30 is a perspective view of a threaded fastener that may be mounted to a printed circuit board in accordance with an embodiment of the present invention.

FIG. 31 is a perspective view of an illustrative knurled fastener that may be mounted to a printed circuit board in accordance with an embodiment of the present invention.

FIG. 32 is a cross-sectional side view of an illustrative fastener that has partially plated solder-philic sidewalls in accordance with an embodiment of the present invention.

FIG. 33 is a cross-sectional side view of an illustrative fastener of the type shown in FIG. 32 showing how the partially plated solder-philic sidewalls of the fastener may be used to inhibit excessive upwards solder flow when attaching the fastener to a printed circuit board in accordance with an embodiment of the present invention.

FIG. 34 is a cross-sectional side view of an illustrative fastener with selectively coated solder-philic sidewalls and an engagement feature such as an annular protrusion in accordance with an embodiment of the present invention.

FIG. 35 is a perspective view of an illustrative fastener with spider leg engagement features and a partial coating of a solder-philic material in accordance with an embodiment of the present invention.

FIG. 36 is a cross-sectional side view of an illustrative fastener with spider leg engagement features and a partial coating of a solder-philic material mounted to a printed circuit board in accordance with an embodiment of the present invention.

FIG. 37 is a perspective view of a radio-frequency shielding can mounted to a substrate such as a printed circuit board in accordance with an embodiment of the present invention.

FIG. 38 is a side view of a radio-frequency shielding can of the type shown in FIG. 37 showing how the can may be provided with a frame and a lid and may be attached to a standoff or other threaded fastener mounted in a printed circuit board in accordance with an embodiment of the present invention.

FIG. 39 is a perspective view of a portion of a frame for a radio-frequency shielding can showing how the frame may have a vertical leg that mates with a corresponding pad on a printed circuit board and may have a portion with a U-shaped opening that facilitates mounting of the frame to the printed circuit board with threaded fasteners in accordance with an embodiment of the present invention.

FIG. 40 is a cross-sectional side view of a threaded fastener mounted to a printed circuit board in accordance with an embodiment of the present invention.

FIG. 41 is an exploded perspective view of illustrative radio-frequency shielding can structures, a printed circuit board, and associated circuitry that may be shielded using the radio-frequency shielding can structures in accordance with an embodiment of the present invention.

FIG. 42 is an exploded perspective view of a portion of a radio-frequency shielding can and an overlapping component that are being mounted to a printed circuit board with common threaded fasteners in accordance with an embodiment of the present invention.

FIG. 43 is a side view of a portion of a radio-frequency shielding can and a component such as a speaker that are mounted to a substrate such as a printed circuit board using a common mounting structure such as mating male and female threaded fasteners in accordance with an embodiment of the present invention.

FIG. 44 is a cross-sectional diagram of a set of battery electrodes for a battery pack in accordance with an embodiment of the present invention.

FIG. 45 is a perspective view of a jelly-roll electrode structure for a battery in accordance with an embodiment of the present invention.

FIG. 46 is a perspective view showing how a jelly-roll electrode structure may be wrapped in a battery pouch in a conventional battery.

FIG. 47 is an end view of a conventional battery of the type shown in FIG. 46 after the battery pouch has been sealed but before the battery pouch edges have been folded and secured.

FIG. 48 is a cross-sectional end view of a conventional battery pack in which the edges of the battery pouch have been folded and secured to the battery pouch using strips of polyimide tape.

FIG. 49 is a side view of an illustrative tool that may be used in manufacturing battery pouch material for a battery pack in accordance with an embodiment of the present invention.

FIG. 50 is a perspective view of a battery pack in accordance with the present invention before artwork has been printed on the surface of the battery pouch and before the edges of the battery pouch have been folded and secured.

FIG. 51 is a perspective view of a battery pack of the type shown in FIG. 50 after information has been printed on the battery pouch and before the battery pouch edges have been folded and secured in accordance with an embodiment of the present invention.

FIG. 52 is a top view of an illustrative layout that may be used for a polymer layer with a rectangular window opening that may be used for securing folded battery pouch edges in a battery pack in accordance with an embodiment of the present invention.

FIG. 53 is a cross-sectional perspective view of a battery pack in accordance with an embodiment of the present invention.

FIG. 54 is a flow chart of illustrative steps involved in forming a battery pack such as the battery pack of FIG. 53 in accordance with an embodiment of the present invention.

FIG. 55 is a perspective view of a panel of rigid printed circuit board material from which multiple printed circuit boards are being produced in accordance with an embodiment of the present invention.

FIG. 56 is a top view of a printed circuit board that is temporarily secured within a panel of printed circuit board material using break out tabs in accordance with an embodiment of the present invention.

FIG. 57 is a perspective view of a portion of a printed circuit board in the vicinity of a broken break out tab in accordance with an embodiment of the present invention.

FIG. 58 is a cross-sectional side view of a conventional printed circuit board and flex circuit arrangement showing how the flex circuit bend radius may be difficult to control and how the flex circuit may be exposed to rough printed circuit board edges.

FIG. 59 is an exploded perspective view of a portion of a printed circuit board and an associated member such as an elastomeric bumper member that may be mounted to the edge of the printed circuit board in accordance with an embodiment of the present invention.

FIG. 60 is a cross-sectional side view of an electronic device containing electronic components that have been interconnected by a flex circuit and having a printed circuit board with an edge covered by a bumper in accordance with an embodiment of the present invention.

FIG. 61 is a flow chart of illustrative steps involved in forming an electronic device having a printed circuit board with a bumper and a flex circuit of the type shown in FIG. 60 in accordance with an embodiment of the present invention.

FIG. 62 is a cross-sectional side view of an illustrative trim structure to which a camera module and flash unit have been mounted in accordance with an embodiment of the present invention.

FIG. 63 is a top view of a trim structure of the type shown in FIG. 62 in accordance with an embodiment of the present invention.

FIG. 64 is a cross-sectional side view of an illustrative trim structure, camera module, and flash unit mounted within an electronic device under a display cover glass and lens in accordance with an embodiment of the present invention.

FIG. 65 is a cross-sectional side view of an illustrative electronic device that may contain shielded circuitry in accordance with an embodiment of the present invention.

FIG. 66 is a cross-sectional side view of a conventional radio-frequency shielding can that contains thermally conductive foam to assist in dissipating heat from electrical components.

FIG. 67 is a cross-sectional side view of an illustrative radio-frequency shielding structure that contains conformal thermally conductive structures formed from multiple materials and that contains an optional layer of thermally conductive grease to help dissipate heat from electrical components within the shielding structure in accordance with an embodiment of the present invention.

FIG. 68 is a cross-sectional side view of an illustrative radio-frequency shielding structure that contains a relatively soft thin conformal thermally conductive material that underlies additional conformal thermally conductive material and that dissipates heat from electrical components within the shielding structure in accordance with an embodiment of the present invention.

FIG. 69 is a cross-sectional view of an illustrative radio-frequency shielding structure or other package in a partially assembled state showing how a printed circuit board mounting tool may be used to mount electrical components on a printed circuit board that will form part of a finished radio-frequency shielded package in accordance with an embodiment of the present invention.

FIG. 70 is a cross-sectional view of an illustrative radio-frequency shielding structure or other package of the type shown in FIG. 69 as thermally conductive material is being introduced into the structure using a filler dispensing tool in accordance with an embodiment of the present invention.

FIG. 71 is a cross-sectional view of an illustrative radio-frequency shielding structure or other package of the type shown in FIGS. 69 and 70 as a heating and molding tool is being used to form a finished structure in accordance with an embodiment of the present invention.

FIG. 72 is a flow chart of illustrative steps involves in forming radio-frequency shielding structures with conformal thermally conductive material layers in accordance with an embodiment of the present invention.

### DETAILED DESCRIPTION

Electronic devices can be provided with mechanical and electronic components such as optical parts, camera mounting structures, cowlings and other cosmetic parts, printed circuits and support structures, thermal management structures, buttons, vibrators, and other mechanical and electrical structures.

Electronic devices that may be provided with these components include desktop computers, computer monitors, computer monitors containing embedded computers, wireless computer cards, wireless adapters, televisions, set-top boxes, gaming consoles, routers, portable electronic devices such as laptop computers, tablet computers, and handheld devices such as cellular telephones and media players, and small devices such as wrist-watch devices, pendant devices, headphone and earpiece devices, and other wearable and miniature devices. Portable devices such as cellular telephones, media players, and other handheld electronic devices are sometimes described herein as an example.

Printed circuit board connectors may be used to connect printed circuit boards such as flexible printed circuits to a rigid printed circuit board. A cowling structure may be mounted to the rigid printed circuit board so as to overlap one or more of the printed circuit board connectors.

An electronic device may have a connector such as a 30-pin connector with a rectangular opening. The connector may have a metal shell. Metal ground plates may be welded to the interior surfaces of the metal shell. A cosmetic dielectric insert may line the metal shell.

Printed circuit board may be provided with fasteners such as threaded nuts. Solder pad structures may be provided for solder used to attach fasteners.

To block radio-frequency signals that may cause interference, the integrated circuits and other components may be enclosed within radio-frequency shielding structures such as radio-frequency shielding cans.

A battery may be provided with positive and negative electrode layers and a separator layer that are used to form jelly-roll-type battery electrode structures. The jelly-roll electrode structures may be encased within a battery pouch having regulatory artwork.

During manufacturing, multiple printed circuit boards may be formed from a common panel of printed circuit board material. Break out tabs may be used to retain a printed circuit board within a panel of printed circuit board material during manufacturing. Flex circuits may be routed over elastomeric bumper members that are mounted over the edges of printed circuit boards.

Camera and flash trim structures may be provided that help align camera modules and flash components with respect to each other when mounted within an electronic device. A trim structure may be formed from materials that dissipate heat, allowing the trim to serve as an integral heat sink.

To ensure adequate thermal dissipation, a conformal coating of a thermally conductive filler such as silicone filled with thermally conductive particles may be deposited over electrical components in radio-frequency shielding cans.

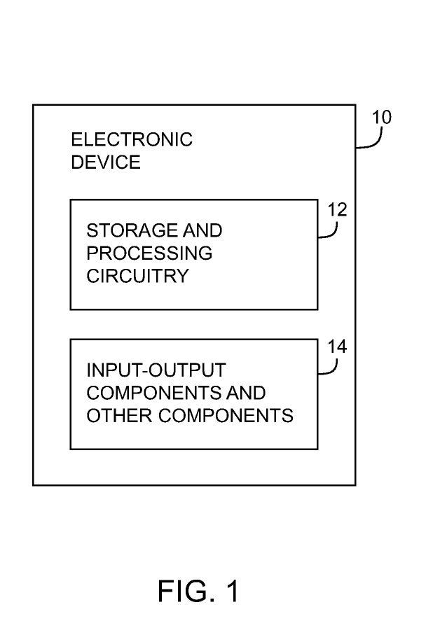

An illustrative electronic device that may be provided with mechanical and electrical features to improve performance, aesthetics, robustness, and size is shown in FIG. 1. As shown in FIG. 1, device 10 may include storage and processing circuitry 12. Storage and processing circuitry 12 may include one or more different types of storage such as hard disk drive storage, nonvolatile memory (e.g., flash memory or other electrically-programmable-read-only memory), volatile memory (e.g., static or dynamic random-access-memory), etc. Storage and processing circuitry 12 may be used in controlling the operation of device 10. Processing circuitry in circuitry 12 may be based on processors such as microprocessors, microcontrollers, digital signal processors, dedicated processing circuits, power management circuits, audio and video chips, and other suitable integrated circuits.

With one suitable arrangement, storage and processing circuitry 12 may be used to run software on device 10, such as internet browsing applications, voice-over-internet-protocol (VOIP) telephone call applications, email applications, media playback applications, operating system functions, antenna and wireless circuit control functions, etc. Storage and processing circuitry 12 may be used in implementing suitable communications protocols. Communications protocols that may be implemented using storage and processing circuitry 12 include internet protocols, wireless local area network protocols (e.g., IEEE 802.11 protocols—sometimes referred to as Wi-Fi®), protocols for other short-range wireless communications links such as the Bluetooth® protocol, protocols for handling cellular telephone communications services, etc.

Input-output devices 14 may be used to allow data to be supplied to device 10 and to allow data to be provided from device 10 to external devices. Examples of input-output devices 14 that may be used in device 10 include display screens such as touch screens (e.g., liquid crystal displays or organic light-emitting diode displays), buttons, joysticks, click wheels, scrolling wheels, touch pads, key pads, keyboards, microphones, speakers and other devices for creating sound, cameras, sensors, etc. A user can control the operation of device 10 by supplying commands through devices 14 or by supplying commands to device 10 through an accessory that communicates with device 10 through a wireless or wired communications link. Devices 14 or accessories that are in communication with device 10 through a wired or wireless connection may be used to convey visual or sonic information to the user of device 10. Device 10 may include connectors for forming data ports (e.g., for attaching external equipment such as computers, accessories, etc.).

Electronic devices such as cellular telephones often use internal connectors. For example, printed circuit board connectors may be used to interconnect flexible and rigid printed circuit boards. Printed circuit board connectors are at risk of becoming disconnected in the event that a user inadvertently drops an electronic device. To help reduce the risk of dislodging printed circuit board connectors, the board connectors in some electronic devices are secured using foam. In a typical electronic device with a plastic housing wall, for example, a layer of compressed foam may be placed between the plastic housing wall and a printed circuit board connector. The compressed foam helps to hold the printed circuit board connector in place.

Although conventional connector mounting arrangements such as these may be satisfactory in some circumstances, tolerances may be poor. If a connector is manufactured or assembled with an undesirable tilt, for example, a corresponding tilt may be produced in the foam. During a drop event, this arrangement may not be sufficiently secure. As a result, the connector may become disconnected.

It would therefore be desirable to be able to provide electronic devices and connectors with improved connector mounting arrangements.

The electrical components in an electronic device may include integrated circuits and other devices and be mounted on a printed circuit board. The printed circuit board on which the electrical components are mounted may be a rigid printed circuit board.

Printed circuit board connectors may be used to connect printed circuit boards such as flexible printed circuits to the rigid printed circuit board. A printed circuit board connector may have mating first and second portions. The first portion may be mounted to the flexible printed circuit board. The second portion may be connected to the flex circuit. Mating pins in the first and second portions may form electrical connections between the first and second portions of the connector.

A cowling structure may be mounted to the rigid printed circuit board so as to overlap one or more of the printed circuit board connectors. A compressed member such as a layer of foam may be interposed between the cowling structure and the printed circuit board connector to help hold the first and second portions of the printed circuit board connector together.

The electronic device may have a housing wall such as a planar housing member. The planar housing member may have a layer of glass and a layer of metal. The layer of metal may rest against a planar surface of the cowling structure.

In accordance with an embodiment, apparatus is provided that includes a first printed circuit board, a second printed circuit board, a printed circuit board connector having mating first and second portions, wherein the first portion is connected to the first printed circuit board and wherein the second portion is connected to the second printed circuit board, and a cowling disposed over the printed circuit board connector that assists in holding the first and second portions of the printed circuit board connector together.

In accordance with another embodiment, an apparatus is provided wherein the cowling includes metal.

In accordance with another embodiment, an apparatus is provided wherein the second printed circuit board includes a flex circuit.

In accordance with another embodiment, an apparatus is provided that also includes compressed foam between the cowling and the printed circuit board connector.

In accordance with another embodiment, an apparatus is provided that also includes foam on the printed circuit board connector, wherein the cowling has base portions connected to the first printed circuit board, vertical sidewall portions, and a planar upper portion and wherein the planar upper portion compresses the foam towards the printed circuit board connector.

In accordance with another embodiment, an apparatus is provided that also includes a stiffener interposed between the foam and the printed circuit board connector, wherein the second printed circuit board includes a flex circuit.

In accordance with another embodiment, an apparatus is provided that also includes a circuit that is electrically connected to the cowling, wherein the cowling is formed from metal and has a recess that receives at least part of the foam.

In accordance with an embodiment, an electronic device is provided that includes a printed circuit board, a circuit board connector connected to the printed circuit board, a cowling that has a first portion that is connected to the printed circuit board and a second portion that covers the circuit board connector, and a compressed member that is interposed between the second portion of the cowling and the circuit board connector and that generates a restoring force that holds the circuit board connector together.

In accordance with another embodiment, an electronic device is provided wherein the compressed member includes foam.

In accordance with another embodiment, an electronic device is provided wherein the second portion of the cowling includes a planar cowling portion.

In accordance with another embodiment, an electronic device is provided that also includes a planar rear housing member having an inner surface, wherein the planar cowling portion has an outer surface that rests against the inner surface of the planar rear housing member.

In accordance with another embodiment, an electronic device is provided wherein the cowling includes metal and wherein the circuit board connector includes a printed circuit board connector having mating first and second printed circuit board connector portions.

In accordance with another embodiment, an electronic device is provided wherein the printed circuit board connector is one of a plurality of printed circuit board connectors on the printed circuit board each of which connects a respective flex circuit to the printed circuit board and wherein the compressed member includes one of a plurality of compressed members each of which is interposed between the second portion of the cowling and a respective one of the plurality of printed circuit board connectors to hold that printed circuit board connector together.

In accordance with another embodiment, an electronic device is provided that also includes a planar rear housing member having a glass layer and having an inner surface, wherein the planar cowling portion has an outer surface against which the inner surface of the planar rear housing member rests.

In accordance with another embodiment, an electronic device is provided wherein the planar rear housing member includes a layer of metal attached to the glass layer, wherein the inner surface is formed by a surface of the layer of metal.

In accordance with another embodiment, an electronic device is provided that also includes a flex circuit that is connected to the printed circuit board with the circuit board connector.

In accordance with an embodiment, an apparatus is provided that includes a printed circuit board connector having mating first and second portions, a flex circuit connected to the first portion of the printed circuit board connector, a rigid printed circuit board connected to the second portion of the printed circuit board connector, a bracket that is mounted to the rigid printed circuit board, and a compressed member between the printed circuit board connector and the bracket that holds the mating first and second portions together.

In accordance with another embodiment, an apparatus is provided wherein the compressed member includes foam and wherein the bracket includes metal.

In accordance with another embodiment, an apparatus is provided that also includes integrated circuits mounted on the rigid printed circuit board.

In accordance with another embodiment, an apparatus is provided that also includes a rear housing member having a glass layer and metal layer, wherein the rear housing member rests against the bracket.

In accordance with these embodiments, electronic devices often contain large numbers of electrical components. For example, electronic devices such as cellular telephones may contain touch screen displays, cameras, microprocessors, batteries, audio integrated circuits, connectors, switches, radio-frequency transceiver circuits and processors, capacitors, resistors, and other discrete components and integrated circuits. To ensure proper operation of an electronic device, these electrical components must be securely mounted within the electronic device and must be electrically interconnected.

Electrical components may be mounted to rigid printed circuit boards. A rigid printed circuit board may, for example, be formed from a dielectric substrate such as a substrate of fiberglass-filled epoxy. The printed circuit board substrate may contain one or more layers of conductive traces. Connectors, integrated circuits, and other components may be soldered to contact pads on the surface of the printed circuit board substrate.

Some printed circuit boards are flexible. For example, some printed circuit boards are formed from flexible polymer sheets such as flexible sheets of polyimide. Printed circuit boards of this type are sometimes referred to as “flex circuits.” Other printed circuit boards (so-called “rigid flex”) contain both rigid and flexible portions.

Electrical components may be soldered and otherwise connected to the conductive traces and associated contact pads on the printed circuit boards in an electronic device. To accommodate desired levels of functionality, it may be desirable to use multiple printed circuit boards in a device. The electrical components on different printed circuit boards may be connected to each other using flex circuit cables, wires, wire bundles, coaxial cables, traces on printed circuit boards, and other suitable conductive paths. To facilitate reliable assembly and to ensure that large numbers of electrical connections can be reliably made, printed circuit board connectors have been developed.

Printed circuit board connectors are available in a variety of form factors. For example, some board-to-board connectors may be well suited to forming connections between respective pairs of parallel rigid printed circuit boards. As another example, some printed board connectors may be well suited to forming connections between flexible printed circuits and rigid printed circuit boards. Yet other printed circuit board connectors may be used to connect flex circuits to flex circuits or to connect particular types of components to a rigid printed circuit board or flex circuit. Connectors such as these may be implemented using low insertion force (LIF) and zero insertion force (ZIF) configurations. Minimal size is often advantageous, so the connectors may be implemented using miniature pins (contacts), small housings, and other structures that ensure that the connectors do not consume too much volume within a product. These different types of printed circuit board connectors are sometimes referred to herein as printed circuit board connectors or board connectors.

Electronic devices are sometimes exposed to shock during use. For example, a user of a handheld electronic device such as a cellular telephone may inadvertently drop the device. During a drop event or other shock-inducing event, printed circuit board connectors are subjected to stress. If the stress is too great, the printed circuit board connectors may become dislodged. A disconnected connector could cause an electronic device to stop working properly, so care should be taken to ensure that connectors are well secured.

With one suitable arrangement, which is described herein as an example, a connector securing structure such as a cowling may be used to help hold a connector in place on a printed circuit board. The cowling may, for example, be formed from a material such as metal. A metal cowling may extend over a connector that is mounted on a printed circuit board. Foam and other structures may also be interposed between the cowling and the printed circuit board. Mounting a printed circuit board connector in this way may help ensure that the connector will not become dislodged during a drop event and may help improve manufacturing tolerances by reducing or eliminating reliance on accurate positioning of housing walls relative to internal connector structures.

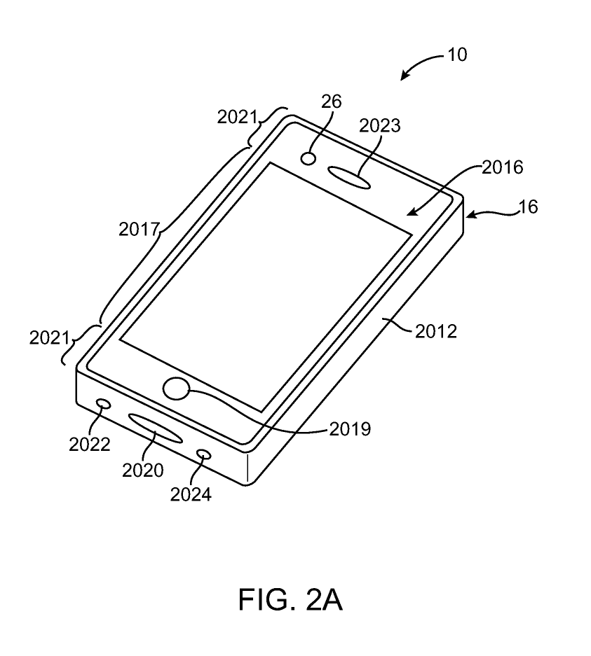

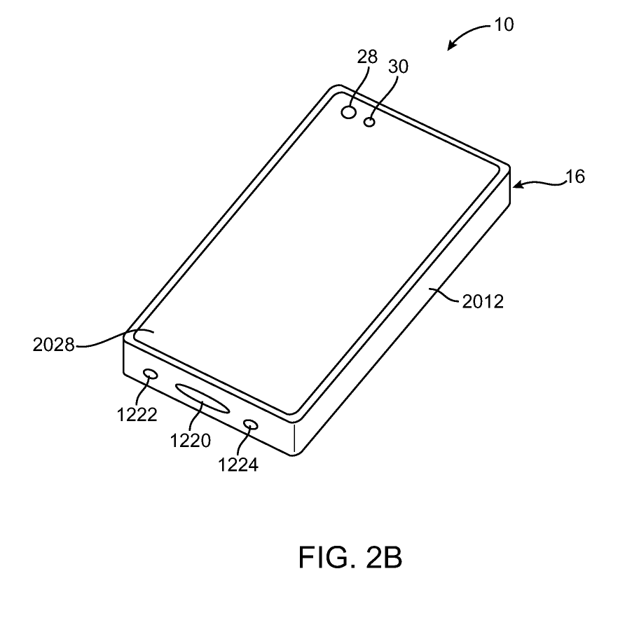

Cowling-based printed circuit board connector mounting arrangements may be used in cellular telephones, music players and other media players, portable computers, tablet computers, ultraportable computers, desktop computers, consumer electronics equipment, or other suitable stationary and portable electronic devices. An illustrative electronic device that may use this type of connector mounting arrangement is shown in FIG. 2.

Illustrative electronic device 10 of FIG. 2 may be, for example, a cellular telephone, media player, handheld device, portable computer, etc. A shown in FIG. 2, device 10 may have housing 16. Housing 16, which is sometimes referred to as a case, may be formed of any suitable materials including, plastic, glass, ceramics, metal, or other suitable materials, or a combination of these materials. In some situations, housing 16 or portions of housing 16 may be formed from a dielectric or other low-conductivity material. Housing 16 or portions of housing 16 may also be formed from conductive materials such as metal.

The housing protects the internal components and may help keep the internal components in their assembled position within the device 10. The housing 16 may also help form part of the outer peripheral look and feel of the device 10, i.e., the ornamental appearance. The housing can be widely varied. For example, the housing can include a variety of external components that utilize a variety of different materials.

With one suitable arrangement, which is sometimes described herein as an example, the sidewalls 2012 of housing 16 are formed from a material such as plastic or metal (e.g., a metal bezel or metal band that surrounds the periphery of device 10), whereas the front panel 2016 and rear panel 2028 of device 10 are formed from planar transparent structures. In some cases, the front and/or rear panels may include an outer transparent layer (e.g., cover glass). Front panel 2016 of device 10 may be, for example, a planar cover glass layer or other glass structure associated with a display such as a touch screen display. Front panel 2016 may cover some or substantially all of the front of device 10. Rear panel 2028 may be, for example, a planar cosmetic glass layer, a glass layer through which visible indicators such as status light-emitting-diodes or back-lit icons are displayed, a layer of touch screen glass that forms part of a rear-mounted touch screen, other display structures, etc. Rear panel 2028 may cover some or substantially all of the planar rear surface of device 10. In one embodiment, the panels 2016 and 2028 may be removable. For example, the rear panel 2028 may be detached from the rest of the housing in order to provide internal access to the electronic device. In one example, the rear panel is made to slide relative to the rest of the housing between a closed position, enclosing the device, and an open position, providing an opening.

An illustrative configuration in which a display is mounted on the front surface 2016 of device 10 is shown in FIG. 2A. Display 2016 may be a liquid crystal display (LCD), an organic light emitting diode (OLED) display, an electronic ink display, a plasma display, or any other suitable display. The outermost surface of display 2016 may be formed from a layer of glass (sometimes referred to as the display's cover glass). Display 2016 may also have interior layers (e.g., a capacitive touch sensor array for providing display 2016 with touch sensing capabilities, a layer of thin-film transistors for controlling the image pixels in the display, etc.).

Display 2016 may have a central active region such as active region 2017 and inactive end regions such as regions 2021. To hide interior portions of device 10 from view, the underside of display 2016 (e.g., the cover glass of the display) in inactive regions 2021 may be coated with an opaque substance such as black ink (as an example). The inner surface of the rear surface glass layer may also be covered with an opaque substance such as black ink.

An opening may be formed in one of regions 2021 of the display cover glass to accommodate button 2019. An opening such as opening 2023 may also be formed in one of regions 2021 (e.g., to form a speaker port). The end portions of housing 2012A (i.e., the peripheral metal band or other housing sidewall structures) may be provided with openings such as openings 2022 and 2024 for microphone and speaker ports and opening 2020 for an input-output data port. An opening may be formed in one of the regions 2021 for front-facing camera 26.

FIG. 2B is rear view of device 10. Device 10 may have a rear-facing camera 28. Device 10 may have a camera flash (camera light) such as camera flash 30.

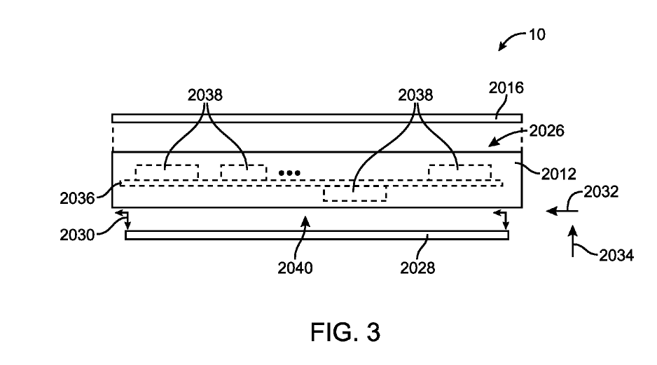

An exploded cross-sectional side view of an illustrative configuration that may be used for device 10 is shown in FIG. 3. As shown in FIG. 3, device 10 may have a band-shaped peripheral housing sidewall portion 2012. Band 2012 may, for example, be a rectangular ring formed from a material such as plastic or metal. Mounting structures such as printed circuit board 2036 may be mounted within device 10. Components 2038 may be mounted on one or both sides of printed circuit board 2036. Multiple printed circuit boards 2036 may be included in device 10, if desired.

Components such as components 2038 may include integrated circuits, discrete components, switches, printed circuit board connectors, data port connectors, batteries, antennas, displays, microphones, speakers, etc. Front member 2016 may be attached to front side 2026 of device 10. Rear member 2028 may be attached to rear side 2040 of device 10. Front member 2016 and rear member 2028 may be formed from plastic, metal, glass, ceramics, composites, other suitable materials, or combinations of these materials.

With one suitable arrangement, which is sometimes described herein as an example, front member 2016 may be formed from one or more layers of glass. For example, front member 2016 may include a touch screen display with a layer of cover glass that is mounted to housing portion 2012. Rear member 2028 may also be formed from one or more layers of glass. For example, rear member 2028 may be formed from a rectangular layer of glass that fits within a recess in housing portion 2012. When attached to housing 2012, members 2016 and 2028 may be considered to form part of housing 2012.

Members 2016 and 2028 may be attached to housing 2012 using adhesive, screws, clips, other fasteners, etc. During assembly, it may be desirable to use a sliding motion when attaching rear member 2028. For example, it may be desirable to move rear member along path 2030. Initially, member 2028 may be moved in direction 2034. After moving member 2028 in direction 2034, member 2028 may be slid along direction 2032. This type of compound pressing and sliding motion may be used to attach member 2028 to device 10 or other suitable attachment techniques may be used to attach member 2028.

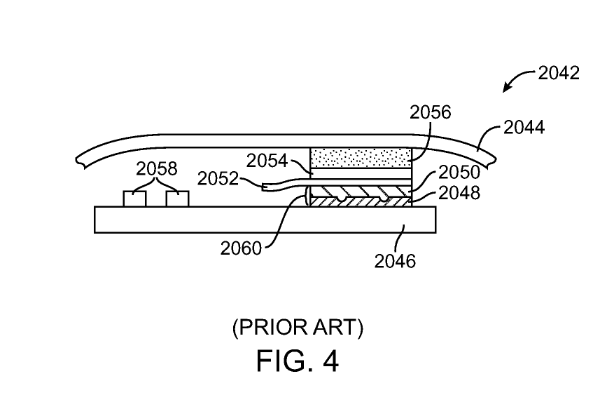

FIG. 4 is a cross-sectional end view of a conventional mounting arrangement for a printed circuit board connector in a cellular telephone. Cellular telephone 2042 of FIG. 4 contains printed circuit board 2046. Integrated circuits 2058 are soldered to printed circuit board 2046. Printed circuit board connector 2060 is also mounted on printed circuit board 2046. Printed circuit board connector 2060 has two portions. Connector portion 2048 is soldered to printed circuit board 2048. Connector portion 2050 is connected to flexible printed circuit 2052. Connector portions 2048 and 2050 have mating pins. When these portions of connector 2060 are held together as shown in FIG. 4, connector 2060 forms an electrical connection between the conductive traces on flexible printed circuit 2052 and the conductive traces and integrated circuit 2058 on printed circuit board 2046.

Stiffener 2054 may be attached to flexible printed circuit 2052 to help even the load on flexible printed circuit 2052 and avoid solder joint damage. To help hold connector portions 2048 and 2050 together, foam 2056 is interposed between plastic cellular telephone housing wall 2044 and stiffener 2054. When mounted in device 2042 in this way, foam 2056 is compressed and exerts a downward force on connector portion 2050. This downward force holds connector 2050 to connector 2048 in an effort to prevent connector 2060 from becoming disconnected.

While satisfactory in some situations, the conventional arrangement of FIG. 4 places strict demands on the tolerances for connector 2060. If connector 2060 is, for example, slightly tilted, foam 2056 will become tilted and may not rest evenly against housing wall 2044. This may cause connector to come apart during a drop event. It is generally difficult to compress foam 2056 properly without tightly controlling the distance between the inner surface of housing wall 2044 and stiffener 2054. The size, shape, and locations of housing wall 2044 can fluctuate due to manufacturing variations, so tight control of this distance may not always be practical.

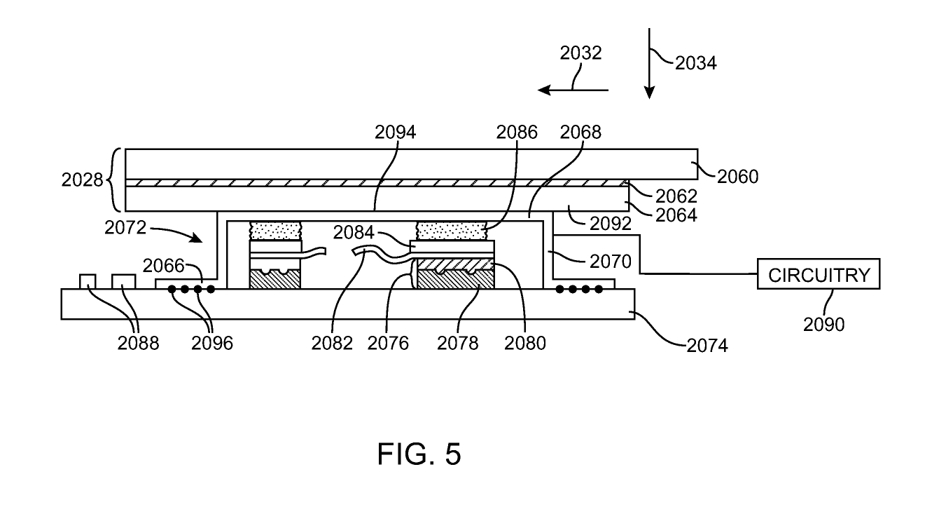

To address concerns such as these, a cowling structure may be used in mounting printed circuit board connectors in device 10 of FIG. 2. An illustrative cowling-based printed circuit board connector mounting arrangement that may be used in device 10 is shown in FIG. 5. As shown in FIG. 5, electrical components 2088 such as integrated circuits may be mounted on printed circuit board 2074. Printed circuit board 2074 may be, for example, a rigid printed circuit board such as a printed circuit board formed from fiberglass-filled epoxy.

Printed circuit board connectors such as printed circuit board connector 2076 may be mounted on printed circuit board 2074. Printed circuit board connector 2076 may be, for example, a flex circuit connector of the low insertion force or zero insertion force type. Connector 2076 may have a lower portion such as lower portion 2078 that is mounted to printed circuit board 2074 using solder or conductive adhesive and may have an upper portion such as portion 2080 that is connected to flex circuit 2082 (e.g., using pins or other contacts, springs, conductive adhesive, solder, etc.). Lower connector portion 2078 and mating upper connector portion 2080 may have mating pins that come into contact when connector portions 2078 and 2089 are connected together to form connector 2076. When connected in this way, connector portion 2080 may be used to connect flex circuit 2082 to connector portion 2078 and board 2074.

A stiffener such as stiffener 2084 may be attached to flex circuit 2082 (e.g., using pressure sensitive adhesive). Stiffener 2084 may be formed from plastic, metal, glass, ceramic, other suitable materials, or combinations of these materials. When attached to flex circuit 2082, stiffener 2084 may help prevent damage to electrical connections associated with connector 2076 (e.g., solder joints).

Cowling 2072 may be used in holding connector 2076 together. Cowling 2072 may be formed from metal, plastic, glass, ceramics, composites, other suitable materials, or combinations of these materials. In a typical configuration, cowling 2072 may be formed from metal. Cowling 2072 may have flanged base portions 2066 that lie parallel to the surface of printed circuit board 2074, vertical sidewalls such as sidewall 2070, and planar top portion 2068. Cowling 2072 may form a bracket, a can (e.g., a closed bracket with four perpendicular walls 2070), or may have other suitable shapes.

As shown in the illustrative configuration of FIG. 5, cowling 2072 may be attached to printed circuit board 2074 using bonds 2096. Bonds 2096 may be formed from adhesive (e.g., pressure sensitive adhesive, epoxy, or other suitable adhesive materials), solder joints, welds, press fit connections, fasteners, or other suitable attachment mechanisms. The thickness of base portions 2066 and the other portions of cowling 2072 may be, for example, less than 1 mm, less than 0.5 mm, less than 0.4 mm, 0.4 mm to 0.2 mm, etc.

When cowling 2072 is attached to printed circuit board 2074 as shown in FIG. 5, planer structure 2068 of cowling 2072 may press inwards on foam 2086 in direction 2034. This compresses foam 2086. Once compressed, foam 2086 exhibits a restoring force in direction 2034 that presses connector portion 2080 in direction 2034 against connector portion 2078. As a result, both parts of connector 2076 are held together, reducing the possibility that connector 2076 will become fully or partly disconnected during a shock (e.g., from a drop event). By ensuring no part of connector 2076 is dislodged by a drop event, the presence of cowling 2072 and the force produced from compressed foam 2086 may improve the robustness of device 10. Foam 2086 may be formed from a block of polymer foam, a piece of solid flexible elastomer such as silicone, or any other flexible and compressible material that, when compressed, generates a restoring force that holds connector 2076 together. Connector 2076 may be used to connect components to a printed circuit board, may be used to connect a battery to a printed circuit board, may be part of a battery, may be a board-to-board connector, may be a low insertion force connector, may be a zero insertion force connector, or may be any other suitable connector or electrical component.

As shown in FIG. 5, planar rear member 2028 (or other suitable front or rear portions of housing 2012) may rest against cowling 2072. Planar rear member 2028 may be formed from a layer of glass such as glass layer 2060. Some or all of the inner surface of glass layer 2060 may be provided with a metal layer such planar metal layer 2064. Metal layer 2064 may help provide additional strength to glass layer 2060 (e.g., in the region covering cowling 2072). Adhesive such as adhesive 2062 may be used in attaching metal layer 2064 to glass layer 2060 (as an example).

With an arrangement of the type shown in FIG. 5, inner surface 2092 of metal layer 2064 may lie parallel to outer surface 2094 of planar portion 2068 of cowling 2072. This allows cowling to rest against glass 2060 and member 2028. During assembly, rear member 2028 may be moved in direction 2032. When layers 2064 and 2068 are implemented as planar members formed of suitable materials (e.g., metal, rigid plastic, etc.) surfaces 2092 and 2094 will not catch on each other during movement of member 2028 in direction 2032. Moreover, because foam 2086 is prevented from touching inner surface 2092 of member 2028, movement of member 2028 in direction 2032 will not disrupt the proper positioning of foam 2086.

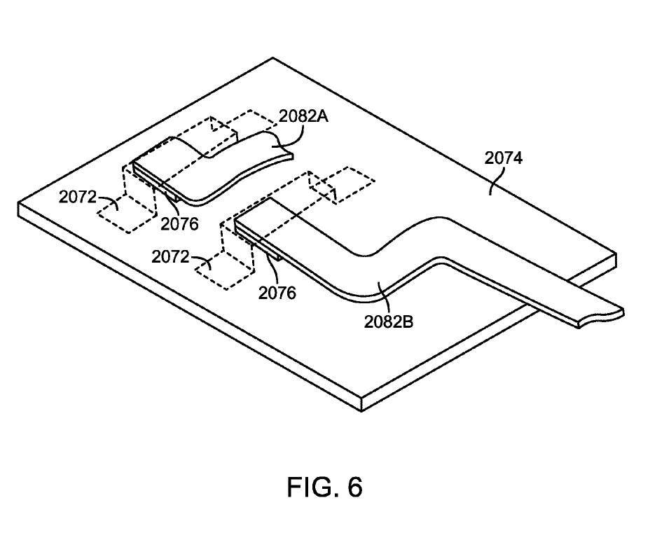

If desired, multiple cowlings may be placed on a single printed circuit board. This type of arrangement is shown in FIG. 6. As shown in FIG. 6, printed circuit board connectors 2076 may be used to physically and electrically connect flex circuits 2082A and 2082B to printed circuit board 2074. Dashed lines 2072 show where bracket-shaped cowlings and foam may be provided to help secure connectors 2076. As described in connection with FIG. 5, cowlings may be connected to printed circuit board 2074 using bonds formed from adhesive (e.g., pressure sensitive adhesive, epoxy, or other suitable adhesive materials), solder joints, welds, press fit connections, fasteners, or other suitable attachment mechanisms.

In some electronic devices, radio-frequency circuitry or other circuitry (shown as circuitry 2090 of FIG. 6) may be electrically coupled to cowling 2072. Cowling 2072 may therefore serve both as a mechanical support for printed circuit board connector 2076 and as a portion of a ground plane, antenna resonating element, radio-frequency shield, or other electrical structure in device 10.

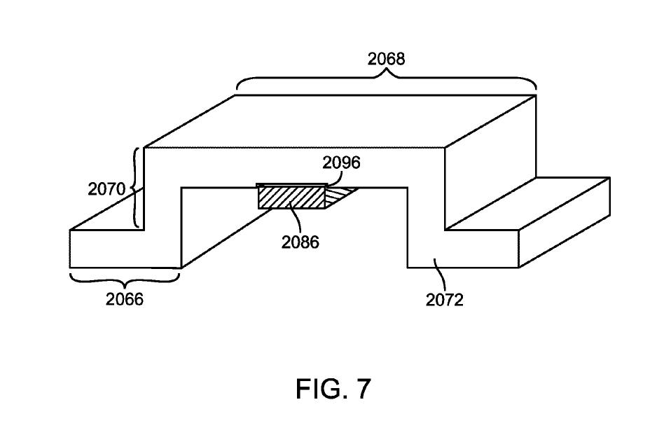

To help align and secure structures in cowling 2072, cowling 2072 may be provided with a recess such as recess 2095 of FIG. 7. Recess 2095 may be provided in the form of a notch, a groove, a rectangular opening that is surrounded on four sides by unrecessed portions of planar portion 2068, or any other suitable shape. Recess 2095 may have any suitable depth. For example, recess 2095 may have a depth that is just sufficient to receive an upper portion of foam 2086. Recess 2095 may also be larger (e.g., sufficiently large to receive all of foam 2086 and some or all of stiffener 2084, flex circuit 2082, and connector 2076.).

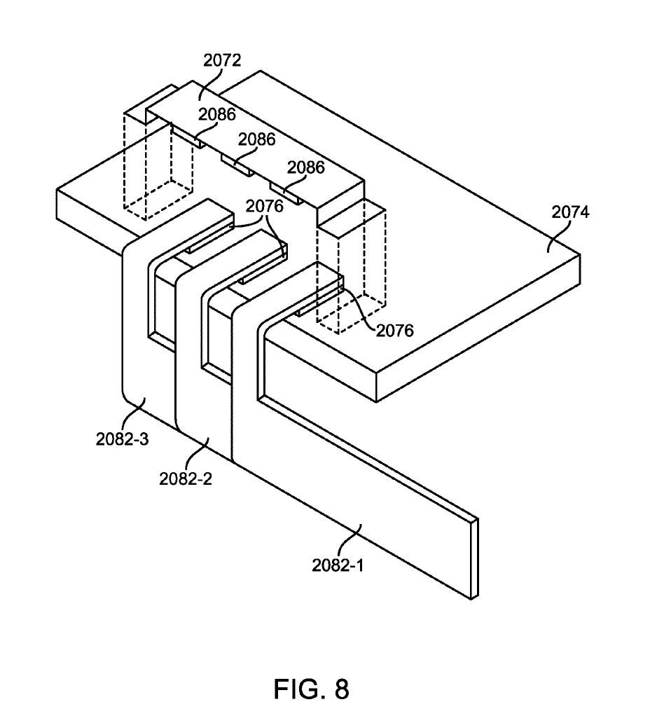

FIG. 8 shows an illustrative arrangement in which cowling 2072 is used in securing printed circuit board connectors 2076 associated with three different flex circuits. In the FIG. 8 example, connectors 2076 are used to connect flex circuits 2082-1, 2082-2, and 2082-3 to printed circuit board 2074. Cowling 2072 may be formed in the shape of a rectangular bracket. When mounted on printed circuit board 2074, cowling 2072 helps hold flex circuits 2082-1, 2082-2, and 2082-3 in place and secures connectors 2076 under compressed foam 2086.

Electronic devices such as handheld electronic devices often include connectors. For example, some cellular telephones include 30-pin connectors. Connectors such as these may be used as input-output data connectors and may receive mating plugs.

To ensure that the electronic device is not adversely affected by electrostatic discharge events or electromagnetic interference, 30-pin connectors have metal grounding shells. These metal shells surround the connector and provide the connector with structural support. When a plug is inserted into the connector, the outer metal portions of the plug are electrically grounded to the corresponding inner metal portions of the connector. Although satisfactory for grounding plugs, connectors with metal shells can be unsightly, because the metal is shiny and prominent.

Conventional connectors are sometimes provided with dye-based moisture indicators. When exposed to water, this type of moisture indicator changes color. It can therefore be determined whether or not an electronic device has been exposed to excessive amounts of moisture by examining the color of the moisture indicator. Examination of the moisture indicator state can be challenging, however, because the moisture indicator is generally mounted on the shell of the connector in a sidewall location that is difficult to view from the exterior of the device.

It would therefore be desirable to provide improved connectors for electronic devices.

In accordance with one embodiment, an electronic device may be provided with a connector such as a 30-pin connector with a rectangular opening. The connector may have a metal shell. A cosmetic dielectric insert may line the metal shell. A contact housing structure may be used to support contact leads within the connector. If desired, there may be 30 contacts in the connector.

The metal shell and the insert may each have planar top, bottom, left, and right sidewalls. The top and bottom sidewalls may be parallel to each other. The left and right sidewalls may be parallel to each other. The top and bottom sidewalls may be perpendicular to the right and left sidewalls so that the outermost edges of the sidewalls define the rectangular shape of the connector opening.

Metal ground plates may be welded to the interior surfaces of the metal shell. Corresponding openings may be provided in the dielectric insert. The openings may receive the metal ground plates. Because the metal ground plates protrude at least partly through the openings of the insert, the interior surfaces of the connector serve as ground structures, even though the insert covers substantially all of the interior of the metal shell. The metal shell may therefore be hidden from view by the cosmetic insert while grounding functionality is retained. When a plug is received within the connector, ground structures in the plug electrically connect to the metal ground plates to reduce adverse effects from electrostatic discharge events and electromagnetic interference.

The rear wall of the connector may be formed from a planar member such as part of the insert or part of the contact housing structure. An opening in the rear wall of the connector may be covered with a moisture indicator. The moisture indicator may include a wicking layer and a dye layer. Moisture barrier layers may surround the wicking layer and the dye layer. A layer of adhesive may be used to mount the moisture indicator behind the opening in the rear wall. The status of the moisture indicator may be determined by looking through the rectangular opening to the connector and the opening in the rear wall.

In accordance with an embodiment, a connector is provided that also includes a metal shell having a plurality of shell sidewalls with interior surfaces, and a dielectric insert that has a plurality of insert sidewalls that hide the interior surfaces of the shell sidewalls from view.

In accordance with another embodiment, a connector is provided wherein the dielectric insert includes a plastic insert.

In accordance with another embodiment, a connector is provided wherein the plurality of shell sidewalls include a top shell sidewall, a bottom shell sidewall, a right shell sidewall, and a left shell sidewall and wherein the plurality of insert sidewalls include a top insert sidewall that at least partly covers the top shell sidewall, a bottom insert sidewall that at least partly covers the bottom shell sidewall, a right insert sidewall that at least partly covers the right shell sidewall, and a left insert sidewall that at least partly covers the left shell sidewall.

In accordance with another embodiment, a connector is provided that also includes a rear wall with a rear wall opening, and a moisture indicator that covers the rear wall opening.

In accordance with another embodiment, a connector is provided wherein the connector has a connector opening defined by the plurality of insert sidewalls, wherein the rear wall has a visible surface that is visible through the connector opening and has a hidden surface that is hidden from view through the connector opening, and wherein the moisture indicator is attached to the hidden surface and covers the rear wall opening.

In accordance with another embodiment, a connector is provided wherein the moisture indicator includes a wicking layer, a dye layer and at least one moisture barrier layer.

In accordance with another embodiment, a connector is provided wherein the dielectric insert has a recess and wherein the metal shell has a protrusion that protrudes into and engages the recess.

In accordance with another embodiment, a connector is provided wherein the dielectric insert includes at least one opening, the connector also including a metal structure that is electrically shorted to the metal shell and that protrudes through the at least one opening in the dielectric insert.

In accordance with another embodiment, a connector is provided that also includes welds that attach the metal structure to the metal shell.

In accordance with another embodiment, a connector is provided wherein the metal structure includes a grounding plate adapted to connect to ground structures in mating plugs.

In accordance with an embodiment, a connector is provided that includes a metal shell having a rectangular opening that receives a plug, wherein the metal shell has top, bottom, right, and left sidewalls with interior surfaces, and a plastic insert in the metal shell, wherein the plastic insert has a rectangular opening that receives the plug, wherein the plastic insert includes top, bottom, right, and left sidewalls that cover at least some of the interior surfaces.

In accordance with another embodiment, a connector is provided that also includes a contact housing structure that is surrounded by the metal shell and the plastic insert, a plurality of contacts mounted in the contact housing structure, a plurality of metal ground plates that are electrically connected to the interior surfaces, and a plurality of openings in the plastic insert each of which receives a respective one of the metal ground plates so that the metal ground plates short to the plug when the plug is received within the rectangular opening.

In accordance with an embodiment, a connector is provided that includes a plurality of sidewalls, and a rear wall having an opening, and a moisture indicator mounted to the rear wall over the opening.

In accordance with another embodiment, a connector is provided that also includes a metal shell having at least four planar members, and a plastic insert in the metal shell.

In accordance with another embodiment, a connector is provided wherein the plastic insert has at least four planar members that are mounted within the four planer members of the metal shell.

In accordance with another embodiment, a connector is provided wherein the plastic insert has another planar member that forms the rear wall of the connector.

In accordance with another embodiment, a connector is provided that also includes a contact housing structure that is surrounded by the plurality of sidewalls, and a plurality of contacts supported by the contact housing structure.

In accordance with another embodiment, a connector is provided wherein the moisture indicator includes a wicking layer and a dye layer and wherein the moisture indicator has adhesive with which the moisture indicator is mounted to the rear wall over the opening.

In accordance with another embodiment, a connector is provided wherein the plurality of contacts include at least 30 contacts.

In accordance with another embodiment, a connector is provided wherein the plurality of sidewalls include parallel top and bottom planar shell members and parallel right and left planar shell members, wherein the top and bottom planar shell members are perpendicular to the right and left planar shell members, and wherein the rear wall is perpendicular to the right and left planar shell members and is perpendicular to the top and bottom planar shell members.

In accordance with these embodiments, electric connectors may be used in electronic devices to provide a port into which a user may insert cables, accessories, and other external equipment. Input-output data connectors may be provided with a number of electrical contacts (pins). For example, an input-output data connector may be provided with a 30-pin assembly that mates with a corresponding 30-pin plug on a cable or other external equipment. Other types of connectors may have fewer than 30 pins or may have more than 30 pins. The use of 30-pin connectors is sometimes described herein as an example. This is, however, merely illustrative. Electronic devices may, in general, be provided with connectors having any suitable number of contacts.

Electronic devices that may be provided with input-output connectors may include desktop computers, televisions, and other consumer electronics equipment. Electronic devices that are provided with connectors may also include portable electronic devices such as laptop computers and tablet computers. Examples of smaller portable electronic devices that may be provided with connectors include wrist-watch devices, pendant devices, headphone and earpiece devices, and other wearable and miniature devices. With one suitable arrangement, connectors may be provided in handheld devices such as cellular telephones and media players.

There may be one or more connectors in a given device. For example, a handheld electronic device such as a cellular telephone may be provided with a single input-output data port implemented using a 30-pin connector. Larger devices such as tablet devices may be provided with one, two, or more than two input-output data ports each of which may be implemented using a respective 30-pin connector (as an example).

An illustrative electronic device of the type that may have an input-output data port connector such as a 30-pin connector is shown in FIGS. 2A and 2B. Device 10 of FIGS. 2A and 2B may be, for example, a tablet computer or a handheld electronic device such as a cellular telephone with circuitry that runs email and other communications applications, web browsing applications, media playback applications, games, etc.

Device 10 may also include one or more connectors such as connector 2020. Connector 2020 may be a 30-pin data connector or other suitable connector that forms an input-output port for device 10 (e.g., a Universal Serial Bus connector, an Ethernet connector, etc.). Connector 2020 may have fewer than 30 pins or more than 30 pins. Connector 2020 may have a rectangular shape (i.e., a box-like shape that has a rectangular opening for receiving a plug with a rectangular cross section), a square shape, a shape with curved sides and a curved opening, a shape with a combination of curved sidewall surfaces and planar sidewall surfaces, etc. Use of a rectangular shape for connector 2020 is sometimes described herein as an example.

Connector 2020 may have a body that is mounted within housing 2012 using screws or other fasteners, adhesive, welds, or other mounting mechanisms. Brackets, frame structures, screw bosses, grooves, and other mounting features may be provided in housing 2012 to accommodate installation of connector 2020.

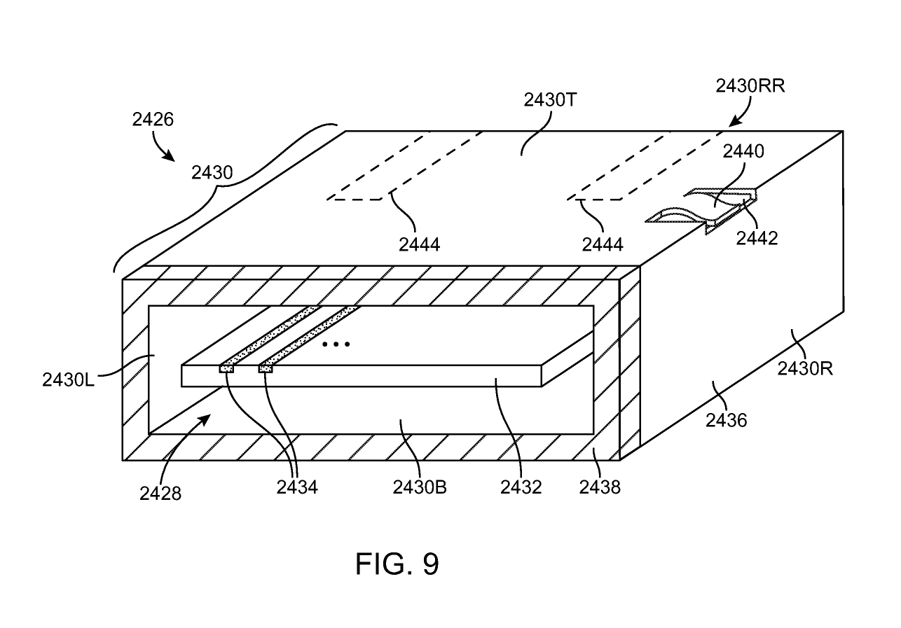

A perspective view of an illustrative embodiment of a connector is shown in FIG. 9. As shown in FIG. 9, connector 2426 may have a connector body 2430 with an opening such as opening 2428. Opening 2428 may have a rectangular shape. Body 2430 may have five planar wall structures (planar wall members) including right wall 2430R, left wall 2430L, top wall 2430T, bottom wall 2430B, and rear wall 2430RR. Body 2430 may be rectangular in shape so that right wall 2430R is parallel to left wall 2430L and so that top wall 2430T is parallel to bottom wall 2430B. Right wall 2430R and left wall 2430L may be perpendicular to top wall 2430T and bottom wall 2430B. Rear wall 2430RR may be perpendicular to walls 2430R, 2430L, 2430T, and 2430B.

Contacts 2434 (which are sometimes referred to as pins or contact leads) may be formed from metal and may be supported using contact housing member 2432 or other suitable contact support structure. Contact housing 2432 may, for example, be formed from plastic.

Body 2430 may include an outer metal shell member such as metal shell 2436 and a cosmetic inner insert member such as insert 2438. Insert 2438 may be formed from a dielectric material such as plastic.

Shell 2436 may be formed from a metal such as stainless steel that exhibits good strength and durability and that is sufficiently conductive to serve as a grounding structure for connector 2426. Stainless steel tends to be shiny, which may draw unwanted attention to the presence of connector 2426. It may therefore be desirable to cover at least some of the exposed inner surfaces of shell 2436 with a non-shiny material. In the embodiment of FIG. 9, inner surfaces in shell 2436 are at least partly covered by insert 2438. With this configuration, the inner surfaces of the planar top, bottom, right, and left sidewalls of shell 2436 are hidden by the corresponding planar top, bottom, right, and left sidewalls of insert 2438, so that insert 2438 substantially hides shell 2436 from view. The rear of connector 2426 may also be covered with a portion of insert 2438 or may be formed from a portion of insert 2438 (e.g., a planar rear wall portion).

To enhance device aesthetics, it may be desirable to form insert 2438 (and, if desired, contact housing 2432) from dark materials such as black plastic or other cosmetically appealing materials. Plastics such as polycarbonate (PC), acrylonitrile-butadiene-styrene copolymers (sometimes referred to as ABS plastic), PC/ABS blends, or other suitable polymers may be used to form insert 2438 and contact housing 2432. Insert 2438 may also be formed using cosmetic materials of other types (i.e., other dielectrics such as ceramic, glass, composites such as carbon-fiber composites, etc.) Insert 2438 and contact housing 2432 may be formed as separate members that are connected (e.g., using adhesive or other suitable fastening mechanisms) or may be formed as part of a unitary structure.

When it is desired to use connector 2426, a user may insert a mating plug into opening 2428. The plug may contain contacts that mate with respective contacts 2434 in connector 2426. For example, the plug may have 30 contacts that mate with 30 corresponding contacts 2434 on contact housing 2432. The plug that is inserted into opening 2428 may have a rectangular cross section that corresponds to the rectangular shape of opening 2428. The plug may be part of a dock, part of an electronic device, part of a cable, or part of other suitable electronic equipment.

Insert 2438 may be formed using molding processes (e.g., insert molding) or may be formed as a separate part such as an injection molded part that is press fit into shell 2436, thereby forming body 2430. To ensure that shell 2436 and insert 2438 remain securely attached to each other, shell 2436 and insert 2438 may be provided with mating engagement features (e.g., tabs or other protrusions, mating slots or other recesses, grooves, etc.). As shown in FIG. 9, for example, shell 2436 may be provided with a bent metal tab 2440 that is received in mating recess 2442 in insert 2438, thereby holding insert 2438 and shell 2436 together.

To ensure proper grounding of a plug that is inserted into opening 2428 to engage with connector 2426, insert 2438 may be provided with openings through which metal plate structures may protrude. The metal structures may be shorted to shell 2436 and may have surfaces that are exposed on the inner surfaces of connector 2426. When a plug is inserted into opening 2428, the outer surfaces of the plug will touch the metal structures and become electrically connected to the metal structures and shell 2436. Shell 2436 may be grounded within device 10, so the inclusion of holes in insert 2438 and the metal structures that protrude through these holes will ensure satisfactory grounding of inserted plugs. This may help to reduce adverse effects from electrostatic discharge events and electromagnetic interference during the use of device 10.

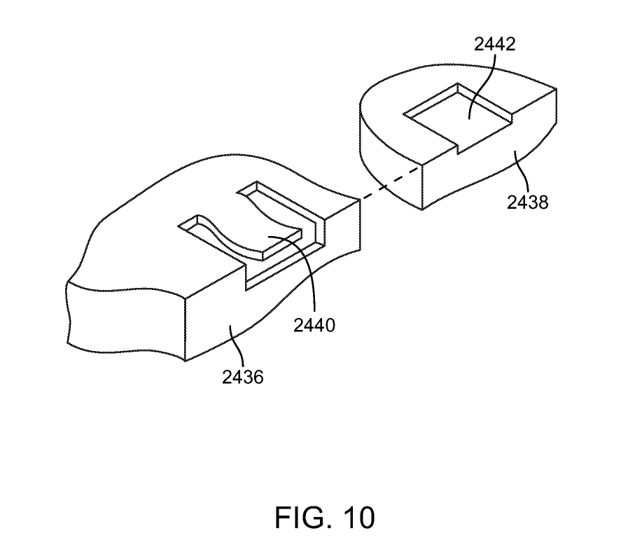

FIG. 10 is an exploded perspective view of portions of shell 2436 and its tab 2440 and corresponding recess 2442 in plastic insert member 2438. The use of a tab and mating recess to hold shell 2436 to insert 2438 is merely illustrative. Any suitable engagement features may be used if desired. In the example of FIG. 9, only a single tab and mating insert recess are shown, but, in general, connector 2426 may have one pair of mating engagement features, two pairs of mating engagement features, or more than two pairs of mating engagement features that secure insert 2438 within shell 2436. Insert 2438 may also be secured to shell 2436 using screws, adhesive, or other suitable fastening mechanisms.

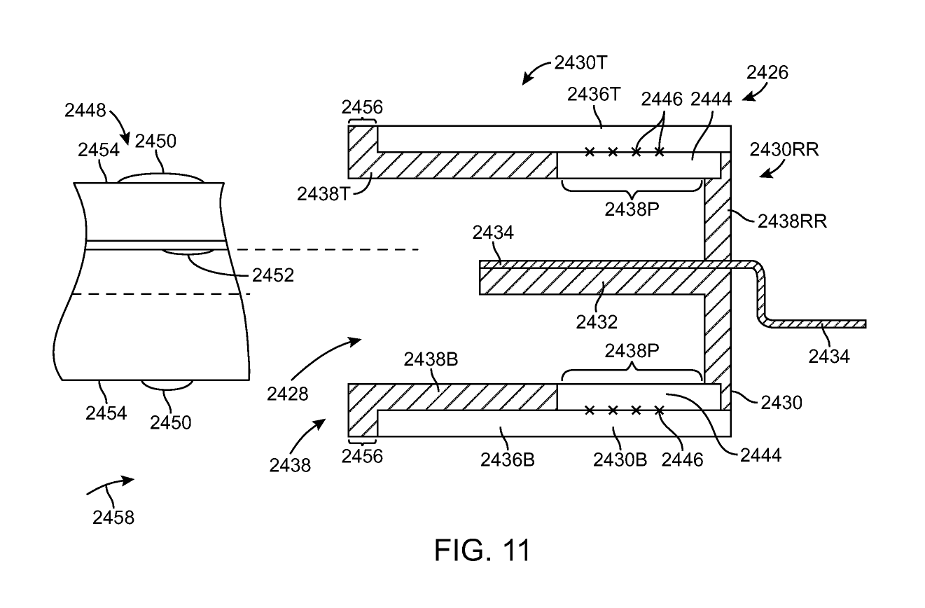

A cross-sectional side view of a connector such as connector 2426 of FIG. 9 is shown in FIG. 11. As shown in FIG. 11, connector 2426 may receive plug 2448 within opening 2428. Plug 2448 may have pins 2452 that mate with pins 2434 in connector 2426. Plug 2448 may also have an outer rectangular grounding sleeve such as sleeve 2454 (i.e., a box-shape housing member that surrounds pins 2452 without becoming electrically shorted to pins 2452). Protrusions such as protrusions 2450 on the planar outer surfaces of sleeve 2454 may facilitate the formation of an electrical connection between sleeve 2454 and the ground structures in the connector. Grounding sleeve 2454 and its protrusions 2450 mate with the inner surfaces of conventional metal shells in conventional 30-pin connectors. In connectors of the type shown in FIG. 11, plug grounding structures 2454 and 2450 mate with metal members 2444, which are shorted to shell 2436.

Metal members 2444 may be planar structures (e.g., rectangular planar structures such as rectangular plates of metal). Metal members 2444 may be formed from stainless steel or other metals that can be electrically connected to shell 2436. Metal members 2444 may be shorted to shell 2436 using solder, welds, or other suitable electrical interconnection techniques. As shown in the cross-sectional view of FIG. 11, metal members 2444 may, for example, be shorted to shell 2436 using welds 2446. Welds 2446 may be formed from the exterior of connector 2426 using laser welding (as an example).

Insert 2438 has planar sidewalls that fit within corresponding planar sidewalls in shell 2436. For example, insert 2438 has an upper wall (upper wall 2438T) that is adjacent to upper wall 2436T of shell 2436. Insert 2438 also has bottom wall 2438B, which is adjacent to bottom wall 2436B of shell 2436. To allow metal ground structures 2444 to be mounted to the inner surfaces of shell 2436, upper insert wall 2438T and bottom insert wall 2438B have openings 2438P through which structures 2444 protrude.

Rear wall 2438RR of insert 2438 may be used to form rear wall 2430RR of connector body 2430. Rear wall 2438RR and contact housing 2432 may be formed as part of a common plastic member or may be formed from separate structures. If desired, rear wall 2430RR may be partly or fully formed from a metal shell member that is part of shell 2436, provided that sufficient clearance is provided to allow contact structures 2434 to pass through rear wall 2430RR of contact body 2430 without shorting.

Insert 2438 preferably has four planar sidewalls (right, left, top, bottom) each of which is nested within one of the four planar sidewalls (right, left, top, bottom) of shell 2436. Rear wall 2438RR may form a fifth wall (i.e., a planar rear wall) for insert 2438. Optional lip structure 2456 on insert 2438 may help hide the outermost edges of shell 2436 from view by a user in direction 2458.

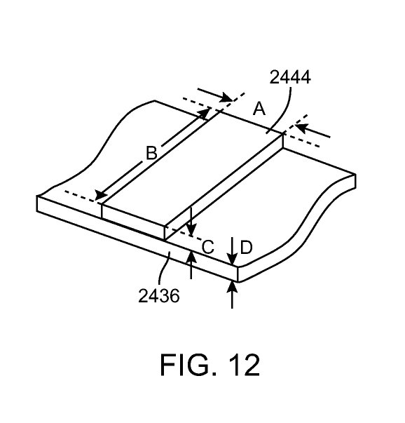

A perspective view of an interior surface of shell 2436 showing how metal structure 2444 may be mounted to shell 2436 is shown in FIG. 12. As shown in FIG. 12, metal structure 2444 may be formed from a rectangular sheet of metal that is welded to an interior surface of shell 2436. Metal structure 2444 serves to extend the grounding function of shell 2436 and may therefore sometimes be referred to as a ground extension or ground plate. Metal structure 2444 may, as an example have a lateral dimension A of about 1.0 to 2.0 mm, a lateral dimension B of about 2.0 to 4.0 mm, and a thickness C of about 0.2 to 0.4 mm (as examples). Metal shell 2436 may have a thickness D of about 0.2 to 0.3 mm (as an example).

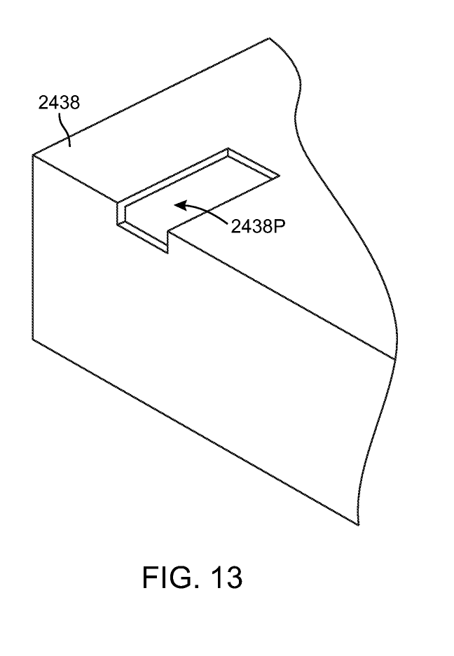

As shown in FIG. 13, opening 2438P in insert 2438 may have a size and shape such as a rectangular shape that accommodates ground plate 2444 of FIG. 12. There may be any suitable number of openings 2438P in insert 2438. For example, there may be four openings 2438P in insert 2438 that receive four corresponding ground plates 2444. Two ground plates 2444 may be mounted on the interior surface of the top wall of shell 2436 (i.e., wall 36T of FIG. 11) where indicated by dashed lines 2444 in FIG. 9. Two corresponding ground plates 2444 may likewise be mounted on the interior surface of the bottom wall of shell 2436 (i.e., wall 2436B of FIG. 11).

It may be desirable to determine whether moisture has entered device 10. A moisture indicator may be provided within the interior of device 10 that is visible through opening 2428. To ensure that the moisture indicator is readily visible, the moisture indicator may be located so that the moisture indicator covers an opening in the rear wall of connector 2426 (i.e., rear wall 2430RR of connector body 2430). The wall on which the moisture indicator is located may be rear wall 2438RR of insert 2438 (see, e.g., FIG. 11).

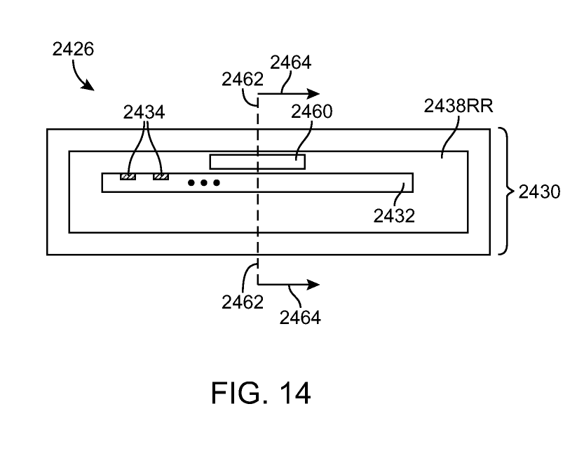

A front view of connector 2426 showing how rear wall 2438RR of connector 2426 may have an opening such as opening 2460 is shown in FIG. 14. Opening 2460 may be rectangular, circular, oval, square, may have other shapes with straight edges, other shapes with curved edges, shapes with a combination of curved and straight edges, or may have other suitable shapes. The use of a rectangular shape for opening 2460 in FIG. 14 is merely illustrative.

Opening 2460 may be covered with a moisture indicator. The moisture indicator may have a wicking layer and a dye layer. When exposed to moisture, the dye wicks into the wicking layer. This changes the appearance of the moisture indicator. For example, the wicking layer may be formed from a white material such as a layer of white paper. The dye may have a color such as a red color. In this type of moisture indicator configuration, exposure to moisture will cause the red dye to wick into the white paper and change its color from white to red. A user (e.g., service personnel associated with the manufacturer of device 10 or other suitable parties) can view the presence of the red color by looking through openings 2428 and 2460.

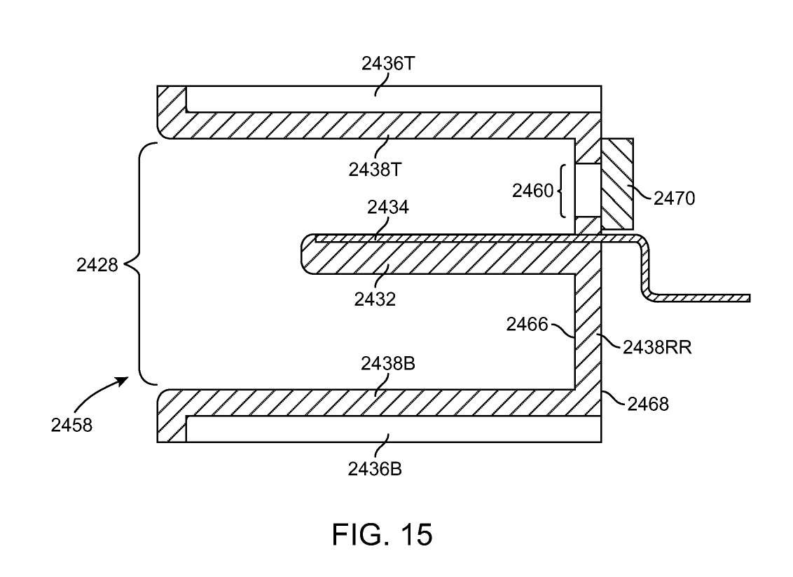

A cross-sectional view of a connector with a rear wall opening that is covered by a moisture indicator that is taken along line 2462-2462 and that is viewed in direction 2464 is shown in FIG. 15. As shown in FIG. 15, rear wall 2438RR of plastic insert 2438 may be provided with an opening such as opening 2460 that passes from exposed wall surface 2466 to hidden wall surface 2468. Moisture indicator 2470 may be mounted on hidden wall surface 2468 so that moisture indicator 2470 covers hole 2460. The state of moisture indicator 2470 may be viewed in direction 2458 through opening 2428 and opening 2460.

If desired, moisture indicator 2470 may be mounted over an opening in the rear wall of a connector that does not include plastic insert 2438. This type of arrangement is shown in FIG. 16. As shown in FIG. 16, contact housing 2432 may be used to form rear wall 2430RR in body 2430 of connector 2426. Shell 2436 in connector 2426 of FIG. 16 does not include an insert such as insert 2438 of FIG. 15. As a result, the interior surfaces of shell 2436 (i.e., surfaces 2472 and 2474) are visible. Plastic member 2432 may be formed from a single structure or from multiple members that are joined using adhesive or other suitable fastening mechanisms).

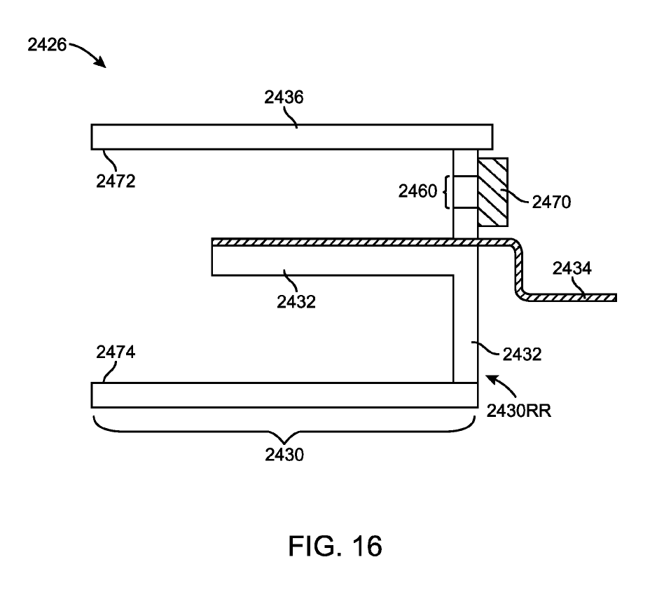

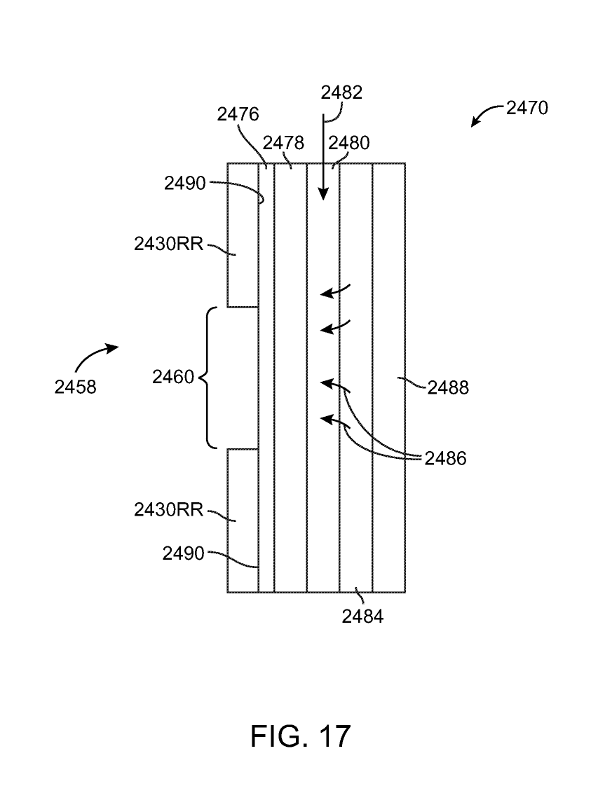

A cross-sectional side view of an illustrative moisture indicator is shown in FIG. 17. As shown in FIG. 17, moisture indicator 2470 may include moisture barrier layers such as moisture barrier layers 2478 and 2488. A layer of adhesive such as adhesive 2476 may be used to attach moisture indicator 2470 to surface 2490 of rear connector wall 2430RR (i.e., part of an insert rear wall or other rear wall structure for connector 2426). The layer of adhesive may be thin and transparent to allow the state of moisture indicator 2470 to be viewed in direction 2458. If desired, opening 2460 may be uncovered by adhesive 2476 (i.e., adhesive 2476 may have an opening of the same size as opening 2460).

Layers 2478 and 2488 may be formed from a material that is relatively impermeable to moisture such as a polymer (e.g., polyethylene terephthalate). With this type of configuration, the sensitivity of moisture indicator 2470 is reduced, because moisture mainly enters moisture indicator 2470 through its edges. If desired, other types of moisture indicator arrangements may be used (e.g., moisture indicators that are not edge activated). The use of an edge activated moisture indicator arrangement in the FIG. 17 example is merely illustrative.

Moisture indicator 2470 may have a wicking layer such as layer 2480 and a dye layer such as dye layer 2484. Wicking layer 2480 may be formed from a white substance such as white paper or fabric that is permeable to moisture. Dye layer 2484 may be formed from a colored material such as red dye that is capable of bleeding into wicking layer 2480. When moisture indicator 2470 is exposed to water or other moisture, the moisture may enter wicking layer 2480 in direction 2482. When the moisture penetrates wicking layer 2480, dye 2484 becomes wet and bleeds into wicking layer 2480 as indicated by arrows 2486. This changes the appearance of wicking layer 2480. For example, if wicking layer 2480 is initially white, the presence of red dye 2486 will turn wicking layer 2480 red.

The color of wicking layer 2480 and therefore the state of moisture indicator 2470 may be determined by viewing layer 2480 in direction 2458 through opening 2460. Because opening 2460 is formed in rear wall 2430RR, layer 2480 can be viewed straight on (i.e., at a non-oblique angle with respect to the longitudinal axis), thereby facilitating accurate inspection of moisture indicator 2470. Electronic devices such as computers, cellular telephones, and other devices typically contain printed circuit boards. Electrical components such as integrated circuits, switches, buttons, input-output port connectors, resistors, capacitors, inductors, and other discrete components may be mounted to a printed circuit board. Contact pads may be formed on the surface of a printed circuit board. Electrical components may be connected to the contact pads using solder. Conductive traces in the printed circuit board may be used to electrically interconnect the electrical components.

It is sometimes desirable to provide printed circuit boards with threaded fasteners such as threaded nuts. The presence of a threaded nut on a printed circuit board makes it possible to use screws to attach components to the printed circuit board.

In conventional arrangements, threaded nuts are sometimes connected to a printed circuit board using connections that are not sufficiently robust or that consume undesired amounts of board area.

It would therefore be desirable to be able to provide improved fastener mounting arrangements for printed circuit boards.

Electronic device 10 (see, e.g., FIGS. 1, 2A, and 2B) may be provided with fasteners such as threaded nuts that are mounted on printed circuit boards. The fasteners may be used to help mount components. For example, screws or other threaded members may mate with threaded bores in the fasteners. The screws may be used in attaching components securely to a printed circuit board.

Solder may be used to attach fasteners to solder pad structures on printed circuit boards. Protrusions in the fasteners and textured fastener surfaces may be provided to help hold the fastener in place within the solder.

A hole may be formed in a printed circuit board. The hole may extend only partly through the printed circuit board or may be a through hole that passes entirely through the printed circuit board. The solder pad structures may include sidewall portions within the hole to which the fastener is soldered. These sidewall portions may have the shape of a vertically extending cylinder that lines the cylindrical surfaces of the hole.

The solder pad structures may also include portions on the front side of the printed circuit board to which horizontally protruding portions of the body of the fastener are soldered. These front-side solder pad structures may, for example, have the shape of a ring that extends around the periphery of the hole on the front surface of the printed circuit board.

The fastener body may define a footprint. The portion of the rear printed circuit board surface that lies within the footprint may be left unmetallized by solder pad structures to allow for the formation of patterned interconnect traces under the fastener.

In accordance with an embodiment, apparatus is provided that includes a fastener body, and a solder-philic coating partially covering the fastener body.

In accordance with another embodiment, apparatus is provided that also includes a threaded bore in the fastener body.

In accordance with another embodiment, apparatus is provided that also includes textured structures on sidewall surfaces of the fastener body.

In accordance with another embodiment, apparatus is provided that also includes a printed circuit board, and solder with which the fastener body is mounted to the printed circuit board.

In accordance with another embodiment, apparatus is provided that also includes a through hole that extends completely through the printed circuit board, wherein the fastener body is at least partly inserted in the through hole.

In accordance with another embodiment, apparatus is provided that also includes solder pad structures on the printed circuit board, wherein the solder is interposed between the solder pad structures and the fastener.

In accordance with another embodiment, apparatus is provided wherein the printed circuit board has first and second opposing surfaces and wherein the through hole has sidewalls and wherein the solder pad structures include a planar solder pad structure portion on the first surface and a vertical solder pad structure portion on the sidewalls.

In accordance with another embodiment, apparatus is provided wherein the fastener body has an associated footprint and wherein the apparatus further includes patterned interconnect traces on the second surface of the printed circuit board within the footprint.

In accordance with another embodiment, apparatus is provided wherein the fastener body has a plurality of radially extending protrusions.

In accordance with an embodiment, apparatus is provided that includes a printed circuit board having first and second sides, wherein the printed circuit board has portions defining a hole in the first side that passes only partly through the printed circuit board and does not penetrate the second side, and a fastener mounted in the hole.

In accordance with another embodiment, apparatus is provided wherein the fastener includes a threaded nut.

In accordance with another embodiment, apparatus is provided that also includes solder pad structures with which the fastener is mounted in the hole.

In accordance with another embodiment, apparatus is provided wherein the solder pad structures include portions on the first surface and portions lining hole sidewalls in the hole.

In accordance with another embodiment, apparatus is provided that also includes solder interposed between the fastener and the solder pad structures.

In accordance with another embodiment, apparatus is provided wherein the fastener has an associated footprint and wherein the apparatus further includes patterned interconnect traces on the second surface of the printed circuit board within the footprint.

In accordance with another embodiment, apparatus is provided that also includes a solder-philic coating that covers only selected portions of the fastener.

In accordance with another embodiment, apparatus is provided wherein the printed circuit board includes a first layer in which the hole is formed and a second layer that does not contain any portions of the hole, wherein the first layer is laminated to the second layer.

In accordance with another embodiment, apparatus is provided wherein the fastener has beveled edges within the hole.

In accordance with another embodiment, apparatus is provided wherein the fastener includes a textured surface that is at least partly covered by the solder.

In accordance with an embodiment, apparatus is provided that includes a printed circuit board having a through-hole that passes between first and second opposing surfaces of the printed circuit board, a fastener mounted to the printed circuit board so that portions of the fastener are located in the through hole, wherein the fastener defines a footprint on the second surface, and an interconnect trace located on the second surface within the footprint.

In accordance with another embodiment, apparatus is provided that also includes solder pad structures having a ring-shaped portion on the first surface surrounding the hole and having vertical sidewall portions lining the through hole, and solder interposed between the solder pad structures and the fastener.

In accordance with these embodiments, structures such as standoffs, fasteners, and threaded nuts may be mounted to a printed circuit board. These structures, which are sometimes collectively referred to herein as fasteners, may be formed from materials such as metal. Threads may be provided in fasteners to receive mating screws. Fasteners without threads may also be mounted to printed circuit boards.

Once a fastener has been mounted to a printed circuit board, the fastener may be used in attaching components to the printed circuit board. For example, data port connectors, additional printed circuit boards, electrical components, mechanical components, and other structures may be attached to the printed circuit board using the fastener. As an example, a component may be screwed into place using screws that screw into mating threads in threaded fasteners on the printed circuit board.

With one suitable arrangement, which is sometimes described herein as an example, fasteners may be mounted on a printed circuit board using solder. Adhesive, springs, clips, rigid engagement features, and other attachment mechanisms may also be used in mounting fasteners to printed circuit boards if desired.

Solder-attachment structures may be formed on a printed circuit board to which solder connections are made. These structures, which are sometimes referred to herein as solder pads, may be formed from metal (e.g., copper) or other materials to which solder adheres. For example, a solder pad may be formed from elemental copper or an alloy of copper. In some configurations, all or part of a solder pad may be formed from a patterned planar structure on the surface of the printed circuit board. Solder pads of this type may be based on square pad structures, ring-shaped designs, etc. In other configurations, some of the solder pad may be formed from a non-planar structure (e.g., a structure that penetrates partially or fully into a recess in a printed circuit board. The recess into which the solder pad layer penetrates may, for example, be a hole that penetrates partially through a printed circuit board or may be a through hole. Through holes, which are sometimes referred to as vias, extend from one side of the printed circuit board to the other.

Part or all of the body of a fastener may be mounted within a printed circuit board hole. Solder may then be used to attach the fastener to the solder pad structures. For example, molten solder may be introduced into the thin gap between the fastener and the solder pad structure. Surface tension generally causes the solder to wick into the gap.

To avoid consuming excessive printed circuit board real estate, the extent to which solder pad structures spread across the rear surface of a printed circuit board can be limited either by removing rear surface solder pad structures or by forming recesses that only partially penetrate the printed circuit board.

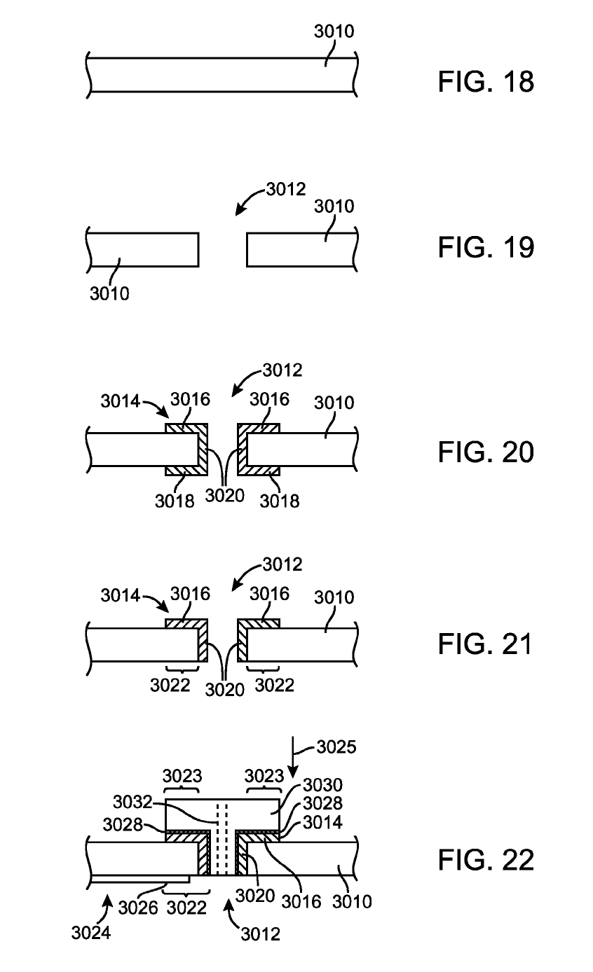

Consider, as an example, the illustrative fastener attachment scheme shown in FIGS. 18, 19, 20, 21, and 22 that may be used with an electronic device (e.g. device 10 of FIG. 1).

FIG. 18 is a cross-sectional side view of a printed circuit board before a fastener attachment recess has been formed. Printed circuit board 3010 may be a rigid printed circuit board such as a fiberglass-filled epoxy board or other suitable printed circuit board.

As shown in FIG. 19, a through hole such as through hole 3012 may be formed in printed circuit board 3010. Any suitable number of through holes may be formed on a given printed circuit board (e.g., one, two, three, more than three, tens of holes, hundreds of holes, etc.). In the illustrative arrangement of FIG. 19, a single through hole is shown to avoid over-complicating the drawing.

As shown in FIG. 20, through hole 3012 may be plated or otherwise coated with solder pad material. One or more processing steps may be used to form solder pad structures 3014. Solder pad deposition techniques that may be used in forming solder pad structures 3014 include electrochemical deposition, physical vapor deposition, screen printing, pad printing, chemical vapor deposition, ink-jet printing, spraying, etc. Solder pad structures 3014 may, for example, be formed by introducing a sensitizing layer into hole 3012 and performing one or more subsequent metal plating operations. As shown in FIG. 20, plating operations may result in solder pad structures 3014 that include vertical sidewalls 3020. Vertical sidewalls 3020 may have a cylindrical shape that conforms to and lines the cylindrical shape of hole 3012. The plating operations may also result in the formation of planar surface structures such as front solder pad ring 3016 and rear solder pad ring 3018. Rings 3016 and 3018 may be planar metal structures that are formed as an integral portion of solder pad structures 3014 and that are therefore connected to vertical sidewalls 3020.

To avoid consuming excessive surface on the printed circuit board some or all of the solder pad ring structures can be removed. For example, rear surface solder pad ring 3018 may be removed from solder pad structures 3014 as shown in FIG. 21. Rear solder pad ring 3018 may be removed using etching techniques, polishing techniques, drilling (milling) techniques, etc. For example, rear solder pad ring 3018 may be removed without removing vertical sidewall portions 3020 of solder pad structures by using a drill to drill away solder pad ring 3018 from the rear surface of printed circuit board. In general, either the upper or lower solder pad ring may be removed in this way. In the orientation of FIG. 21, the solder pad ring on the lower (rear) surface of printed circuit board 3010 has been removed as an example.

By removing rear ring 3018, an unmetallized area 3022 is formed that lies vertically under front surface solder pad ring 3016. Unmetallized (uncovered) area 3022 may have a circular ring shape. As shown in FIG. 22, because metal 3018 of FIG. 20 has been removed from area 3022, area 3022 is available for forming conductive trace patterns. For example, interconnect trace 3024 may have a portion such as portion 3026 that lies in unmetallized area 3022. Had metal layer 3018 of FIG. 20 not been removed, area 3022 would have been occupied with conductor and would not be available for forming patterned interconnect traces. Area 3022 is located directly under horizontally protruding portions 3023 of fastener 3030 (in the orientation of FIG. 22) and may therefore be said to lie in the “footprint” of fastener 3030. The size and shape of the footprint defined by fastener 3030 depends on the size and shape of the body of fastener 3030 when viewed from vertical (top) direction 3025.

Fastener 3030 of FIG. 22 may be mounted within though hole 3012. For example, a narrow part of the body of fastener 3030 may be inserted into hole 3012. Once fastener 3030 has been inserted into hole 3012, molten solder 3028 may be introduced into the thin gap between fastener 3030 and solder pad structures 3014. Through the wicking action associated with molten solder, solder 3028 may fill the gap and thereby become interposed between fastener 3030 and solder pad structures 3014. Solder may be used to attach fastener 3030 to both ring-shaped planar solder pad portion 3016 and vertical sidewall solder pad portion 3020 of solder pad structures 3014. As illustrated by threaded bore 3302 in the example of FIG. 22, fastener 3030 may be threaded to receive screws.

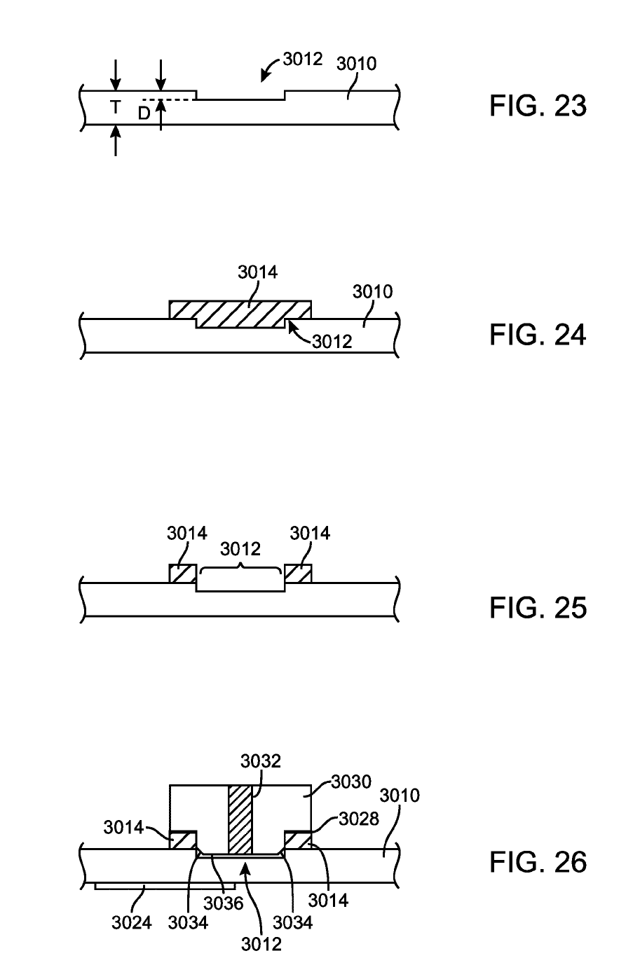

If desired, fasteners may be attached to a hole that passes only partially through printed circuit board 3010. This type of arrangement is shown in the cross-sectional side views of FIGS. 23, 24, 25, and 26.

As shown in FIG. 23, recess (hole) 3012 may be formed to a depth D that is less than thickness T of printed circuit board 3010. Hole 3012 may be formed by mechanical drilling, by laser drilling, by punching holes through a portion of a printed circuit board and laminating that portion of the printed circuit board to additional printed circuit board layers, etc.

As shown in FIG. 24, hole 3012 may be filled with metal or other suitable material for solder pad structures 3014.

To accommodate fastener 3030, the central portion of the metal of FIG. 24 may be drilled out or otherwise removed, leaving hole 3012 and peripheral (ring-shaped) solder pad structures 3014 of FIG. 25.

As shown in FIG. 26, fastener 3030 may be soldered to solder pad structures 3014 using solder 3028. If desired, vertical sidewall portions of the metal that was deposited as shown in FIG. 24 may be left in place (e.g., by drilling away the central portion of the metal using a drill bit that is smaller in diameter than the drill bit that was used to form hole 3012). Solder 3078 may then be used to form a connection to the vertical sidewall portions. In the example of FIG. 26, all of the sidewall portions of solder pad structures 3014 were removed prior to inserting fastener 3030 into hole 3012.

To help ensure that fastener 3030 fits into hole 3012, even if hole 3012 has a sloped lower surface (e.g., from use of a drill bit with a rounded tip), fastener 3030 may be provided with one or more bevels such as bevel 3034 or other angled surfaces. Bevel 3034 may extend around the entire periphery of lower surface 3036 of fastener 3030. The angel of bevel 3034 with respect to the planar surface of printed circuit board 3010 may be, for example, 45°, less than 60°, etc.

Because hole 3012 passes only partially through printed circuit board 3010, the surface of printed circuit board 3010 that lies under fastener 3030 (i.e., the footprint of fastener 3030) remains unmetallized and can be used to accommodate patterned interconnect traces such as illustrative trace 3024 of FIG. 26.

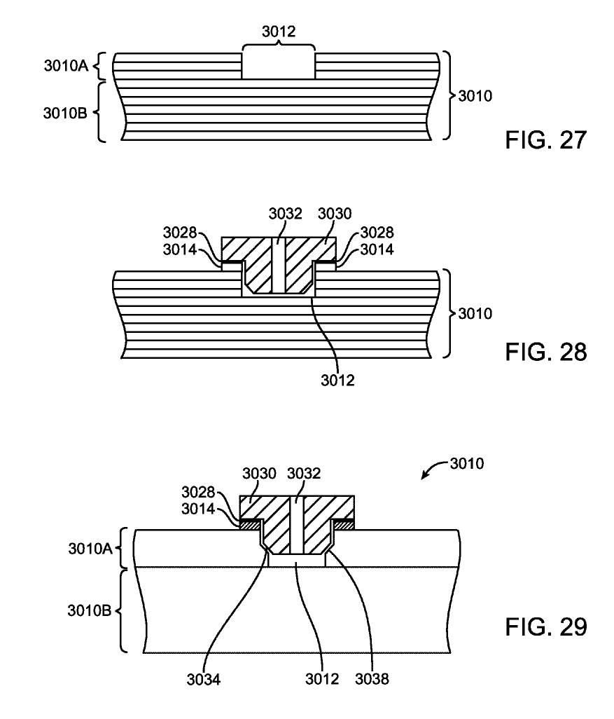

If desired, printed circuit board 3010 may be formed from laminated layers. An arrangement of this type is shown in FIG. 27. As shown in FIG. 27, printed circuit board 3010 may be formed from upper layer 3010A and lower layer 3010B. Layers 3010A and 3010B may each contain multiple layers of printed circuit board dielectric and multiple layers of patterned interconnect traces. For example, layer 3010A may contain three printed circuit board layers and layer 3010B may contain 7 printed circuit board layers (as an example).

Hole 3012 may, if desired, be formed in upper layer 3010A before upper layer 3010A and lower layer 3010B are laminated together (e.g., using adhesive, etc.). For example, hole 3012 may be removed using a punch or may be formed using a drilling tool. Following formation of hole 3012, layer 3010A may be attached to layer 10B to form printed circuit board 3010.

As shown in FIG. 28, solder pad structures 3014 may be formed on the surface of printed circuit board 3010 around the periphery of hole 3012. Solder 3028 may be used to attach fastener 3030 to solder pad structures 3014.

If desired, a drill may be used to form hole 3012 in upper layer 3010A, resulting in sloping sidewalls 3038, as shown in FIG. 29. Bevels 3034 may be provided on fastener 3030 to help ensure that fastener 3030 can be fully inserted into hole 3012 without catching on the edges of hole 3012. When properly inserted, the flanged edge portions of fastener 3030 may rest on solder pad structures 3014, as shown in FIG. 29. Solder 3028 may be used to form a solder joint between fastener 3030 and solder pad structures 3014.

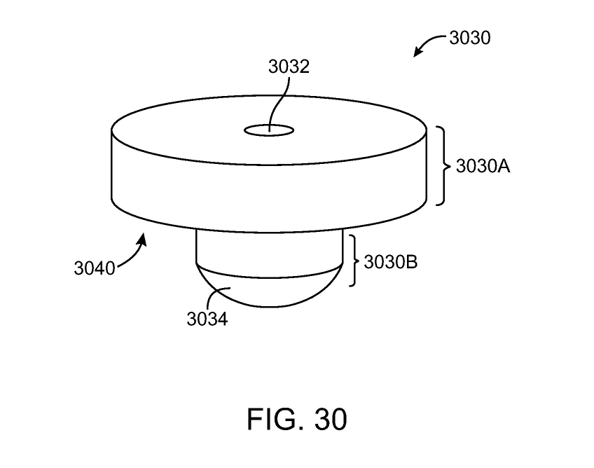

FIG. 30 is a perspective view of an illustrative printed circuit board fastener. Threaded bore 3032 may be used to receive screws or other threaded structures. Bore 3032 may extend completely or partially through fastener 3030. Upper portion 3030A of fastener 3030 may have a wider diameter than lower portion 3030B. This allows lower portion 3030B of fastener 3030 to be inserted into printed circuit board holes and allows lower surface 3040 of portion 3030A to come to rest on solder pad structures 3014. Bevel 3034 or other curved or angled surfaces may be formed on lower portion 3030B to help avoid contact with sloped hole sidewalls such as sidewalls 3038 of FIG. 29.

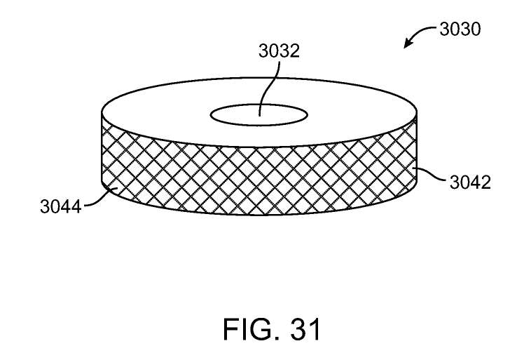

As shown in FIG. 31, fastener 3030 may have a disk shape or other suitable shape with knurled sidewalls 3042. Sidewalls 3042 may include textured structures such as raised ridges and sunken grooves. These structures may engage with solder 3028 when solder 3028 extends up sidewalls 3042.

It may be desirable to control the amount by which solder 3028 wicks up the sidewalls of fastener 3030. Excessive sidewall wicking may, for example, cause solder to cover part of the uppermost surface of fastener 3030. To prevent this type of encroachment of solder 3028, fastener 3030 may be provided with solder-phobic and solder-philic regions. As an example, fastener 3030 may be formed form a metal that repels solder or may be coated with a solder-phobic layer (e.g., a layer of oxide). Part of fastener 3030 may then be coated with a solder-philic coating such as a layer of silver or gold.

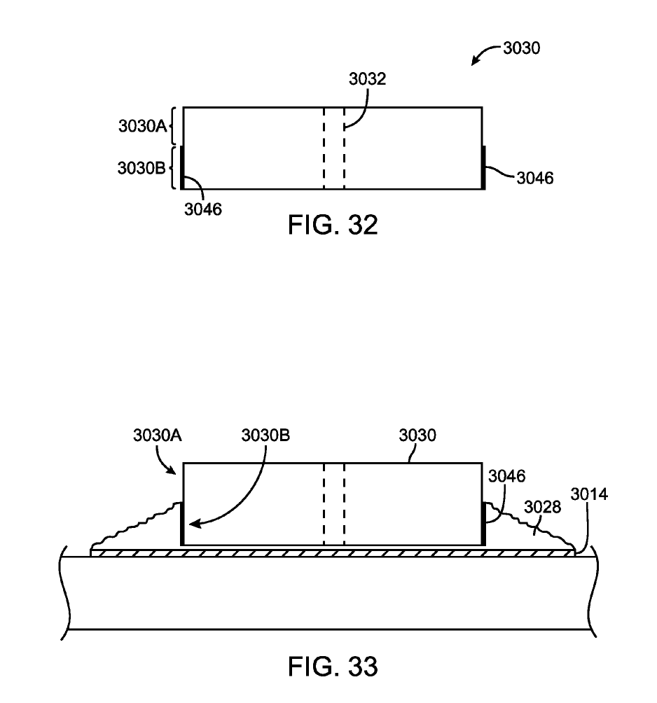

Consider, as an example, fastener 3030 of FIGS. 32 and 33. In this example, fastener 3030 is formed from a material that does not exhibit a high affinity to solder (i.e., a solder-phobic metal or metal coated with a solder-phobic coating such as a layer of oxide). As shown in FIG. 32, this renders upper sidewall portion 3030A solder-phobic. Lower sidewall portion 3030B may be coated with solder-philic coating 3046. When solder 3028 is used to mount fastener 3030 to printed circuit board 3010 (e.g., by soldering fastener 3030 to solder pad structure 3014 as shown in FIG. 32, solder 3028 will only adhere to lower sidewall portion 30B of fastener 3030. Upper sidewall portion 3030A will remain uncoated.

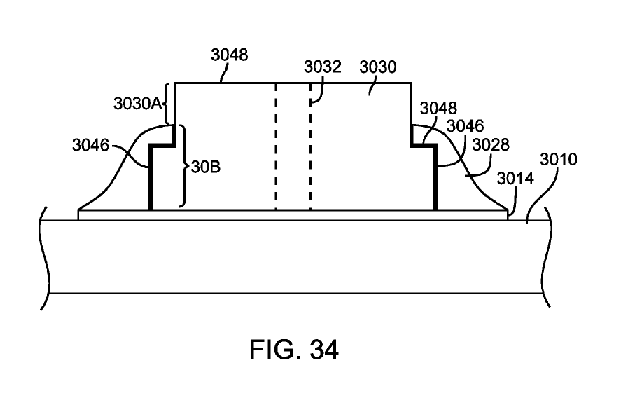

FIG. 34 shows how fastener 3030 may be provided with a protrusion that forms ledge 3048. Ledge 3048 or other substantially horizontal surfaces that are formed on the sidewalls of fastener 3030 may be used to engage solder 3028. This helps to hold fastener 3030 to printed circuit board 3010. As shown in FIG. 34, solder-philic coating 3046 may be formed on the lower portions of fastener 3030 to prevent solder 3028 from adhering to upper portions near top surface 3048.

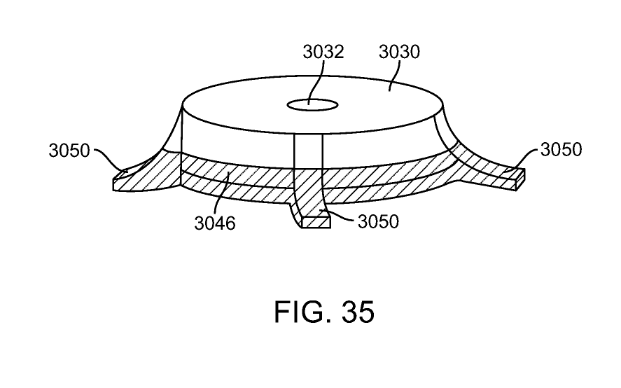

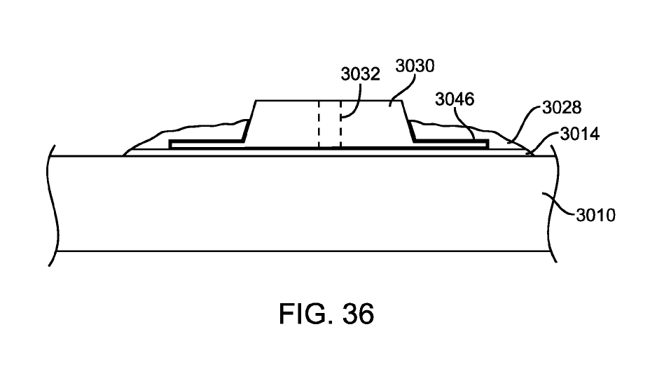

In the example of FIG. 35, fastener 3030 has been provided with radially extending protrusions such as legs 3050. As shown in FIG. 36, legs 3050 may engage with solder 3028 and thereby help to hold fastener 3030 in place when fastener 3030 is soldered to printed circuit board 3010. There may be any suitable number of protrusions on fastener 3030 (e.g., one leg, two legs, three evenly spaced legs, or four or more legs). Moreover, protrusions need not be formed in the shape of legs. For example, protrusions such as ring-shaped protrusions may be formed that are rotationally symmetric.

Fasteners 3030 may, if desired, have combinations of the features described in connection with FIGS. 18-34. For example, a fastener with radially extending legs may be provided with a narrow lower cylindrical portion such as portion 3030B of fastener 3030 in the example of FIG. 30.

Fastener 3030 of FIG. 30 and other fasteners may be provided with selective solder-philic and solder-phobic regions. Textured surface 3044 of fastener 3030 of FIG. 31 may be provided on fasteners of the other shapes shown in FIGS. 18-34. Fasteners 3030 may be mounted on the surface of a printed circuit board or may be mounted in a hole that is formed partly through or completely through printed circuit board 3010. Fasteners may have substantially cylindrical bodies, as shown in the examples of FIGS. 18-34 or may have bodies with other shapes (e.g., cubes, etc.). Narrowed fastener body portions such as portions 3030B of FIG. 30 may be provided on any of the fasteners of FIGS. 18-34 to allow the narrow portion of the fastener to be inserted into a printed circuit board hole.

Electronic devices such as computers, cellular telephones, and other devices typically contain printed circuit boards. Electrical components such as integrated circuits, switches, buttons, input-output port connectors, resistors, capacitors, inductors, and other discrete components may be mounted to a printed circuit board.

Some of the circuitry on a printed circuit board may be used in handling radio-frequency signals. Examples of circuits that handle radio-frequency signals include radio-frequency transmitters, radio-frequency receivers, low-noise amplifiers for receiving incoming radio-frequency signals from an antenna, and power amplifiers for boosting signal strengths of radio-frequency signals prior to transmission over an antenna.

It is sometimes desirable to enclose circuits on a printed circuit board in radio-frequency shielding cans. Radio-frequency shielding may be used to help prevent radio-frequency signals that are generated by a circuit from escaping and causing interference. Radio-frequency shielding may also be used to prevent external radio-frequency signals from interfering with the operation of the circuitry that is shielded within the shielding can.

In dense printed circuit board environments, space consumption by radio-frequency shielding cans and other components is a concern. If care is not taken, the area that is consumed by the radio-frequency shielding cans and components on the printed circuit board may become excessive, leading to inefficient layouts and excessive board size.

It would therefore be desirable to provide improved techniques for mounting radio-frequency shielding cans and other components to printed circuit boards.

In accordance with one embodiment, an electronic device may be provided with a printed circuit board mounted with integrated circuits and other circuitry. To block radio-frequency signals that may cause interference, the integrated circuits and other components may be enclosed within radio-frequency shielding structures such as radio-frequency shielding cans.

A radio-frequency shielding can may have a frame and a lid. The frame may have legs that are mounted to the printed circuit board. The legs may be configured so that there is less than a quarter of a wavelength of separation between circuit board attachment points at electromagnetic frequencies of interest.

The frame may have corners at which mounting structures are used to attach the radio-frequency shielding can to the printed circuit board. An additional component such as a speaker or other electrical component may overlap the radio-frequency shielding can at one of the corners. The mounting structures may include mating fasteners. One of the fasteners may be a screw with a threaded shaft. The other fastener may be a standoff with a threaded bore that receives the threaded shaft. The standoff may be soldered to the printed circuit board in an opening that does not pass completely through the printed circuit board.

In accordance with an embodiment, apparatus is provided that includes a radio-frequency shielding can having a first opening, an electrical component having a second opening that overlaps with the first opening, a mounting structure that is received in both the first and second openings, and a substrate to which the mounting structure mounts the radio-frequency shielding can and the electrical component.

In accordance with another embodiment, apparatus is provided wherein the mounting structure includes mating fasteners.

In accordance with another embodiment, apparatus is provided wherein the mating fasteners include a male fastener and a female fastener.

In accordance with another embodiment, apparatus is provided wherein the male fastener has a threaded shaft and wherein the female fastener has a threaded bore.

In accordance with another embodiment, apparatus is provided wherein the female fastener is mounted to the substrate.

In accordance with another embodiment, apparatus is provided wherein the radio-frequency shielding can has a frame and a lid and wherein the first opening is formed in the frame.

In accordance with another embodiment, apparatus is provided wherein the electrical component includes a speaker.

In accordance with another embodiment, apparatus is provided wherein the mounting structure includes first and second mating fasteners, wherein the second fastener is soldered to the substrate, and wherein the first fastener is screwed into the second fastener.

In accordance with another embodiment, apparatus is provided wherein the substrate includes a printed circuit board with a solder pad and wherein the second fastener is soldered to the substrate at the solder pad.

In accordance with another embodiment, apparatus is provided wherein the solder pad includes a ring-shaped metal structure and wherein the printed circuit board includes multiple layers of ring-shaped metal below the solder pad.

In accordance with another embodiment, apparatus is provided wherein the radio-frequency shielding can blocks radio-frequency signals at a wavelength associated with operating circuitry within the radio-frequency shielding can, wherein the mounting structure and other portions of the radio-frequency shielding can are attached to the substrate at a plurality of respective attachment points and wherein no two adjacent attachment points among the attachment points are separated by more than a quarter of the wavelength.

In accordance with another embodiment, apparatus is provided wherein the substrate includes a printed circuit board having a thickness, wherein the mounting structure includes a first fastener and a second fastener, and wherein the second fastener is soldered to the printed circuit board without passing through the thickness of the printed circuit board.

In accordance with an embodiment, an electronic device is provided that includes a housing, a printed circuit board within the housing, a radio-frequency shielding can having four corners, an electrical component that overlaps a given one of the four corners, and a first fastener that is mounted to the printed circuit board, and a second fastener that mates with the first fastener at the given one of the four corners and that attaches both the radio-frequency shielding can and the electrical component to the printed circuit board at the given one of the four corners.

In accordance with another embodiment an electronic device is provided wherein the second fastener includes a screw and wherein the first fastener has a threaded bore that accepts the screw.

In accordance with another embodiment an electronic device is provided wherein the electrical component includes a speaker.

In accordance with another embodiment an electronic device is provided wherein the radio-frequency shielding can has a first U-shaped opening, wherein the electrical component has a second U-shaped opening, and wherein the screw passes through the first and second U-shaped openings at the given one of the four corners.

In accordance with an embodiment, apparatus is provided that includes a radio-frequency shielding can having a first opening, an electrical component having a second opening that overlaps the first opening, a printed circuit board, a first fastener mounted to the printed circuit board, and a second fastener that passes through the first and second openings and that mates with the first fastener to attach the radio-frequency shielding can and the electrical component to the printed circuit board.

In accordance with another embodiment an apparatus is provided wherein the second fastener includes a screw, the first fastener includes a threaded bore that receives the screw, the printed circuit board includes solder pad structures, and the first fastener is soldered to the solder pad structures.

In accordance with another embodiment an apparatus is provided wherein the radio-frequency shielding can has four corners and wherein the first opening is located at a given one of the four corners.

In accordance with another embodiment an apparatus is provided wherein the radio-frequency shielding can includes a frame and a lid that is attached to the frame and wherein the first opening includes a U-shaped opening in the frame.

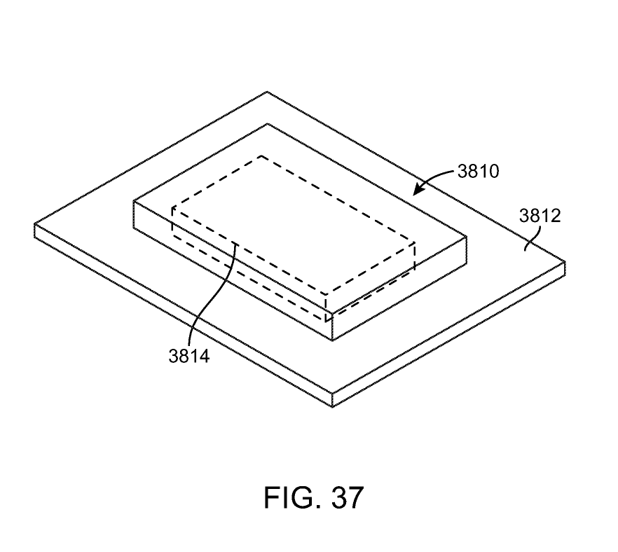

In accordance with these embodiments, radio-frequency shielding enclosures (“cans”) may be used to block radio-frequency interference. As shown in FIG. 37, radio-frequency shielding can 3810 may be mounted to a substrate such as printed circuit board 3812. Printed circuit boards such as printed circuit board 3812 of FIG. 37 may be mounted in the interior of cellular telephones, computers, and other electronic devices. Components that are sensitive to radio-frequency interference such as radio-frequency transceivers and other circuits can be enclosed by can 3810, as illustrated by components 3814 in FIG. 37. Enclosing components 3814 in can 3810 may prevent radio-frequency interference from disrupting the operation of components 3814.

Can 3810 may be formed from conductive materials such as metal. The presence of the metal in can 3810 helps block radio-frequency electromagnetic signals. Can 3810 may have walls that are formed from solid metal, perforated metal, laminated structures with one or more conductive layers, etc. In some configurations, can 3810 may be formed from a unitary structure such as a piece of stamped sheet metal. In other configurations, can 3810 may be formed from a multipart structure. As an example, can 3810 may have a frame and a lid.

In a radio-frequency shield with a frame and a lid, the frame may be mounted to a printed circuit board using mounting structures. For example, a male threaded fastener such as a screw may mate with a corresponding female threaded fastener such as a standoff or nut. With this type of arrangement, the screw may be used to secure the frame to the printed circuit board. The lid of the radio-frequency shielding can may be press-fit onto the frame. Adhesive, welds, and other attachment mechanisms may also be used in attaching a radio-frequency shielding can lid to a radio-frequency shielding can frame if desired. For clarity, use of radio-frequency shielding arrangements that have a frame and a lid are sometimes described herein as an example. This is, however, merely illustrative. Radio-frequency shielding enclosures may be formed from a one-piece structure, a two-piece structure, from structures having three or more pieces, etc.

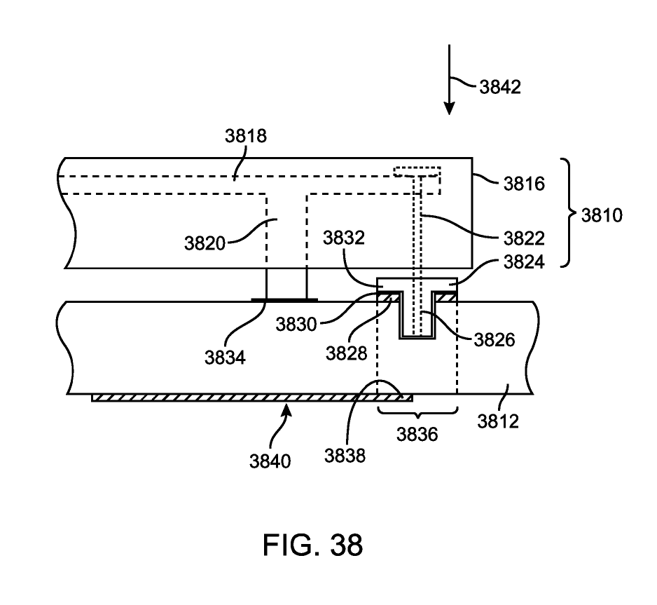

A side view of an illustrative radio-frequency shielding can mounted on a printed circuit board is shown in FIG. 38. As shown in FIG. 38, radio-frequency shielding can 3810 may include a frame such as frame 3818. A lid such as lid 3816 may be mounted on frame 3818. Lid 3816 may, for example, be a rectangular lid having a horizontal planar top and four vertical planar sidewalls (as an example). Lid 3816 may be press fit onto frame 3818 or may be attached to frame 3818 using fasteners, welds, adhesive, etc.

Frame 3818 may have one or more vertical protrusions such as leg 3820. Each leg may be attached to printed circuit board 3812. As shown in FIG. 38, for example, printed circuit board 3812 may have a metal pad such as pad 3834 to which leg 3820 is attached using solder or other suitable attachment mechanism.

Fasteners such as male fastener 3822 and mating female fastener 3824 may also be used in attaching radio-frequency shielding can 3810 to printed circuit board 3812. Fasteners such as fastener 3822 and fastener 3824 may include engagement features such as holes, prongs, etc. These engagement features may allow fastener 3822 to mate with fastener 3824. With one illustrative arrangement, which is sometimes described herein as an example, fastener 3824 may be a standoff or other fastening structure that is attached to printed circuit board 3812 and structure 3822 may be a screw or other threaded fastening structure. Fastening structure 3824 may have a threaded bore such as threaded bore 3826 into which screw 3822 may be screwed. Screw 3822 may pass through an opening in frame 3818. When screw 3822 is tightened, screw 3822 may bear down on the upper surface of frame 3818, holding frame 3818 and legs such as leg 3820 against the upper surface of printed circuit board 3812.

Fastener 3824 may be attached to printed circuit board 3812 using solder, using a through-hole mounting arrangement with a fastening nut or other backside attachment structure, using adhesive, etc. With the illustrative arrangement shown in FIG. 38, printed circuit board 3812 has been provided with solder pad structures 3828. Solder 3830 has been used to attach horizontally protruding head portions 3832 of fastener 3824 to solder pad structure 3828.

If desired, traces such as conductive interconnect trace 3840 of FIG. 38 may be formed on the rear (lower) surface of printed circuit board 3812. The size and shape of fastener 3824 may define an outline (e.g., a circle) when viewed from vertical direction 3842. The outline of fastener 3824 may, in turn, define a footprint (e.g., a circular projected area) such as footprint 3836 on the back surface of printed circuit board 3812. In configurations of the type shown in FIG. 38 in which fastener 3824 does not protrude through the entire thickness of printed circuit board 3812, the entire surface area within footprint 3836 is available for interconnect traces and component mounting. For example, interconnect trace 3840 may have a portion such as portion 3838 that is located within footprint 3836.

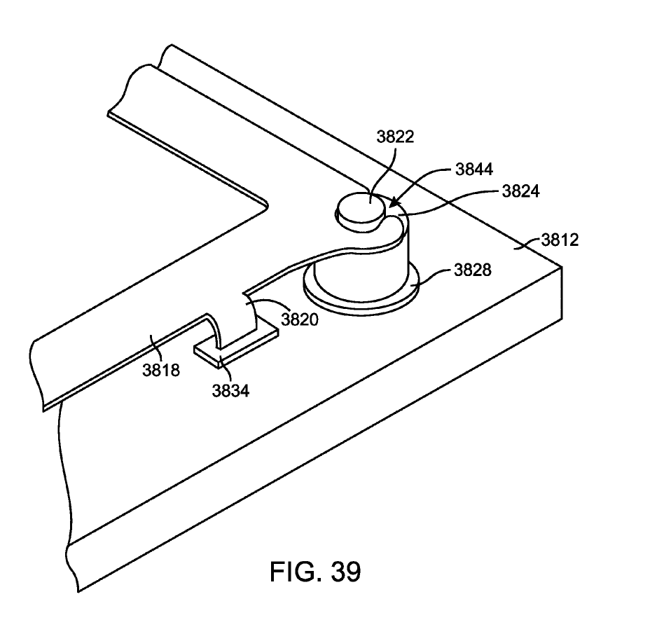

A perspective view of radio-frequency shielding can 3810 of FIG. 38 without lid 3816 is shown in FIG. 39. As shown in FIG. 39, frame 3818 may have an opening such as opening 3844 into which fastener 3822 may be received. Opening 3844 may be a round hole, a square hole, a U-shaped opening or other open-ended slot (as shown in FIG. 39) or an opening of any other suitable shape that allows fastener 3822 to hold frame 3818 to fastener 3824. An advantage of using a U-shaped slot of the type shown in FIG. 39 is that this type of opening may accommodate variations in the position of fastener 3822, thereby enhancing manufacturing tolerances. Fastener 3824 may have a substantially cylindrical shape (as shown in FIG. 39) or other shapes may be used for fastener 3828 (e.g., rectangular, hexagonal, etc.). Fasteners 3822 and 3824 may be formed from metal (as an example).

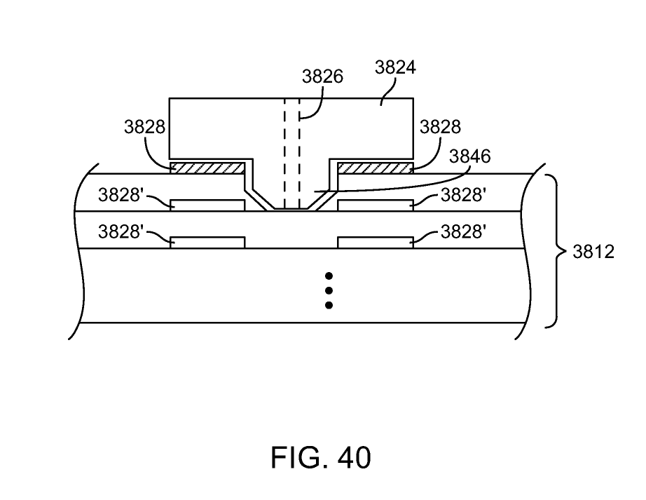

To enhance grounding and thermal conductivity in the vicinity of fastener 3824, ground layers such as layers 3828′ in FIG. 40 may be formed under solder pad 3828. Vias may be used to short layer 3828 to layers 3828′. Conductive traces in board 3812 may be used to ground layers 3828 and 3828′. Printed circuit board 3812 may contain one layer, two layers, three layers, four or more layers, etc. Each printed circuit board layer may include a layer of patterned conductor (e.g., copper traces). Vias may be used to interconnect patterned conductor layers. Solder pad 3828 may, as an example, have the shape of a circular ring with a central hole that accommodates protruding portion 3846 of fastener 3824. As shown in FIG. 40, layers 3828′ may have substantially the same size and shape as solder pad 3828 (as an example). If desired, layers 3828′ may have other shapes and sizes. The arrangement of FIG. 40 in which there are two or more layers 3828′ and each layer 3828′ has substantially the same size and shape of layer 3828 is merely illustrative.

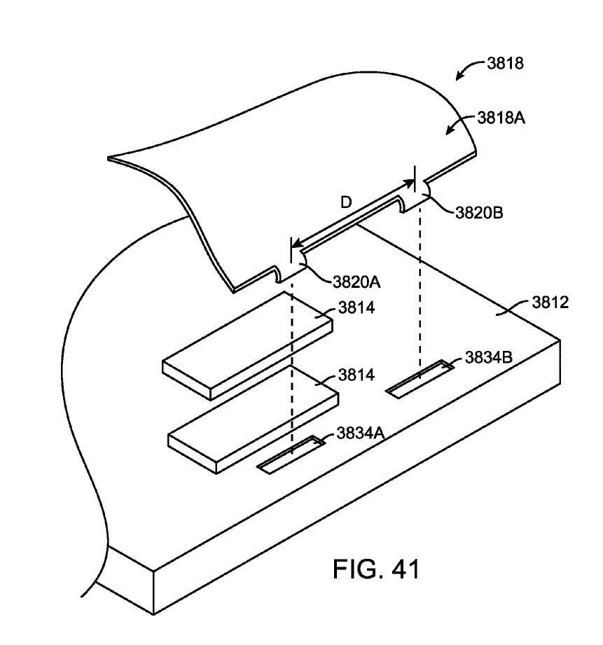

As shown in FIG. 41, frame 3818 may have two or more legs. For example, frame 3818 may have a rectangular ring shape with four edges such as edge 3818A. There may be two or more legs on each of the four edges such as legs 3820A and 3820B. Each of the legs may be soldered to a respective solder pad on printed circuit board 3812. For example, leg 3820A may be soldered to solder pad 3834A and leg 3820B may be soldered to solder pad 3834B. Solder pads 3834A and 3834B may be grounded. The legs and the fasteners used at the corners of the radio-frequency shielding can form attachment points to the printed circuit board. In this type of configuration, it may be desirable for the spacing D between adjacent attachment points (e.g., adjacent legs and/or fasteners) to be less than a quarter of a wavelength at electromagnetic frequencies of interest (e.g., less than a quarter of a wavelength A, where A is the wavelength of a radio-frequency signal that is associated with operation of a radio-frequency transceiver, radio-frequency amplifier, or other circuitry enclosed within the shielding can). If, for example, if is desired to block radio-frequency signals having a wavelength A or greater, distance D may be less than λ/4. The spacing between the fastener 3822 at each corner of frame 3818 and its nearest leg will also be less than λ/4 with this approach. By ensuring that the maximum lateral spacing between any two adjacent attachment points to the printed circuit board it less than λ/4, radio-frequency blocking performance at operating frequencies of interest may be enhanced.

To use space efficiently on printed circuit board 3812 and thereby minimize the volume consumed by electronic components and board 3812 when board 3812 is mounted in an electronic device housing, radio-frequency shielding can 3810 and other components can share a common mounting structure. For example, male fastener 3822 and mating female fastener 3824 may be located at a given one of the four corners of radio-frequency shielding can 3810. An additional component may have a corner that overlaps with the given corner of the can. A common mounting structure such as male fastener 3822 and mating female fastener may be used at the overlapping corner to secure both the radio-frequency shielding can and the additional component. The additional component may be a speaker, a microphone, a switch, a connector such as an input-output data port connector, other types of electrical components, etc.

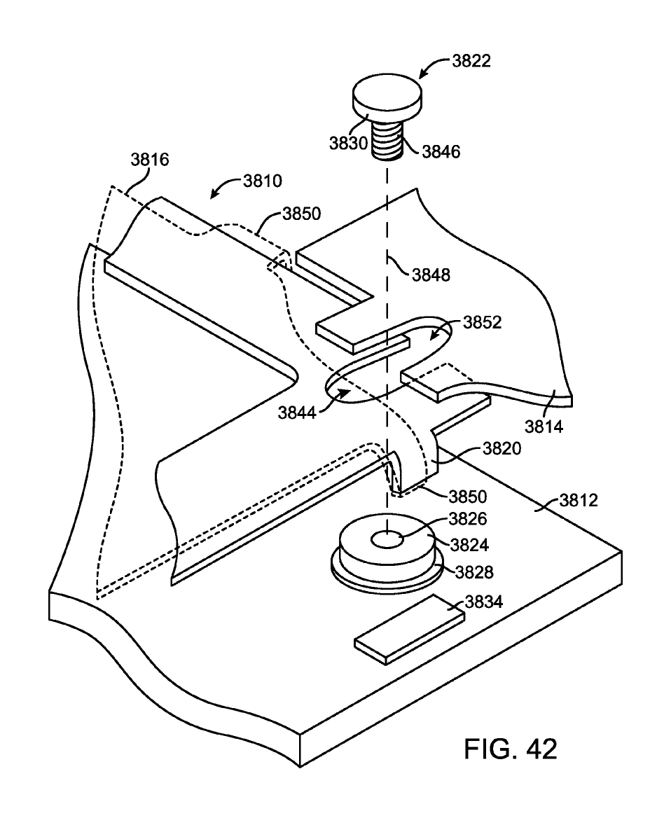

An arrangement in which a radio-frequency shielding can and another component share a common mounting structure and have overlapping corners is shown in FIG. 42. As shown in FIG. 42, radio-frequency shielding can 3810 may have a frame such as frame 3818 and a shield lid such as lid 3816. Frame 3818 may have leg such as leg 3820. Frame legs such as leg 3820 may be soldered or otherwise connected to solder pads such as solder pad 3834 on the surface of printed circuit board 3812. Lid 3816 may also have legs such as legs 3850. Lid legs 3850 can be soldered to solder pads such as solder pad 3834 adjacent to leg such as frame legs 3820, if desired.

Frame 3818 may have fastener openings such as U-shaped fastener opening 3844. Overlapping component 3814 may also have fastener openings such as U-shaped fastener opening 3852. Fastener opening 3844 and fastener opening 3852 may overlap at vertical fastener attachment axis 3848. Component 3814 may be mounted on top of frame 3818 or, if desired, frame 3818 may be mounted on top of component 3854.

During assembly, fastener 3822 may be screwed into fastener 3824 along attachment access 3848, so that the threads on shaft portion 3846 of fastener 3822 mate with the threads in threaded bore 3826 of fastener 3824 on printed circuit board 3812. As fastener 3822 is screwed into fastener 3824, screw head portions 3830 of fastener 3822 may be forced downwards along axis 3848 towards printed circuit board 3812. This compresses component 3814 and radio-frequency shielding frame 3818 between fastener 3822 and fastener 3824 and holds component 3814 and frame 3818 in place on printed circuit board 3812. By mounting both radio-frequency shielding can 3810 and component 3854 to printed circuit board 3812 using a common attachment point, board area is used efficiently and the number of fasteners that are mounted to board 3812 is minimized.

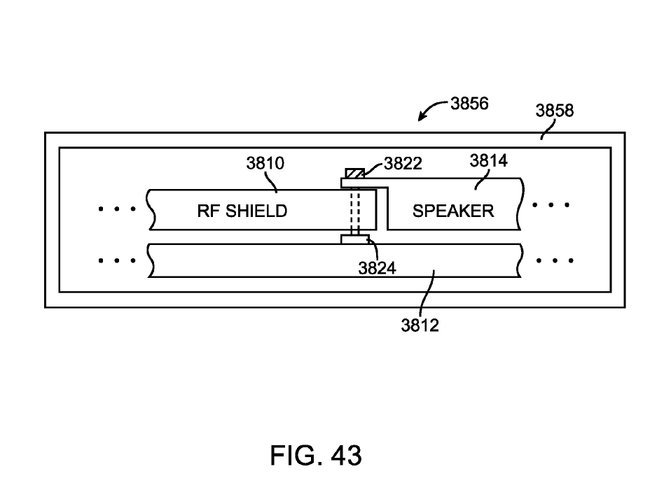

A side view of the interior portion of an electronic device that includes a radio-frequency shielding can and at least one overlapping component is shown in FIG. 43. As shown in FIG. 43, electronic device 3856 may have a housing such as housing 3858. Housing 3858 may be formed form plastic, metal, ceramics, glass, composites, other suitable materials, and combinations of these materials. Housing 3858 may include sidewalls and internal support structures or may be formed using a unibody configuration (as examples).

Printed circuit board 3812 may be mounted within housing 3858. One or more radio-frequency transceivers, radio-frequency amplifiers, and other components that generate radio-frequency signals and/or that are adversely affected by radio-frequency interference may be enclosed within radio-frequency shielding cans such as radio-frequency shielding can 3810. Cans such as can 3810 may have any suitable shape. For example, can 3810 may be rectangular when viewed from above and may have four corners. Component 3814, which may be an electrical component such as a speaker, a microphone, a switch, a connector, or other component, may have one or more corners or other portions that overlap radio-frequency shielding can 3810.

As described in connection with FIG. 42, space may be conserved by using a single male fastener such as fastener 3822 and a single female fastener such as female fastener 3824 or other common mounting structure to attach both component 3814 and radio-frequency shielding can 3810 to printed circuit board 3812.

Electronic devices often contain batteries. For example, cellular telephone, media players, and portable computers generally contain batteries.

A battery may have positive and negative electrode layers that separated by an insulating layer. The electrode layers can be rolled into a cylindrical shape to form a jelly-roll electrode structure. Positive and negative battery terminals can be connected to the positive and negative electrodes. The jelly-roll electrode structure and the battery terminals may then be wrapped in a battery pouch formed from a layer of metalized insulator. After wrapping the electrode structure in the battery pouch, the edges of the pouch are folded inwards against the pouch. The edges may be held in place using strips of polyimide tape. The battery pouch with taped edge forms a completed battery pack. In some situations, the battery pack is mounted directly in an electronic device. In other situations, the battery is wrapped in an adhesive label.

Conventional batteries such as these are not always satisfactory. For example, the adhesive label may be used to provide the battery with required regulatory information, but adds undesired thickness to the battery pack. The strips of polyimide tape that are used to hold the edges of the battery pouch in place are sometimes prone to peeling. Conventional labels and polyimide tape may also be visually unappealing when a device housing is opened to replace or repair a battery.

It would therefore be desirable to be able to provide improved batteries for electronic devices.

In accordance with one embodiment, an electronic device may be provided with a battery having electrode structures. The electrode structures may be formed from positive and negative electrode layers that are laminated to opposing sides of a separator layer. The positive and negative electrode layers and the separator layer may be used to form jelly-roll-type battery electrode structures.

A battery pouch may be formed from a sheet of metalized polymer. The metalized polymer may include one or more clear polymer layers, a layer of ink, and a layer of metal. The battery pouch sheet may be folded along one edge and sealed along the remaining edges. The jelly-roll electrode structures may be encased within the battery pouch.

Regulatory artwork may be printed directly on the metalized polymer of the battery pouch sheet. The regulatory artwork may be formed from one or more layers of ink. For example, a dark background ink layer may be printed on the battery pouch sheet and a light patterned foreground ink layer may be printed on the battery pouch sheet on top of the background ink layer. The patterned foreground ink may include text, logos, icons, and other information.

A single sheet of adhesive-backed polymer may be used to secure the edges of the battery pouch. The adhesive-backed polymer sheet may have a window such as a rectangular window. The window may be aligned with the printed regulatory artwork, so that the regulatory artwork is visible through the window.

In accordance with an embodiment, a battery pack is provided that includes battery electrode structures, a battery pouch formed from a polymer sheet, and a layer of patterned ink on the polymer sheet.

In accordance with another embodiment, a battery is provided wherein the polymer sheet includes a metalized polymer sheet having layer of metal and a layer of polymer.

In accordance with another embodiment, a battery is provided wherein the metalized polymer sheet includes a layer of ink.

In accordance with another embodiment, a battery is provided wherein the polymer sheet includes a layer of metal and a layer of polymer and wherein the battery pack further includes a layer of background ink on the layer of polymer under the layer of patterned ink.

In accordance with another embodiment, a battery is provided wherein the layer of background ink includes a substantially rectangular printed black ink layer and wherein the layer of patterned ink includes white ink.

In accordance with another embodiment, a battery is provided wherein the background ink has a color and wherein the layer of patterned ink includes text and is formed from a material having a color that contrasts with the color of the background ink.

In accordance with another embodiment, a battery is provided that also includes an adhesive-coated polymer sheet with a window opening that is wrapped around battery pouch so that the layer of patterned ink is visible through the window opening.

In accordance with another embodiment, a battery is provided that also includes an adhesive-coated polymer sheet with a window opening that is wrapped around battery pouch so that the layer of patterned ink is visible through the window opening.

In accordance with another embodiment, a battery is provided wherein the polymer sheet include a layer of polyimide.

In accordance with another embodiment, a battery is provided wherein the polymer sheet that forms the battery pouch includes a layer of nylon and a layer of aluminum and has a substantially rectangular window opening.

In accordance with another embodiment, a battery is provided wherein the battery electrode structures include jelly-roll electrode structures.

In accordance with an embodiment, a method for forming a battery pack is provided that includes forming battery electrode structures, enclosing the battery electrode structures in a battery pouch having a folded rear edge and left, right, and front edges, and securing the front, left, and right edges of the battery pouch using a unitary polymer sheet that has a window opening.

In accordance with another embodiment, a method is provided that also includes printing regulatory information on the battery pouch with patterned ink.

In accordance with another embodiment, a method is provided wherein securing the front, left, and right edges of the battery pouch includes aligning the window opening so that the patterned ink is visible through the window opening.

In accordance with another embodiment, a method is provided wherein securing the front, left, and right edges of the battery pouch includes wrapping portions of the single polymer sheet around the battery pouch and attaching the polymer sheet to the battery pouch with adhesive.

In accordance with another embodiment, a method is provided that also includes printing a background layer of ink onto the battery pouch, wherein the patterned ink is printed on the background layer of ink.

In accordance with an embodiment, a battery is provided that includes a jelly-roll battery electrode structure, a battery pouch formed from a metalized polymer battery pouch sheet that encloses the jelly-roll battery electrode structure, and patterned ink on the metalized polymer battery pouch sheet.

In accordance with another embodiment, a battery is provided that also includes an adhesive-backed polymer sheet that secures folded edges of the battery pouch and that has a rectangular window opening through which the patterned ink is visible.

In accordance with another embodiment, a battery is provided wherein the battery pouch sheet includes a layer of ink.

In accordance with another embodiment, a battery is provided that also includes a background layer of ink having a first color that is printed on the metalized polymer battery pouch sheet, wherein the patterned ink has a second color that contrasts with the first color add wherein the patterned ink includes text printed on the background layer of ink.

In accordance with these embodiments, batteries are used in electronic devices. For example, batteries may be used in portable electronic devices such as cellular telephones, handheld computers, media players, portable computers, and other electronic equipment.

A battery has a positive electrode and a negative electrode. For example, in a lithium-ion battery, the positive electrode, which is sometimes referred to as the cathode, includes lithium, whereas the negative electrode, which is sometimes referred to as the anode, contains carbon. In lithium polymer batteries, which are sometimes described herein as an example, the positive and negative electrodes are laminated to opposing sides of a polymer separator sheet. For example, a lithium polymer battery may have a positive electrode layer that is formed from LiCoO2 or LiMnO4, a separator layer that is formed from a polymer such as polyethyleneoxide, and a negative electrode layer that contains lithium or a compound of lithium and carbon (as examples). Other types of electrodes and separators may be used. These are merely illustrative examples.

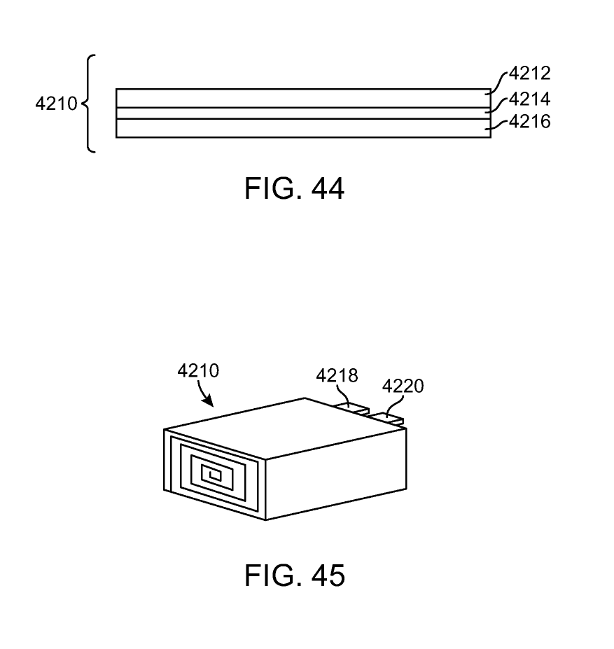

A side view of an illustrative set of battery electrodes and an associated separator layer is shown in FIG. 44. As shown in FIG. 44, electrode structures 4210 may include electrodes 4212 and 4216 and separator 4214. Positive electrode layer 4212 may be attached to the upper surface of separator layer 4214 and negative electrode layer 4216 may be attached to the lower surface of separator layer 4214. The layers of electrode structures 4210 are typically thin (e.g., fractions of a millimeter).

To ensure that the battery that is formed from electrode structures 4210 has sufficient capacity, the area of the electrode structures may be many square centimeters in size (as an example). It may therefore be desirable to fold electrode structures into a more compact shape. For example, it may be desirable to wrap electrode structures into a shape of the type shown in FIG. 45. This type of electrode configuration, which is sometimes referred to as a jelly-roll shape, reduces the footprint of the battery and provides the battery with a size and shape that is compatible with typical device form factors.

As shown in FIG. 45, jelly-roll type electrode structures 4210 may be provided with positive and negative battery terminals such as terminals 4218 and 4220. Positive battery terminal 4218 may be electrically connected to positive electrode 4212. Negative battery terminal 4220 may be electrically connected to negative electrode 4216.

Before being used in an electronic device, jelly-roll electrode structures 4210 of FIG. 45 may be sealed in a battery pouch. The battery pouch may, for example, be formed from a polymer that is lined with a metal such as aluminum.

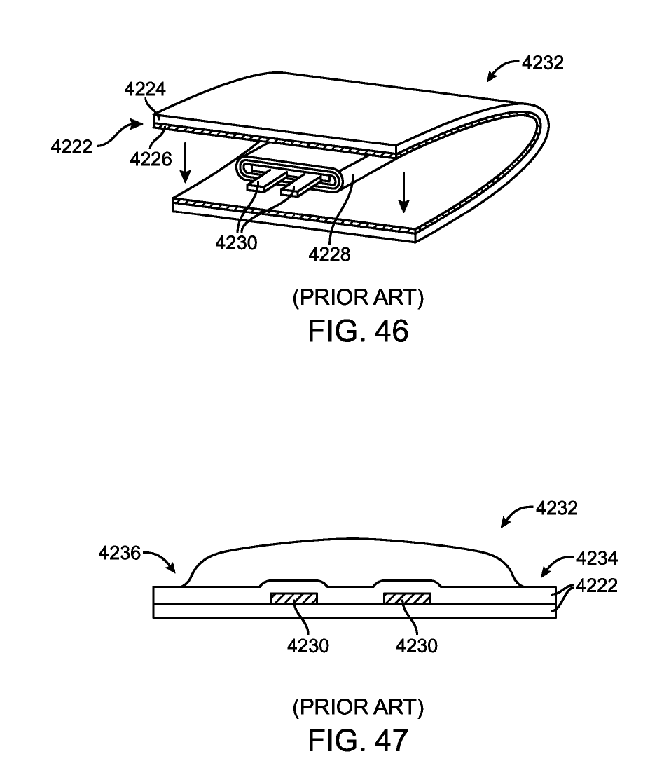

A conventional battery pouch is in a partially assembled state is shown in FIG. 46. As shown in FIG. 46, battery pouch 4232 may be formed from battery pouch sheet 4224. Battery pouch sheet 4224 may be used to form a battery pouch that encloses jelly-roll electrode structures 4228. Terminals 4230 may form the battery terminals for a battery pack when assembly is complete.

Battery pouch sheet 4224 has outer insulating layer 4224 and an inner conductive layer 4226. Outer layer 4224 may be formed from nylon or nylon coated with a layer of polypropylene or polyester. Inner layer 4222 may be formed from aluminum.

During assembly, battery pouch sheet 4222 may be folded on itself along its rear edge as shown in FIG. 46. The remaining edges of battery pouch sheet 4222 may then be sealed to form battery pouch 4232. FIG. 47 shows an end view of conventional battery pouch 4232 after the edges of the pouch have been sealed.

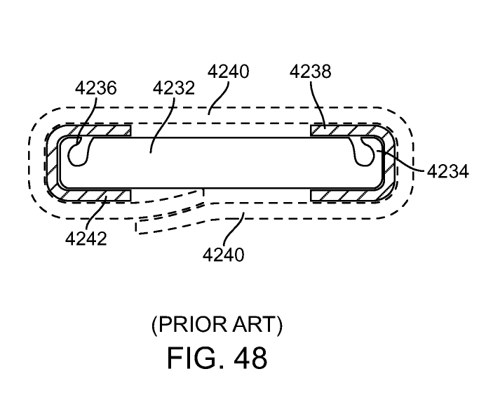

After forming the conventional battery pouch of FIG. 47, a conventional battery pack may be formed by folding up the edges of the battery pouch and securing the folded edges with strips of polyimide tape. A cross-sectional end view of conventional battery pouch 4232 of FIG. 47 after edges 4234 and 4236 have been folded against the sides of pouch 4232 and secured with strips of polyimide tape is shown in FIG. 48. As shown in FIG. 48, left edge 4236 of battery pouch 4232 may be folded against the left side of battery pouch 4232 and may be secured with left side polyimide tape strip 4242. Right side polyimide tape strip 4238 may be used to secure folded right edge 4234 of battery pouch 4232.

In some conventional battery packs, a printed adhesive label such as label 4240 of FIG. 48 may be wrapped around the exterior of the battery pouch. Label 4240 may contain printed information that is used to comply with labeling regulations, but the presence of label 4240 tends to add about 0.2 mm of thickness to the battery pack. Label 4240 and tape 4238 and 4242 may also be prone to peeling and may not be aesthetically appealing.

To help minimize battery pack thickness and to improve battery pack appearance, labeling information may be printed directly on a battery pouch. For example, a first layer of ink may be printed over some or all of the battery pouch to form a background. This background ink may, for example, be black or may have other suitable dark or light colors. A contrasting foreground ink may be printed on the background layer in a pattern that forms text, logos, icons, graphics, and other suitable labeling information. If, for example, the background ink is black or has another dark color, the foreground ink may be white or may have another light color. If the background is light in color, the foreground ink may be dark. Contrasting color pairs (e.g., orange and blue) may also be used for the background and foreground ink layers. The ink may be formed from dye, pigment, paint, colored adhesive, colored polymers, or other suitable materials.

Any suitable techniques may be used to deposit the ink layers on the battery pouch. For example, the ink layers may be deposited by pad printing, using a paint brush, screen printing, dripping, spraying, ink-jet printing, etc.

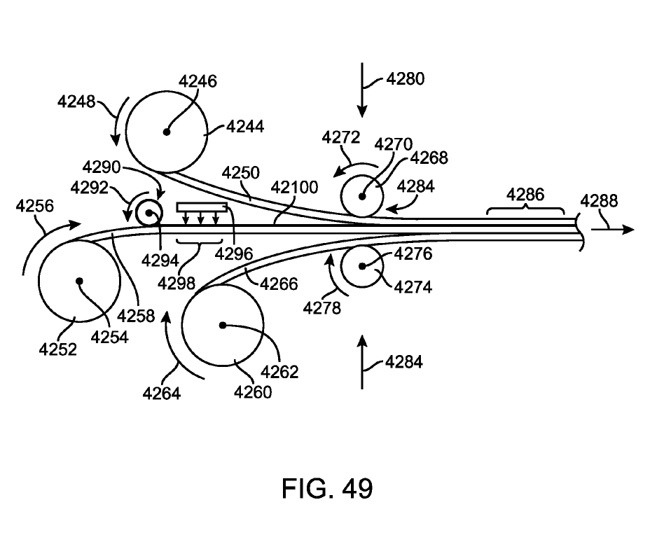

In addition to forming printed information directly on the battery pouch, the battery pouch can be formed from an attractive material such as a battery pouch sheet (layer) that contains a layer of black ink or ink of other colors. FIG. 49 shows how a battery pouch sheet may be formed using strips of flexible material that are dispensed from a set of rollers.

As shown in FIG. 49, a first roller such as roller 4244 may rotate about rotational axis 4246 in direction 4248 and may dispense first sheet 4250. Sheet 4250 may be, for example, a sheet of aluminum or other metal or conductive material. A second roller such as roller 4252 may rotate about rotational axis 4254 in direction 4256 and may dispense second sheet 4258. Sheet 4258 may be, for example, a layer of nylon or other insulator. If desired, a third roller such as roller 4260 may rotated about rotational axis 4262 in direction 4264 and may dispense third sheet 4266. Sheet 4266 may be a layer of polypropylene, polyester, or other suitable insulating material (as examples).

Pressure rollers 4268 and 4274 may compress sheets 4250, 4258, and 4266 together to form a unitary battery pouch sheet in region 4286. In particular, pressure roller 4268 may rotate about rotational axis 4270 in direction 4272 and may press downwards on the sheets in direction 4280. Pressure roller 4274 may rotate about rotational axis 4276 in direction 4278 and may press upwards on the sheets in direction 4282. The opposing forces from the pressure rollers squeeze the sheets of the battery pouch sheet together in region 4284 so that sheets 4250, 4258, and 4266 form respective layers of a single battery pouch sheet in region 4286. The battery pouch sheet may be dispensed from the equipment of FIG. 49 in direction 4288.

The insulating layers of the battery pouch sheet such as layer 4258 and layer 4266 may be colored (e.g., with a black dye or other coloring material) or may be clear. If desired, a colored coating layer of ink or other coloring materials may be incorporated into the battery pouch sheet. When the insulating layers of the battery pouch sheet are formed from clear materials, the presence of the coloring layer may help improve the aesthetics of the battery.

With one suitable arrangement, layer 4266 may be formed from a transparent layer of polypropylene or polyester and layer 4258 may be formed from a transparent layer of nylon. These transparent insulating sheets may be rendered opaque by coating one or both of these sheets with black ink (as an example). As shown in FIG. 49, layer 4258 may be coated with a layer of black ink 42100 using ink dispensing roller 4290. Roller 4290 may rotate about rotational axis 94 in direction 4292 to coat layer 4258 with ink layer 42100 or a layer of other suitable opaque substance. The black ink layer may provide the battery pouch with a matte black appearance. If desired, a heat source such as heater 4296 may be used to heat ink 42100 in region 4298 and thereby help cure the ink before reaching pressure rollers 4268 and 4274. Other types of curing scheme may be used if desired (e.g., ultraviolet light curing, etc.). The ink (e.g., the matte black ink) that is used in forming the opaque ink layer in the battery pouch sheet may be formed from any suitable substance (e.g., dye, pigment, paint, colored adhesive, particles of carbon or other colored particles, polymer resins, etc.).

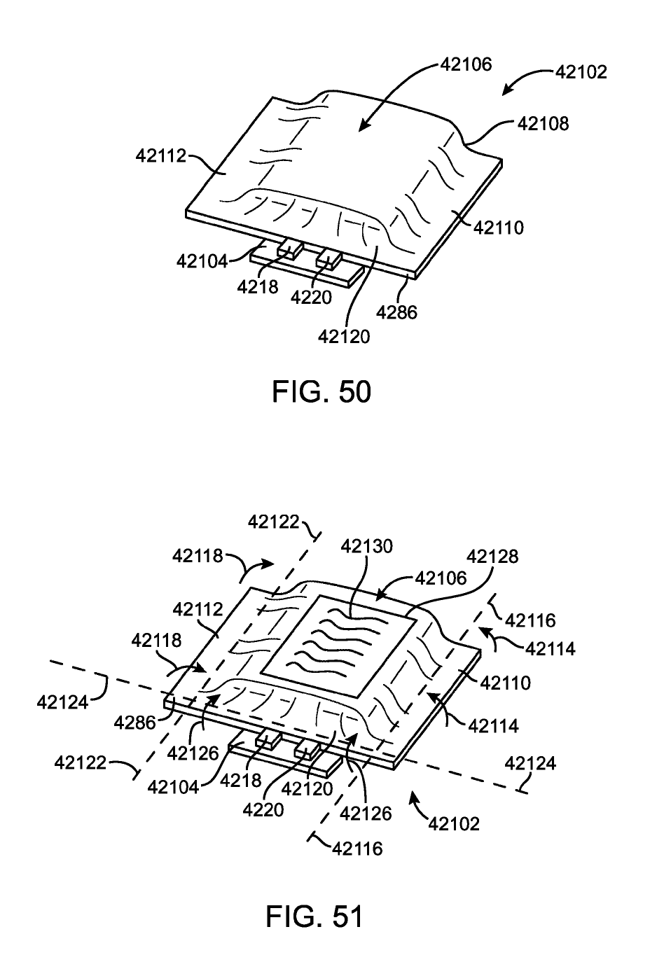

FIG. 50 shows how a battery pouch such as battery pouch 42102 may be formed from battery pouch sheet 86 of FIG. 49. As shown in FIG. 50, battery pouch sheet 86 may be folded to form battery pouch 42102. Battery electrodes such as jelly-roll electrode structures 4210 of FIG. 45 may be enclosed within pouch 42102 so that battery electrodes 4218 and 4220 protrude from front battery pouch edge 42120. If desired, a battery protection circuit such as battery protection circuit 42104 may be electrically connected to electrodes 4218 and 4220.

Battery pouch sheet 4286 may be folded on itself along rear battery pouch edge 42108. If the jelly-roll electrode structures have a relatively flat shape, the folding process will form a substantially planar upper surface 42106 on battery pouch 42102. Electrode structures with different shapes will tend to result in different battery pouch shapes.

In the FIG. 50 example, the upper and lower layers of folded sheet 4286 that lie along left battery pouch edge 42112, right battery pouch edge 42110, and front battery pouch edge 42120 may be sealed to form an environmentally sealed enclosure for the battery electrode structures. Sealing may be performed using adhesive, heat, pressure, crimping, etc.

After the edges of battery pouch 42102 have been sealed, these edges may be folded inward, as shown in FIG. 51. In particular, right edge 42110 of battery pouch 42102 may be folded upwards against the right side of battery pouch 42102. In making this fold, edge 42110 may be moved in direction 42114 about fold axis 42116. Left edge 42112 of battery pouch 42102 may be folded upwards against the left side of battery pouch 42102 by folding edge 42112 in direction 42118 about fold axis 42122. Front edge 42120 may be folded in direction 42126 against the front of battery pouch 42102 about fold axis 42124.

To provide a thin and attractive label for battery pouch 42102, one or more layers of ink (or other suitable materials) may be deposited on the surfaces of battery pouch 42102. As described in connection with FIG. 49, battery pouch 42102 may be formed from a matte black sheet of battery pouch material. It may therefore be desirable to print labeling information on battery pouch 42102 using an ink of a contrasting color such as white. If desired, a background layer of ink may be deposited on the surface of battery pouch 42102 to form a contrasting layer that helps a user view the lettering, logos, icons, and other printed information of a foreground layer of ink. This type of arrangement is shown in FIG. 51.

As shown in the example of FIG. 51, a background layer 42128 of black ink (or ink of a different color) has been formed in region 42106 on the front surface of battery pouch 42102. Layer 42128 may be, for example, about 20 microns thick, less than 20 microns thick, less than 10 microns thick, etc. The shape of layer 42128 may be, for example, a rectangle. Foreground ink layer 42130 may be formed on top of some or all of background layer 42128. Ink layer 42130 may be, for example, about 20 microns thick, less than 20 microns thick, less than 10 microns thick, etc. Foreground ink layer 42130 may be formed from an ink having a color that contrasts with background layer 42128. For example, if background ink layer 42128 is matte black, foreground layer 42130 may be white or may have another light color. Layer 42130 may be patterned to form text (e.g., regulatory text), icons (e.g., regulatory icons), other information that is needed for regulatory compliance, informative information about the type and capacity of the battery, manufacturing information, etc. Background ink layer 42128 and foreground ink layer 42130 may be formed using screen printing, pad printing, brushes, ink jet printing, dripping, spraying, etc.

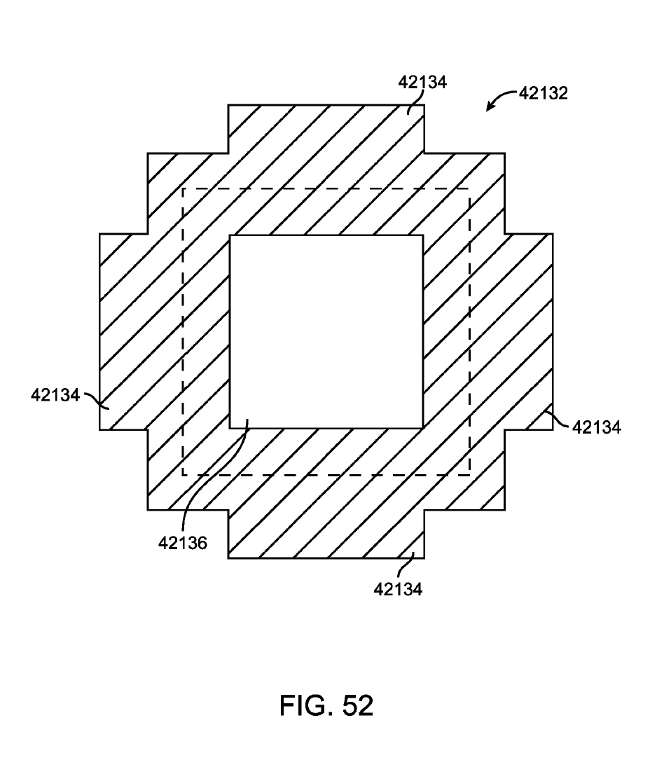

The edges of battery pouch 42102 may be secured using polyimide tape or other suitable strips of adhesive-backed material. To enhance battery aesthetics and improve manufacturing tolerances, it may be desirable to form the edge-securing polymer structures for the battery from a single unitary sheet of polymer such as adhesive-backed polyimide. An example of an illustrative pattern that may be used in forming a patterned polymer sheet of this type is shown in FIG. 52. Other patterns may be used. The pattern shown in FIG. 52 is merely an example.

As shown in the example of FIG. 52, sheet 42132 may have a substantially rectangular shape with extending portions such as tabs 42134. Sheet 42132 may be formed from polyimide, polyimide coated with a layer of pressure sensitive adhesive (PSA) or other adhesive, polymers other than polyimide, or other suitable materials. An opaque material such as black ink may be printed on sheet 42132 (e.g., to match the color of the battery pouch ink).

A window such as window 42136 may be formed by cutting an opening in the center of sheet 42132. The opening may be rectangular, oval, or may have other suitable shapes. A rectangular window opening in sheet 42132 may be used, for example, to match a corresponding rectangular layer of background ink such as background ink layer 42128 of FIG. 51. The size of window 42136 may be, for example, slightly smaller than the size of background ink layer 42128, so that the inner edges of window 42136 cover the peripheral edges of background ink layer 42128.

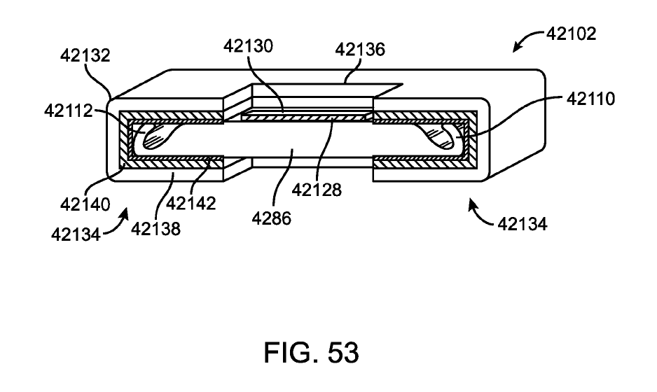

During assembly, the edges of polymer sheet 42132 may be wrapped over the folded edges of battery pouch 42102. A cross-sectional perspective view of battery pouch 42102 after polymer sheet 42132 has been used to secure the folded edges of the battery pouch and thereby complete formation of the battery pack is shown in FIG. 53. As shown in FIG. 53, folded battery pack edges such as edges 42110 and 42112 may be secured by polymer sheet 42132 by wrapping tabs 42134 around the edges (e.g., the front, rear, left, and right edges) of the battery pouch. This type of arrangement may help to ensure that the edges of the battery pack and their seals are well protected while providing good dimensional control and protection for battery protection circuit 42104.

A layer of an opaque material such as matte black ink layer 42140 may be formed on polymer sheet 42132 to hide the folds of the battery pouch edges from view. A layer of adhesive such as adhesive 42142 may be used to secure polymer sheet 42132 to the battery pouch sheet 4286. Window 42136 may be aligned so that background ink layer 42128 and foreground patterned ink layer 42130 are framed within window 42136 (as shown in FIG. 53) or so that the inner edges of window 42136 slightly overlap the periphery of background link layer 42128. The size of window 42136 is preferably large enough to avoid obscuring foreground ink 42130. This allows the regulatory artwork on the front surface of the battery to be viewed through the window.

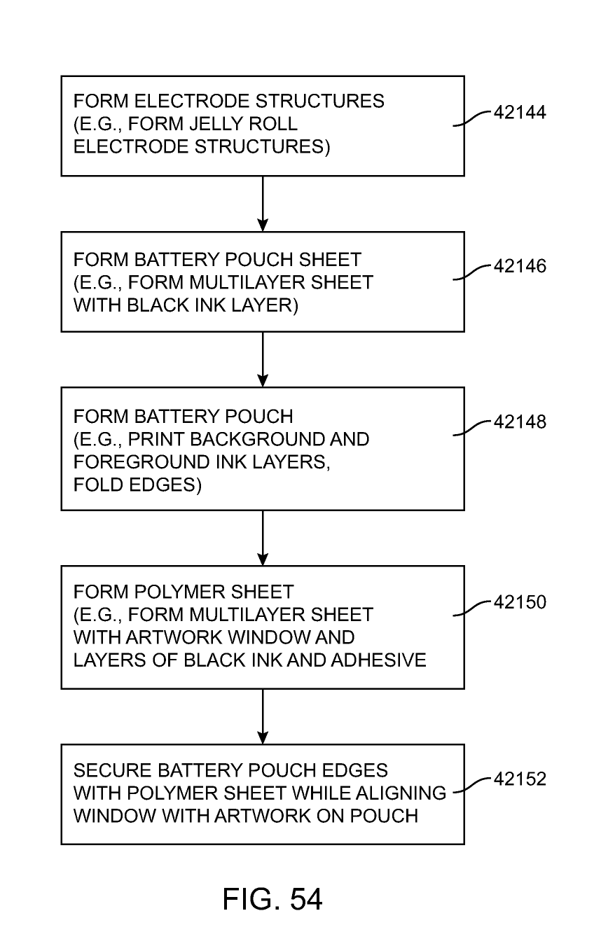

A flow chart of illustrative steps involved in forming a battery pack such as the battery pack of FIG. 53 is shown in FIG. 54. At step 42144, battery electrode structures may be formed. For example, positive and negative electrodes may be laminated to opposing sides of a separator layer as shown in FIG. 44. A jelly-roll electrode structure may then be formed by folding up the electrodes, as described in connection with FIG. 45.

At step 42146, a metalized polymer battery pouch sheet may be formed. As described in connection with FIG. 49, the battery pouch sheet may include a layer of metal such as aluminum or other conductive materials formed on one or more polymer layers (e.g., transparent polymer layers). A layer of black ink may be used to coat at least one of the layers of material in the metalized polymer battery pouch sheet to provide the metalized polymer battery pouch sheet with a desired appearance (e.g., a matte black finish).

At step 42148, a battery pouch such as battery pouch 42102 of FIG. 50 may be formed by printing background ink and foreground ink layers onto the battery pouch sheet, by folding the battery pouch sheet on itself along a rear edge, and by folding the edges of the battery pouch as described in connection with FIG. 51.

At step 42150, a polymer sheet with a window such as sheet 42132 of FIG. 52 may be formed. For example, a layer of polymer may be coated with black ink and adhesive and a rectangular opening may be cut out to form a rectangular window such as window 42136 of FIG. 52.

At step 42152, the window in the polymer sheet may be aligned with the printed ink layers on the surface of the battery pouch while the edges of the polymer sheet (e.g., tabs 42134 of FIG. 52) are wrapped around the edges of the battery pouch (e.g., the front, rear, left, and right edges of the battery pouch). This forms a completed battery pack of the type shown in FIG. 53.

Electronic devices such as computers, cellular telephones, and other devices typically contain printed circuit boards. Electrical components such as integrated circuits, switches, buttons, input-output port connectors, resistors, capacitors, inductors, and other discrete components may be mounted to a printed circuit board.

Rigid printed circuit boards may be formed from materials such as fiberglass-filled epoxy. In typical manufacturing environments, printed circuit boards are cut from large panels of printed circuit board material. Break out tabs may be used to secure the boards during processing. After processing is complete, the tabs may be broken to release the boards from the panel. Portions of the boards where the tabs are broken generally exhibit rough edges.

Many modern electronic devices use flexible printed circuits (“flex circuits”). Circuit components may be mounted on flex circuits. Flex circuits may also contain traces that are used in forming signal buses. Because flex circuits are thin and flexible, buses formed from flex circuits are often used in routing signals between different portions of compact electronic devices.

In some applications, it is necessary to route a flex circuit near the broken tab of a printed circuit board. In this type of environment, the flex circuit may become exposed to rough printed circuit board edges. If care is not taken, the rough edges of the board may damage the flex circuit. It can also be difficult to control the bend radius of the flex circuit accurately.

It would therefore be desirable to provide improved ways in which to mount flex circuits in electronic devices that contain printed circuit boards.

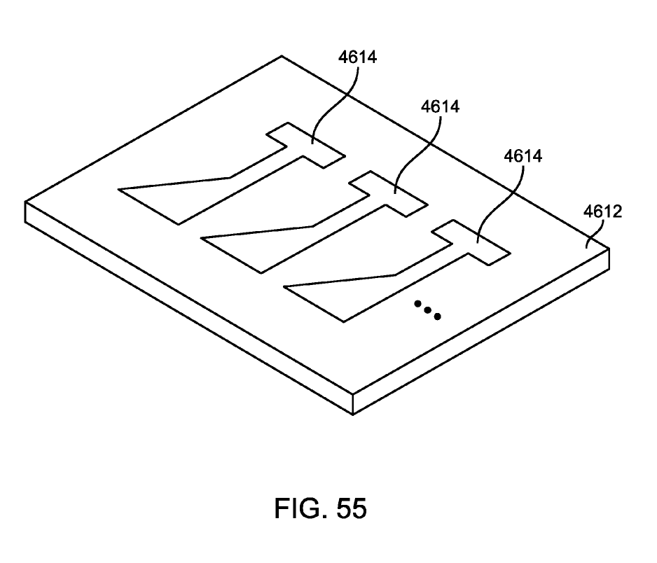

As described in connection with FIGS. 55-60, this can be accomplished by providing electronic devices (e.g., device 10 of FIG. 1) with printed circuit boards on which integrated circuits and other components are mounted. During manufacturing, multiple printed circuit boards may be formed from a common panel of printed circuit board material. Milling machines and other tools may be used in cutting printed circuit boards from the panel.

Break out tabs may be used to retain a printed circuit board within a panel of printed circuit board material during manufacturing. The break out tabs may be broken when it is desired to release the printed circuit board from the panel. Broken break out tabs may have jagged edges.

Flex circuits may be used to interconnect displays and other components and circuitry mounted on printed circuit boards. Bumpers such as bumpers formed from elastomeric bumper members may be mounted over the edges of printed circuit boards. Flex circuits may be routed over the bumper members. A bumper member may protect a flex circuit from roughness associated with a broken break out tab and may help create a defined bend radius in the flex circuit.

According to an embodiment, a printed circuit board bumper is provided that includes a member having first portions that define a groove that receives an edge of a printed circuit board and having second portions that define a curved outer surface opposite the groove.

According to another embodiment, a printed circuit board bumper is provided wherein the member includes an elastomeric substance.

According to another embodiment, a printed circuit board bumper is provided wherein the member includes silicone.

According to another embodiment, a printed circuit board bumper is provided wherein the member includes an elastomeric member, wherein the groove has first and second opposing parallel planar sidewalls and a perpendicular rear planar wall.

According to another embodiment, a printed circuit board bumper is provided wherein the second portions are configured to form the curved outer surface in a half cylinder shape.

According to an embodiment, apparatus is provided that includes a printed circuit board having an edge, a bumper mounted to the edge, wherein the bumper has an exterior surface, and a flex circuit having at least a portion that lies on the exterior surface of the bumper.

According to another embodiment, apparatus is provided wherein the bumper includes a groove that receives the edge.

According to another embodiment, apparatus is provided wherein the bumper includes an elastomeric bumper member.

According to another embodiment, apparatus is provided wherein the bumper includes an elastomeric member with a groove that receives the edge and wherein the exterior surface includes a curved surface.

According to another embodiment, apparatus is provided wherein at least part of the edge of the printed circuit board includes a broken break out tab and wherein the bumper is mounted to the edge over the broken break out tab.

According to another embodiment, apparatus is provided wherein the bumper includes an elastomeric member with a groove that receives the part of the edge that includes the broken break out tab and wherein the exterior surface includes a curved surface.

According to another embodiment, apparatus is provided wherein at least part of the edge of the printed circuit board includes a recessed portion and a broken break out tab within the recessed portion and wherein the bumper is mounted to the edge over the broken break out tab in the recessed portion of the printed circuit board edge.

According to another embodiment, apparatus is provided wherein the bumper includes an elastomeric bumper member.

According to another embodiment, apparatus is provided that also includes a first component, and a second component, wherein the second component is mounted to the printed circuit board, wherein the flex circuit has at least a first end that is connected to the first component, wherein the flex circuit has at least a second end that is connected to the printed circuit board and that is electrically connected to the second component, and wherein the portion of the flex circuit that lies on the exterior surface of the bumper includes a middle portion between the first and second ends.

According to another embodiment, apparatus is provided wherein the first component includes a display and wherein the second component includes an integrated circuit mounted to the printed circuit board.

According to an embodiment, an electronic device, is provided that includes a component, a rigid printed circuit board having an edge, an elastomeric member mounted to the edge, and a flex circuit that is connected to the component and the rigid printed circuit board and that has a portion that lies on the elastomeric member.

According to another embodiment, an electronic device is provided wherein the flex circuit includes a sheet of polymer with conductive traces and wherein the component includes a display.

According to another embodiment, an electronic device is provided wherein the rigid printed circuit board has a broken break out tab portion along the edge and wherein the elastomeric member covers the broken break out tab portion.

According to another embodiment, an electronic device is provided wherein the elastomeric member has a groove that receives the broken break out tab portion.

According to another embodiment, an electronic device is provided wherein the component includes a display, wherein the elastomeric member includes a curved surface, and wherein the portion of the flex circuit that lies on the elastomeric member includes a bent flex circuit portion that lies on the curved surface.

Electronic devices such as cellular telephones, computers, media players, and other equipment often contain printed circuit boards. Some printed circuit boards, such as printed circuit boards formed from substrates of epoxy or fiberglass-filled epoxy, are rigid. Flexible printed circuit boards (“flex circuits”) may be formed from flexible sheets of polymer such as sheets of polyimide. Printed circuit boards that include both rigid printed circuit board portions and flexible portions (i.e., flex circuit “tails”) are sometimes referred to as rigid flex.

In an electronic device, components such as integrated circuits, discrete components such as resistors, capacitors, and inductors, surface mount technology (SMT) components, switches, input-output port connectors, and other electrical components are mounted on printed circuit boards. Components may be mounted using solder (as an example).

It is often desirable to electrically interconnect components that are mounted on different printed circuit boards or that are located in different areas within an electronic device. Conductive traces on printed circuit boards may be used in forming buses and other interconnection paths. In a typical arrangement, a flex circuit may contain multiple parallel conductive traces that form a parallel or serial bus. Different parts of the flex circuit (e.g., opposing ends of a bus) can be attached to components within an electrical device. To accommodate assembly requirements, the flex circuit can be bent. This approach may be used for the flex circuit portions of a rigid flex structure.

To satisfy high-volume manufacturing requirements, multiple identical printed circuit boards may be produced in parallel. With one suitable arrangement, which is sometimes described herein as an example, multiple rigid printed circuit boards may be formed from a panel of rigid printed circuit board bard material. As shown in FIG. 55, for example, printed circuit boards 4614 may be formed from a larger panel of printed circuit board material such as printed circuit board panel 4612. Printed circuit boards 4614 may be rectangular, may have curved sides, may have a polygonal shape with more than four sides, may have a combination of curved and straight sides, or may have other shapes. The illustrative shape of printed circuit boards 4614 in FIG. 55 is merely illustrative.

Printed circuit boards 4614 may be separated from panel 4612 using printed circuit board cutting tools. Cutting techniques that may be used include scoring, milling, drilling, and sawing (as examples).

With one suitable arrangement, grooves are cut around almost the entire periphery of a printed circuit board. To ensure that the printed circuit board does not prematurely detach from the panel, break out tabs are used to temporarily hold the printed circuit boards in place.

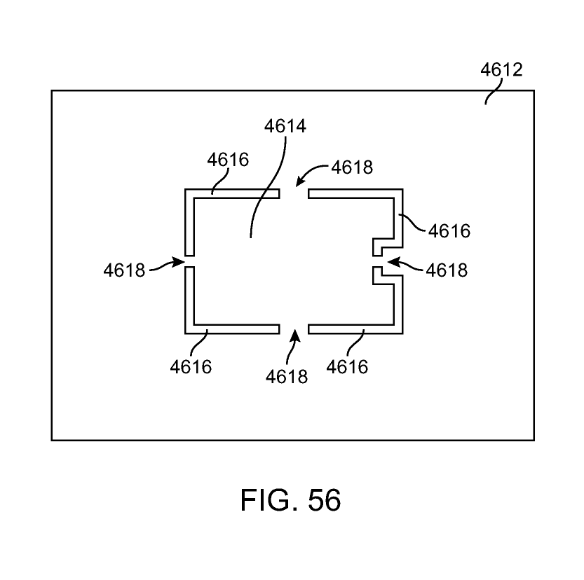

An arrangement of this type is shown in FIG. 56. As shown in FIG. 56, grooves such as grooves 4616 may be formed in printed circuit board panel 4612 around the periphery of printed circuit board 4614. Break out tabs 4618 may be provided along some or all of the edges of printed circuit board 4614 to hold printed circuit board 4614 in place within panel 4612 until printed circuit board processing is complete. Once desired patterning and assembly operations have been completed, tabs 4618 may be broken to release board 4614 from panel 4612.

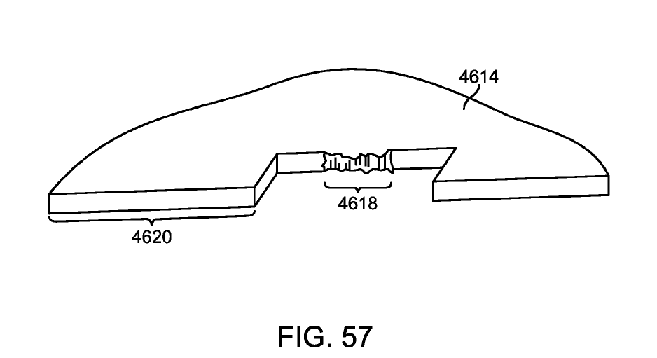

As shown in FIG. 57, the process of breaking tabs 4618 may leave rough edges on printed circuit board 4614. Some of the edges of printed circuit board 4614 such as edge 4620 may be relatively smooth (e.g., due to the use of milling to form grooves 4616). However, the portions of printed circuit board 4614 associated with tabs 4618 may have rough surfaces, because these portions of board 4614 were formed by breaking tabs 4618. During assembly of an electronic device, care should be taken to avoid damaging flex circuits and other structures that might come in contact with jagged printed circuit board edges.

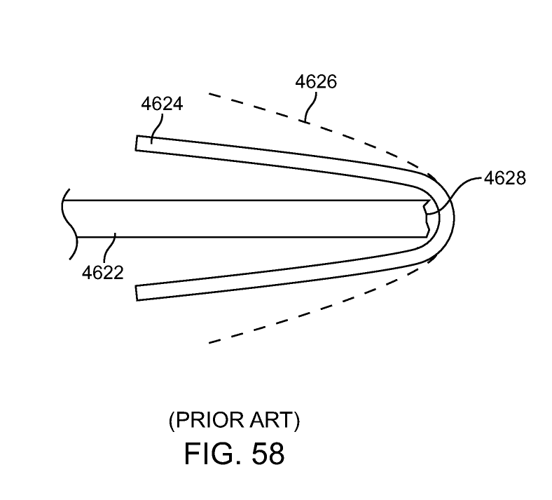

In conventional arrangements, flex circuits can become damaged by the presence of the jagged edges of a printed circuit board. Consider, as an example, the situation of FIG. 58. As shown in FIG. 58, printed circuit board 4622 has rough edges 4628 that were formed when breaking break out tabs to release printed circuit board 4622 from a panel of printed circuit board material. Due to layout constraints, it may be necessary to bend flex circuit 4624 around edge 4628. This brings flex circuit 4624 in close proximity to the rough surface of broken break out tab printed circuit board edge 4628 and raises the risk of damage to flex circuit 4624. Conventional arrangements of the type shown in FIG. 58 also make it difficult to accurately control the placement of flex circuit 4624. Edge 4628 of board 4622 is perpendicular to the front and rear surfaces of board 4622, which creates an abrupt edge profile. Because flex circuit 4624 does not conform to the abrupt edge profile of board 4622, the shape of the flex circuit can be affected by variations in flex circuit tension that can arise from manufacturing variations. This may make it difficult to control the placement of flex circuit 4624.

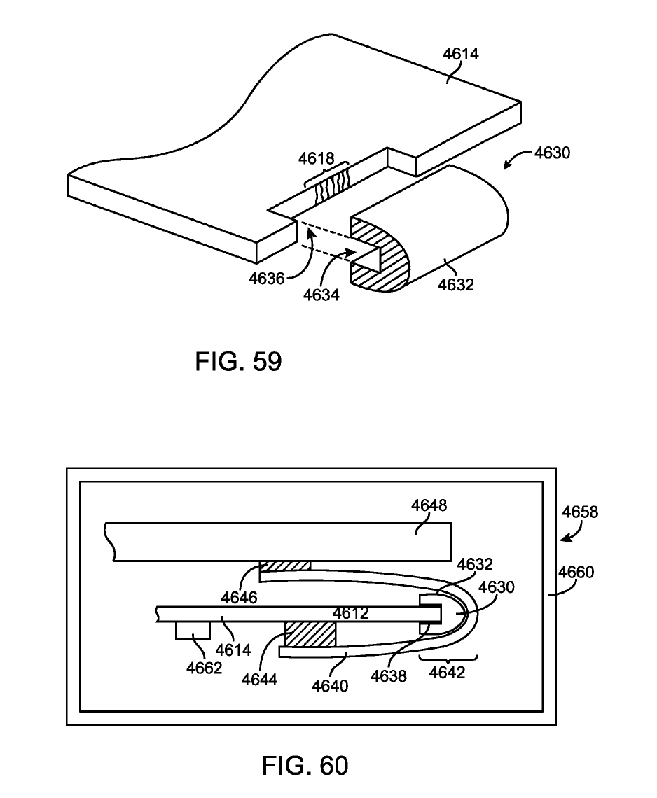

As shown in FIG. 59, the potentially rough edges of printed circuit board 4614 may be covered using a covering member such as member 4630. Member 4630 may be formed from plastic, epoxy, flexible polymers, metal, ceramic, glass, composites, other materials, or combinations of these materials. Member 4630 may be formed from a single-piece structure or may be formed from multiple structures that are attached together. With one suitable arrangement, which is sometimes described herein as an example, member 4630 may be formed from an elastomeric material such as silicone or other pliable substance. Member 4630 may have a curved outer surface of a predetermined size and shape such as surface 4632. Surface 4632 may have the shape of a half cylinder, may have an approximately half-cylindrical shape with a variable radius, or may have other suitable shapes. The shape of member 4630 and therefore exterior surface 4632 may help define the bend radius for a flex circuit that lies on top of surface 4632 when member 4630 is used in an electronic device.

Member 4630 may sometimes be referred to as a bumper or protective structure, because member 4630 may cover rough edges such as the jagged edges associated with broken break out tab portion 4618 of edge 4636. Broken tab portion 4618 may, as shown in the FIG. 59 example, be located in a recessed portion along one of the edges of printed circuit board 4614. Bumper member 4630 may have a groove such as groove 4634 that allows bumper member 4630 to be mounted on the edge of printed circuit board 4614.

Groove 4634 and curved exterior surface 4632 may be formed from portions of bumper 4630 that lie on opposing surfaces of the bumper member. As shown in FIG. 59, for example, groove 4634 may face edge 4618, whereas surface 4632 may lie on the opposing surface of bumper 4630, facing away from edge 4618. Groove 4634 may have a cross-section of a rectangular open-ended slot (i.e., groove 4634 may have a first and second opposing parallel planar sidewalls and a perpendicular planar rear wall). Other shapes may be used for groove 4634 if desired.

In the exploded configuration of FIG. 59, bumper 4630 is not attached to printed circuit board 4614. An illustrative configuration for an electronic device in which bumper 4630 has been mounted to one of the edges of printed circuit board 4614 is shown in FIG. 60.

As shown in FIG. 60, bumper 4630 may be mounted on printed circuit board 4614 using adhesive 4638. If desired, adhesive 4638 may be omitted (e.g., when bumper 4630 is formed from an elastomeric substance such as silicone that has a sticky surface). When bumper 4630 is mounted to printed circuit board 4614 as shown in FIG. 60, bumper 4630 covers jagged edge portion 4618 of board 4614 and creates a surface (surface 4632) that defines the location of structures such as flex cable.

In the FIG. 60 example, printed circuit board 4614 is mounted within housing 4660 of electronic device 4658. Housing 4660 may be formed using a unibody construction or may be formed from multiple structures that are connected together. Materials that may be used in forming sidewalls and other portions of housing 4660 include plastic, metal, composites, glass, ceramic, etc.

Electronic device 4658 may include multiple printed circuit boards and multiple electronic components. In the FIG. 60 example, component 4662 has been mounted to printed circuit board 4614. Components such as component 4662 may include integrated circuits, discrete components, switches, speakers, microphones, input-output port connectors, etc. There may be multiple components such as component 4662 mounted on a given printed circuit board in device 4658. Component 4648 in the example of FIG. 60 may be a printed circuit board to which integrated circuits and other devices have been mounted or may be a display module (e.g., a touch screen display, a liquid crystal display, a plasma display, an electronic ink display, an organic light emitting diode display, etc.).

Flex circuits such as flex circuit 4640 may be used to convey information between the components of device 4658. For example, flex circuit 4640 may be used to convey information between component 4662 on printed circuit board 4614 and component 4648. Flex circuit 4640 may contain metal traces that form a signal bus. The metal traces on flex circuit 4640 may be connected to corresponding metal traces on printed circuit board 4614 using connector 4644. Connector 4646 may be used to interconnect the traces on flex circuit 4640 to traces and other circuitry on component 4648.

When mounting component 4648 and printed circuit board 4614 within device housing 4660, it may be desirable to bend flex circuit 4640. For example, flex circuit 4640 may be bent sufficiently to form a 180° bend of the type shown in FIG. 60. When bent in this way, flex circuit 4640 conforms to surface 4632 of bumper 4630. As a result, the bend radius of flex circuit 4640 in region 4642 is well defined and manufacturing constraints can be satisfied. The presence of bumper 4630 also prevents flex circuit 4640 from bearing against the potentially rough edge of printed circuit board 4614, thereby preventing damage to the traces on flex circuit 4640.

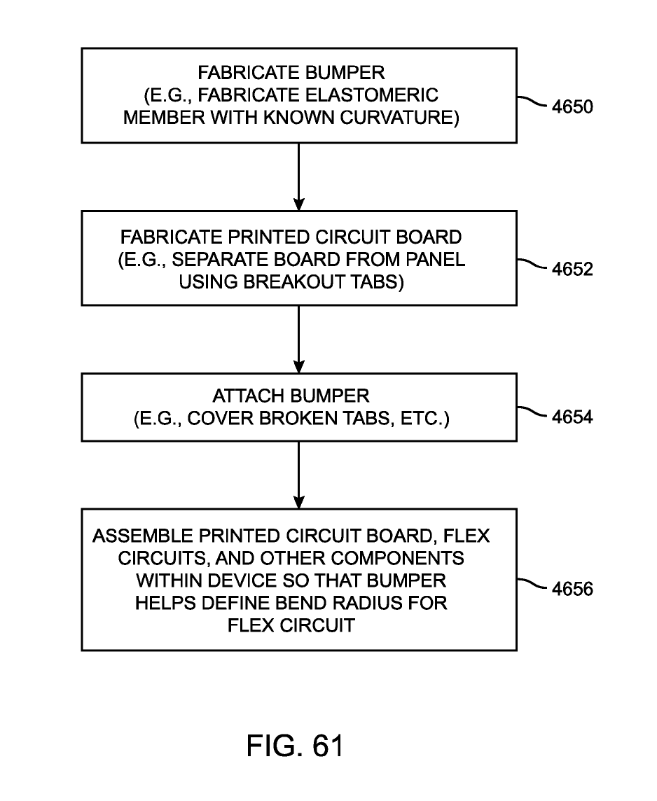

Illustrative steps involved in forming an electronic device such as device 4658 of FIG. 60 that includes a printed circuit board with a bumper are shown in FIG. 61.

At step 4650, bumpers such as bumper 4630 of FIGS. 59 and 60 may be fabricated. For example, an injection molding tool or compression molding tool may be used to form bumpers. The bumpers may have grooves or other openings that allow the bumpers to be mounted along and over an edge of a printed circuit board. The exterior surface of each bumper (i.e., the surface that is exposed when the bumper is mounted on a printed circuit board) may have a defined shape and bend radius to accommodate flex circuit cables and other components in an electronic device.

Bumpers 4630 may be formed from plastic such as polycarbonate (PC), acrylonitrile butadiene styrene (ABS), PC/ABS blends, nylon, polyimide, epoxy, flexible polymers, glass, metal, foam, ceramic, composites (e.g., materials such as fiberglass and carbon fiber composites that include fibers bound together with a resin binder), other materials, and combinations of these materials. With one suitable arrangement, bumpers 4630 are formed from elastomeric materials such as silicone. Elastomeric substances such as silicone may exhibit sticky surfaces that help attach the bumpers to printed circuit boards and may flex somewhat to minimize wear to overlying flex circuits and other cables during use. Bumpers 4630 may have slots that are shaped to mate with the edges of a printed circuit board.

At step 4652, a printed circuit board may be fabricated. For example, a printed circuit board may be separated from a panel of printed circuit board materials. The printed circuit board panel may be, for example, a rigid printed circuit board panel formed from fiberglass-filled epoxy or other suitable printed circuit board panel substrate material. Grooves such as grooves 4616 of FIG. 56 may be formed around the periphery of the printed circuit board using a milling tool, saw, mechanical drill, laser drill, or other equipment. Break out tabs such as break out tabs 4618 of FIG. 56 may be formed at a number of locations around the periphery of the printed circuit board to temporarily hold the printed circuit board in place within the panel while grooves 4616 are formed. When it is desired to release the printed circuit board from the panel (in this type of arrangement), the break out tabs may be broken. If desired, printed circuit board 4614 may be released from panel 4612 using other techniques (e.g., scoring, stamping, etc.).

At step 4654, one or more of the bumpers such as bumper 4630 that were formed at step 4650 may be attached to the printed circuit board. For example, bumper 4630 may be affixed to printed circuit board 14 by placing groove 4634 of bumper 4630 over broken tab portion 4618 of printed circuit board edge 4636 as shown in FIG. 59. The elastomeric nature of and somewhat sticky inner surfaces of groove 4634 may help hold bumper 4630 in place on printed circuit board 4614 or other fastening mechanisms may be used to mount bumper 4630 (e.g., adhesive, screws, retention features on board 4614, springs, clips, or other separate retention features, etc. If desired, multiple bumpers 4630 may be attached to a single printed circuit board 4614 (e.g., to cover some or all of its break out tab edges 4618).

At step 4656, the printed circuit board and its associated bumpers may be assembled inside an electronic device such as device 4658 of FIG. 60. Device 4658 may be, for example, a cellular telephone, a media player, a computer, a tablet or handheld computer, etc. Within device 4658, structures such as flex circuit cable 4640 may be used to interconnect components. For example, flex circuit cables may be used to interconnect a pair of printed circuit boards or may be used to connect a display to a printed circuit board and the integrated circuits on the printed circuit board. In regions of device 4658 where it is necessary for the cable to change directions, the cable may be bent around the exterior surface of the bumper. For example, cable 4640 may be bent around exterior bumper surface 4632 of bumper 4630 in bent region 4642 of cable 4640, as shown in FIG. 60. The presence of bumper 4630 may protect the cable from exposure to rouge portions of the printed circuit board edge. The known shape of surface 4632 may help define the bend radius of the cable and thereby ensure that the cable length and location meet design criteria, even when the tension on the cable fluctuates due to manufacturing variations. Challenges arise in devices such as device 10 of FIG. 1 in connection with mounting camera modules and flash units while dissipating heat and ensuring that the resulting device is aesthetically pleasing.

It would be desirable to be able to provide improved structures for mounting electrical components in electronic devices such as camera and flash components.

In accordance with one embodiment, camera and flash trim structures may be provided that help align camera modules and flash components with respect to each other when mounted within an electronic device (e.g. device 10 of FIG. 1). A trim structure may be formed from materials that dissipate heat, allowing the trim to serve as an integral heat sink.

In accordance with an embodiment, apparatus is provided that includes a heat sink structure, a camera module mounted to the heat sink structure, and a flash unit mounted to the heat sink structure.

In accordance with another embodiment, apparatus is provided wherein the heat sink structure includes a first hole through which light for the camera module passes and a second hole through which light from the flash unit passes.

In accordance with another embodiment, apparatus is provided that also includes a cover glass having a black ink layer with an opening through which the light from the flash unit passes.

In accordance with another embodiment, apparatus is provided wherein the flash unit includes a light-emitting diode that is attached to the heat sink structure with adhesive.

In accordance with these embodiments, an electronic device such as device 10 of FIG. 1 may be provided with a camera and flash. The camera may include a camera module. The camera module may include an image sensor chip that includes an array of image pixels, a lens that focuses images onto the image sensor, and a housing in which components such as the image sensor and lens are mounted. The flash unit may be based on a light emitting diode or other source of light.

The camera module and flash unit may be mounted within the housing of the electronic device. Openings may be formed to allow light for the camera to enter the device and to allow light from the flash to exit the device. A camera module opening may sometimes be referred to as a camera window. A flash unit opening may sometimes be referred to as a flash window.

If desired, a display in the electronic device may have a cover glass layer that is formed from a planar layer of glass, plastic, or other suitable transparent members. In inactive peripheral regions of the display, a layer of black ink or other opaque coating may be provided on the underside of the cover glass. This helps shield internal components in the electronic device from view by the user, thereby improving device aesthetics. In active portions of the display (i.e., portions of the display that contain image pixels for the display), the cover glass is not covered with black ink. This allows a user to view the image on the display through the cover glass. There may be, for example, a rectangular opening in the center of the cover glass that is aligned with a corresponding rectangular array of image pixels in a liquid crystal display. The camera window and flash window may be formed from openings in the black ink layer on the inner surface of the cover glass or may be formed in a housing wall or other suitable portion of an electronic device.

The camera module and the flash unit may be mounted to a common trim (support) structure. The trim structure may be formed from metal parts or parts formed from other materials. These parts may be connected using welds or other fastening techniques to form a unitary trim structure. The trim structure may, for example, be formed from a sheet of metal in which a trim opening for the camera has been formed and a metal member in which a trim opening for the flash unit has been formed. By using the same trim structure to mount and cover both the camera module and the flash unit, the relative spacing between the camera module and the flash unit may be well controlled. When the trim structure is mounted within the electronic device, the trim opening for the camera may be aligned with the camera window in the black ink on the cover glass and the trim opening for the flash unit may be aligned with the flash window in the black ink. In arrangements in which the trim structure is formed from metal, the trim structure may serve as an integral heat sink that helps dissipate heat that is generated by the flash unit during operation.

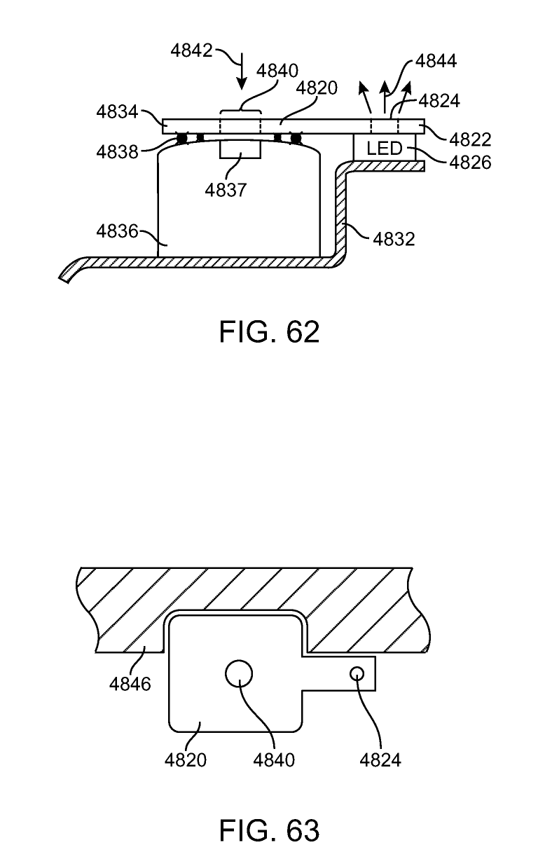

A cross-sectional side view of a trim structure to which a camera module and flash unit have been mounted is shown in FIG. 62.

As shown in FIG. 62, trim structure 4820 may have a camera trim opening such as opening 4840 and a flash unit trim opening such as opening 4824. Camera module 4836 may be mounted to trim structure 4820 using adhesive 4838 or other suitable attachment mechanisms. When mounted, lens 4837 of camera module 4836 may be aligned with opening 4840 in trim structure 4820. In operation, image light 4842 enters camera module through opening 4840 in trim structure 4820 and lens 4837.

Flash unit 4826 may be based on a light-emitting diode or other electronic component that produces light 4844. Flash unit 4826 may be mounted to trim structure 4820 using adhesive, screws, clip, springs, or other fastening mechanisms. When mounted to trim structure 4820, flash unit 4826 may be aligned with opening 4824 so that light 4844 passes through opening 4824 (i.e., to illuminate the subject of a photograph that is being taken using camera module 4836).

Flex circuit 4832 may contain conductive traces that form electrical interconnects for flash unit 4826 and camera module 4836.

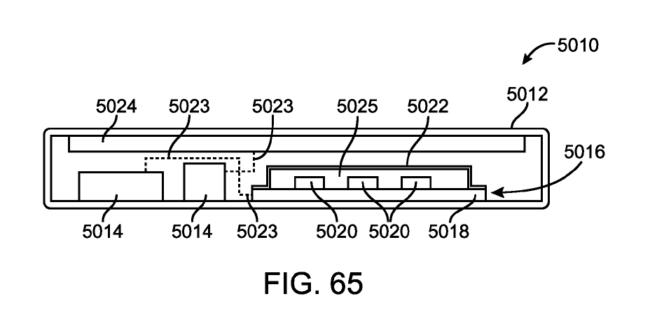

A top view of trim structure 4820 of FIG. 62 is shown in FIG. 65. As shown in FIG. 65, openings 4840 and 4824 may, if desired, have circular shapes. Trim structure 4820 may be mounted within a recess or other alignment structure in internal housing structure 4846 to help align trim structure 4820, camera module 4836, and flash unit 4826 relative to the electronic device in which trim structure 4820 is mounted and thereby help align the camera module and flash relative to the camera and flash windows in the cover glass.

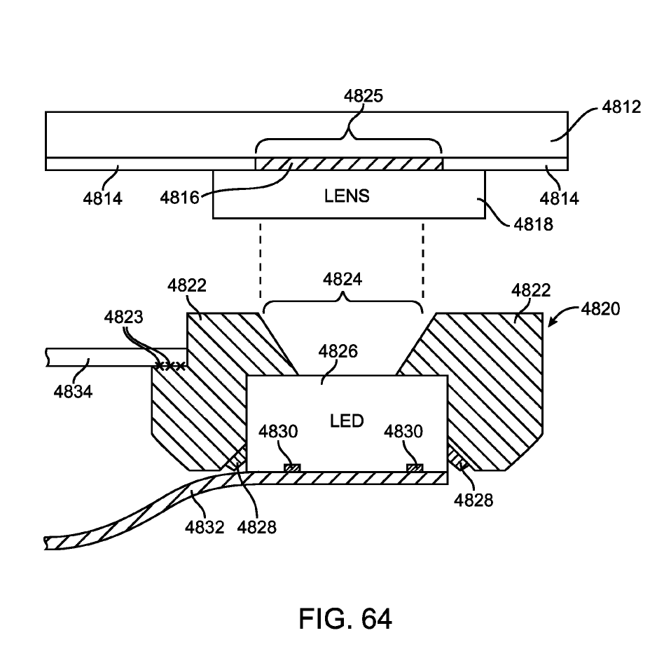

A cross-sectional side view of a portion of the electronic device in which trim structure 4820 is mounted is shown in FIG. 64. As shown in FIG. 64, trim structure 4820 may include a thin metal sheet such as sheet 4834 (which contains opening 4840 of FIG. 65) and a thicker metal heat sink structure such as structure 4822. Structure 4834 may be, for example, a planar stainless steel member having a thickness of about 0.1 to 0.2 mm. Heat sink structure 4822 may be formed from a metal such as stainless steel. Heat sink structure 4822 may be connected to metal sheet 4834 using welds 4823 or other suitable attachments mechanisms. Heat sink structure 4822 of trim 4820 may have an opening (trim opening 4824) that is aligned with lens 4818. Lens 4818 may be used to collimate light emitted from flash unit 4826. Lens 4812 may be aligned with opening 4825 in black ink layer 4814 on cover glass 4812. Optical adhesive 4816 may be used to attach lens 4818 to cover glass 4812.

Flash unit 4826 may be mounted within a recessed portion of heat sink structure 4822. Adhesive 4828 or other suitable attachment mechanisms may be used to attach flash unit 4826 to heat sink structure 4822. Power for operating flash unit 4826 may be routed to flash unit 4826 using traces on flexible printed circuit 4832 that are coupled to power terminals 4830 on flash unit 4826.

Heat may be produced during operation of flash unit 4826, particularly when flash unit 4826 is operated in a continuous (“torch”) mode. The heat that is produced is dissipated through heat sink structure 4822 and other metal structures of trim structure 4840. The relatively large surface area of metal sheet 4834 may help to dissipate heat into the air surrounding trim structure 4822. Because both portion 4834 and portion 4822 contribute to the heat dissipating qualities of trim structure 4820, portions 4834 and 4822 are sometimes collectively referred to as a “heat sink” or “heat sink structure.”

Integrated circuits and other electrical components are often packaged in radio-frequency shielding cans. During operation, the electrical components generate heat. To ensure that the components do not overheat, thermally conductive foam pads and thermal grease may be placed between the upper surfaces of the electrical components and the inner surface of the shielding can. The thermally conductive foam pads are compressed between electrical components and the can. Heat that is generated in the components can flow through the compressed pads and can be dissipated through the can.

Conventional shielding arrangements such as these are sometimes acceptable when manufacturing tolerances are relatively loose. In situations in which tolerances are tight and in which good thermal conduction attributes are required, enhanced shielding structures may be required.

It would therefore be desirable to be able to provide improved techniques for packaging electrical components in structures such as radio-frequency shielding cans while providing satisfactory heat dissipation capabilities.

In accordance with one embodiment, electrical components such as radio-frequency power amplifiers and other radio-frequency integrated circuits may be provided that are mounted to a substrate such as a printed circuit board of an electronic device (e.g., device 10 of FIG. 1). For example, electrical components may be soldered to a rigid or flexible printed circuit board. Frame structures that serve as attachment points for subsequent radio-frequency shield mounting may also be soldered to the printed circuit board substrate.

The electrical components may have different shapes and sizes. As a result, the electrical components and the surface of the printed circuit board may give rise to an irregular surface with components of various heights.

To ensure adequate thermal dissipation, a conformal coating of a thermally conductive filler such as silicone filled with thermally conductive particles may be deposited. The conformal coating may cover all of the exposed electrical components and may smoothly conform to the irregular surface of the components.

Radio-frequency shielding such as a metal radio-frequency shield can may be mounted over the electrical components to shield the components and prevent radio-frequency interference. The radio-frequency shielding may be formed by attaching a radio-frequency can lid to the frame structures that are mounted on the substrate.

The thermally conductive filler may be formed from one or more materials. For example, a first shot of material may be used to cover a given set of the electrical component and a second shot of material may be used to cover the remaining electrical components and the first shot. The thermally conductive filler may be dispensed in a fluid state and cured using heat or light. Once cured, the thermally conductive filler may solidify. Solidified filler may be elastomeric (e.g., an elastomeric material with ceramic particles or other mixtures of materials) or may be rigid. Because the filler completely fills the shield cavity, heat is dissipated rapidly from the electrical components to the shield lid. In the event that rework or repair is required, the filler can be removed from the cavity. A battery powered electronic device may use shielded circuitry that includes a conformal thermally conductive filler.

This relates generally to packaging of electrical components, and, more particularly, to packaging of electrical components in a package such as a radio-frequency can using thermally conductive materials.

According to an embodiment, shielded circuitry is provided that includes a substrate, a plurality of electrical components mounted on the substrate, a radio-frequency shield that is attached to the substrate and that covers the plurality of electrical components, wherein a cavity is formed between an inner surface of the radio-frequency shield and the electrical components and portions of the substrate, and thermally conductive filler that substantially fills the cavity.

According to another embodiment, shielded circuitry is provided wherein the electrical components have surfaces at different heights above the substrate that form surface irregularities and wherein the thermally conductive filler conforms to the surface irregularities.

According to another embodiment, shielded circuitry is provided wherein the substrate includes a printed circuit board.

According to another embodiment, shielded circuitry is provided wherein the electrical components include an integrated circuit.

According to another embodiment, shielded circuitry is provided wherein the electrical components includes radio-frequency integrated circuits.

According to another embodiment, shielded circuitry is provided wherein the electrical components include at least one radio-frequency power amplifier.

According to another embodiment, shielded circuitry is provided wherein the thermally conductive filler includes silicone.

According to another embodiment, shielded circuitry is provided wherein the thermally conductive filler includes an elastomeric material containing particles of ceramic.

According to another embodiment, shielded circuitry is provided wherein the thermally conductive filler includes an elastomeric material containing particles of material.

According to another embodiment, shielded circuitry is provided wherein the radio-frequency shield includes a metal radio-frequency shield can lid.

According to an embodiment, a method of forming shielded circuitry is provided that includes mounting a plurality of electrical components on a region of a substrate, conformally covering all of the electrical components and the region of the substrate with a thermally conductive filler, and encasing the filler and the conformally covered electrical components with a radio-frequency shielding structure.

According to another embodiment, a method is provided wherein the radio-frequency shielding structure includes a can lid, wherein a cavity region is defined between the can lid and the electrical components and the region of the substrate, and wherein the thermally conductive filler fills substantially all of the cavity region.

According to another embodiment, a method is provided wherein encasing the filler and the conformally covered electrical components includes dispensing the filler in fluid form.

According to another embodiment, a method is provided wherein encasing the filler and the conformally covered electrical components includes solidifying the filler that has been dispensed in fluid form to create solid thermally conductive filler.

According to another embodiment, a method is provided wherein solidifying the filler includes solidifying at least two different types of thermally conductive material to form the solid thermally conductive filler.

According to an embodiment, an electronic device is provided that includes a housing having an interior, a battery in the interior, a plurality of radio-frequency integrated circuits mounted to a substrate that are powered by the battery, a radio-frequency shield mounted to the substrate and that defines a cavity region, and thermally conductive filler that fills substantially all of the cavity region, that covers at least part of the substrate, and that conformally covers the radio-frequency integrated circuits.

According to another embodiment, an electronic device is provided wherein the radio-frequency integrated circuits include at least one radio-frequency power amplifier.

According to another embodiment, an electronic device is provided wherein the thermally conductive filler includes silicone.

According to another embodiment, an electronic device is provided wherein the thermally conductive filler includes an elastomeric material.

According to another embodiment, an electronic device is provided that also includes ceramic particles in the elastomeric material.

In accordance with these embodiments, electronic devices such as computers, cellular telephones, media players, and other equipment may be provided with numerous electronic components. Electronic components that are used in electronic devices include integrated circuits such as radio-frequency power amplifiers, radio-frequency transceivers, processors, audio and video circuits, memory chips, hard drives, discrete components such as resistors, capacitors, and inductors, communications circuits, etc. These electrical components are often electrically and mechanically interconnected using printed circuits boards. Rigid printed circuit boards such as printed circuit boards formed from fiberglass-filled epoxy and other rigid substrates and flexible printed circuit boards (“flex circuits”) formed from flexible polymer substrates such as sheets of polyimide may be used.

In devices where radio-frequency interference is a concern, radio-frequency shielding is sometimes used to enclose electrical components. For example, components that are sensitive to external radio-frequency signals or components that emit radio-frequency signals that might interfere with other components be mounted on a printed circuit board and covered with a conductive radio-frequency shielding can.

The presence of the shielding can helps to mitigate radio-frequency interference, but can trap air. The trapped air, in turn, can serve as a thermal insulator. This can make it difficult to remove heat properly from electrical components within the shielding can. Thermally conductive foam is sometimes used in conventional shielding cans to help dissipate heat. This type of approach may not, however, be satisfactory in environments with tight mechanical and thermal tolerances.

To enhance thermal performance, particularly in component packages that might contain radio-frequency shielding, one or more layers of conformal thermally conductive material may be formed over electrical components within a package. This type of approach may be used for radio-frequency shielding structures in electronic devices such as computers, cellular telephones, media players, and other electronic equipment.

A cross-sectional side view of an illustrative electronic device that may contain a radio-frequency shielding structure with conformal thermally conductive material layers is shown in FIG. 65. The electronic device of FIG. 65 may be, for example, a cellular telephone, a portable or desktop computer, a gaming device, a navigation device, a tablet computer, a wristwatch or pendant device, a media player, embedded equipment in a house or other environment, or any other suitable electronic equipment. As shown in FIG. 65, electronic device 10 may have a housing such as housing 5012. Housing 5012 may be formed from one or more different materials such as plastic, metal, ceramic, glass, etc. For example, housing 5012 may be formed from metal and plastic internal frame members covered with a plastic or metal shell having relatively thin housing walls. As another example, housing 5012 may be formed from a one or more relatively larger pieces of material (e.g., one or two mating machined metal housing structures, one or two molded or machined plastic structures, etc.). Combinations of these arrangements may also be used.

A display such as a touch screen display (e.g., display 5024) may be mounted on one surface of housing 5012 (e.g., below an opening in an upper planar surface of housing 5012). Device 10 may also contain buttons, microphone and speaker ports, input-output connectors for data ports and other signals, and other user interface and input-output circuitry. Processing and storage circuitry in device 10 may be based on memory chips, hard drives, volatile and nonvolatile memory, microcontrollers, microprocessors, custom processors, application-specific integrated circuits, etc. Electrical components such as these are depicted as components 5014, 5020, and 5024 in the example of FIG. 65.

Components 5014, 5020, and 5024 may include integrated circuits, discrete components (e.g., resistors, capacitors, inductors, individual transistors, individual switches and buttons), antennas, batteries, components that are packaged using surface mount technology (SMT) packages, etc. These components may be interconnected using printed circuit board traces, coaxial cables and other transmission lines, wires, flex circuit busses, and other conductive paths (shown as paths 5023 in FIG. 65). During operation, electrical components 5014, 5020, and 5024 may be powered by an external power supply or an internal battery (e.g., a battery among one of components 5014).

Active components tend to generate heat. For example, radio-frequency components such as power amplifiers and other integrated circuits may become hot to the touch. Unless care is taken, excess heat may adversely affect performance.

Radio-frequency shielding may be used to isolate some of the components in device 10. In the example of FIG. 65, radio-frequency shielding structure 5016 has been formed by placing a radio-frequency shield (metal can 5022) over components 5020 on printed circuit board 5018. Printed circuit board 5018 may contain a conductive ground plane on its rear surface that serves as radio-frequency shielding for the underside of structure 5016. Metal can 5022 can serve as radio-frequency shielding for the topside of structure 5016.

Components 5020 may, as an example, include radio-frequency components such as radio-frequency transceiver circuits, radio-frequency power amplifiers, or other circuitry that generates and/or is sensitive to radio-frequency shielding. Radio-frequency shielding structure 5016 (e.g., metal can 5022), helps prevent radio-frequency signals from within structure 5016 from adversely affecting electrical components in device 10 and helps prevent radio-frequency interference from adversely affecting the operation of components 5020 within radio-frequency shielding structure 5016.

To remove excess heat from components 5020, components 5020 may be covered with one or more conformal layers of thermally conductive material. The thermally conductive material may fill substantially all of the interior portion of structures 5016 (i.e., all of region 5025 in FIG. 65). Conformal thermally conductive materials may remove heat more effectively and may be more suitable for manufacturing with tight tolerances than conventional radio-frequency shielding cans.

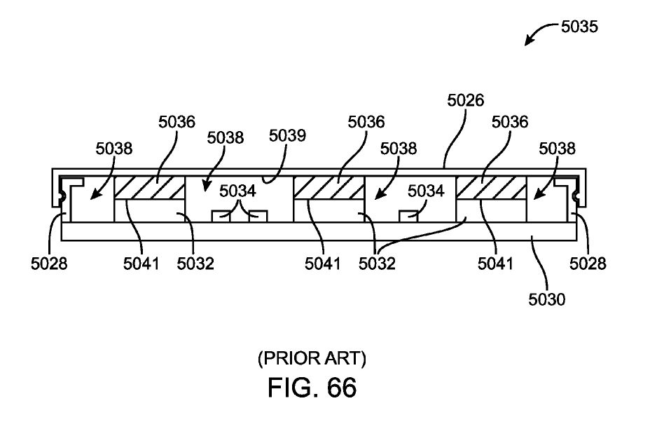

A cross-sectional side view of a conventional radio-frequency shielding arrangement is shown in FIG. 66. As shown in FIG. 66, radio-frequency shielding structure 5035 includes a rigid printed circuit board substrate 5030 on which electrical components such as integrated circuits 5032 and other electrical components 5034 are mounted. Electrical components 5032 are covered with thermally conductive foam 5036. Thermal grease may also be used. Foam 5036 is compressed between inner surface 5039 of metal radio-frequency can 5026 and respective top component surfaces 5041 when can 5026 is mounted on frame 5028. In this configuration, heat that is produced by components 5032 may be conveyed through foam 5036 to radio-frequency shielding can 5026. The remainder of the interior of structure 5035 such as region 5038 is generally filled with air. Air has insulating properties, so the presence of air in structure 5035 may retard the removal of heat. The use of multiple foam pads 5036 to fill the gaps between components 5032 and inner can surface 5039 may also impose thickness tolerance requirements on foam pads 5036 that are difficult to satisfy in a production environment.

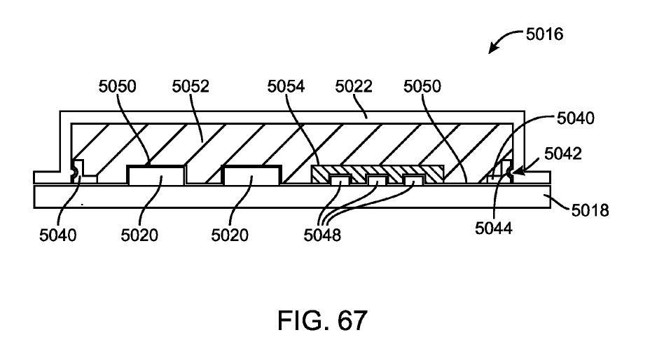

A cross-sectional side view of an illustrative radio-frequency shielding structure of the type that may be used as structure 5016 of FIG. 65 is shown in FIG. 67. As shown in FIG. 67, radio-frequency shielding structure 5016 may include a radio-frequency shield such as radio-frequency shielding can 5022 or other radio-frequency shield or packaging structure. Components 5020 may be mounted on substrate 5018. Components 5020 on substrate 5018 may be enclosed within structure 5016 using structure 5022.

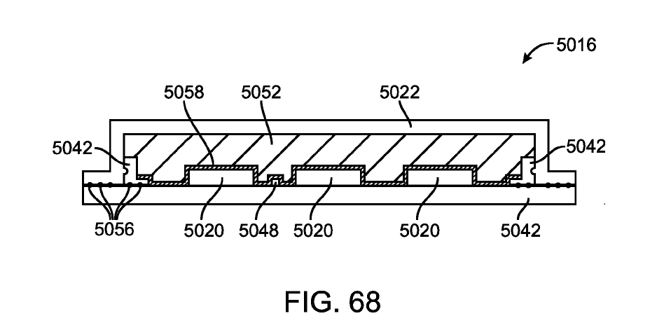

Arrangements in which structure 5022 is a radio-frequency shielding can (or a cover for such a can) are sometimes described herein as an example. Substrate 5018 and components 5020 may, if desired, be enclosed in other shielding or packaging structures. For example, a radio-frequency shield may be formed from mating upper and lower shielding structures that are attached together to form a can. Radio-frequency signals may also be blocked by one or more metal ground plane layers in substrate 5018. Illustrative arrangements that include a single can such as can 5022 and that use ground structures in substrate 5018 to provide lower-surface shielding are sometimes described herein as an example. In general, any suitable radio-frequency shield structures or other packaging structures may be used in packaging components 5020. The arrangement of FIG. 68 is merely an example.

Substrate 5018 may be formed from rigid printed circuit materials such as fiberglass-filled epoxy, flexible printed circuit (“flex circuit”) materials such as polyimide or other thin polymer sheets, glass, plastic, ceramics, or other suitable substrate materials. Conductive traces or other signal interconnect lines may be formed in and on substrate 5018. Components 5020 may be mounted to substrate 5018 using solder (e.g., solder-bumps in a flip-chip mounting structure), clips, springs, connectors, or other suitable attachment mechanisms.

Structures 5040 may be connected to the surface of substrate 5018 to facilitate mounting of shielding can 5022. Structures 5040 may be, for example, metal frame structures with detents such as detent 5044 or other engagement features to which mating protrusions such as protrusion 5042 of radio-frequency shielding can 5022 or other radio-frequency shielding structures may be mounted. Structures 5040 may be attached to substrate 5046 using solder (e.g., solder 5056 of FIG. 68), adhesive, screws or other fasteners, or other suitable mounting arrangements.

An optional layer of thermal grease such as thermal grease 5050 may be used to cover the surface of substrate 5018 and the electrical components that are mounted on substrate 5018 such as components 5020 and 5048.

One or more layers of thermally conductive material may be formed over components 5020 and 5048. This conductive material may fill substantially the entire interior of radio-frequency shielding can 5022 (i.e., the interior of radio-frequency shielding structure 5016). By using a malleable material that is, at least initially, flexible and compliant enough to smoothly conform to the uneven contours of the top and sidewall surfaces of components 5020 and 5048, good thermal conductivity may be maintained. Use of thermally conductive material that conforms to the uneven heights and shapes of components 5020 and 5048 also may facilitate the process of meeting tight tolerances during manufacturing. With conventional arrangements of the type shown in FIG. 66, for example, differences in the properties of foam pieces 5036 may lead to unevenness within structure 5035. By using one or more layers of thermally conductive material that conforms to the shapes of components 5020 and 5048, this source of unevenness within the radio-frequency shield may be reduced or eliminated.

Any suitable number of layers of thermally conductive material may be used in covering components 5020 and 5048. For example, a single layer of material may be used. If desired, two layers of material with different properties may be used or three or more different materials may be used to fill substantially all of the cavity under shield can 5022. In the example of FIG. 67, there are two different thermally conductive materials in the cavity under can 5022 in addition to optional thermal grease layer 5050. Thermally conductive structure 5054 may be formed from a first thermally conductive material. Thermally conductive structure 5052 may be formed from a second material that is different than the material of structure 5054.

The materials that are used for layer 5050, structure 5054, and structure 5052 may help form a thermally conductive path between components 5020 and 5048 and radio-frequency shielding can 5022. Can 5022 may be surrounded by air or other suitable media and may dissipate heat into the environment. By ensuring good thermal conduction within the interior of structure 5016, components 5020 and 5048 may be cooled satisfactorily.

Structures such as structures 5052 and 5054 may be formed from a material that is malleable enough to conform to the surface shapes of components 5020 and 5048. Thermally conductive material for filling the cavity under shield 5022 may sometimes be referred to herein as filler or thermally conductive filler. One or more different materials may be used as conformal filler. With one suitable arrangement, the filler is formed from a material that is initially a fluid and that solidifies following curing. In its fluid state, the filler may be a runny liquid or may be more viscous. For example, the filler may be implemented using a thick paste or may be implemented using a material that has a moderate viscosity. Curing may be performed by applying heat, by waiting a sufficient amount of time at room temperature (chemical curing), by applying ultraviolet light or other light, or using other suitable curing techniques. Once cured, the filler may transition from a relatively soft or running fluid state into a more viscous fluid or a soft or hard solid.

The filler may contain one or more materials that are dielectrics (insulators). For example, a layer of dielectric may be included as a lower layer (e.g., on top of a thermal grease layer) to ensure that input-output pins on components 5020 and 5048 and exposed traces on substrate 5018 are not electrically shorted. Subsequent layers may be conductive or may be insulating. For example, subsequent layers may contain a mixture of dielectric and conductive particles that has a finite conductivity or that is insulting.

To ensure sufficient thermal conductivity, particularly when the filler is insulating (or at least exhibiting low conductivity), the filler may be formed from a mixture of materials. For example, the filler may be formed from a dielectric binder material in which particles with high thermal conductivity are embedded. The particles may be formed from metal, nanostructures, fibers, or other suitable structures or materials. The binder may be a resin, an elastomeric polymer, etc.

Examples of materials that may be used as filler include epoxy (e.g., ultraviolet-light-cured epoxy, two-part epoxy, thermally-cured epoxy, etc.), elastomeric (rubber-like) polymers such as silicone, thermoplastics, ceramics, glass, metallic compounds, polyimide, etc. As an example, the filler may be formed from silicone into which metal particles, particles of alumina silicate or other ceramics, or other materials have been incorporated to enhance thermal conductivity. The thermal conductivity of the filer may be, for example, greater than 10³ W/m²° C., 10⁴ W/m²° C., 10³ W/m²° C., etc.

To facilitate rework, it may be desirable to select a material for the filler that can be removed from components 5020 and 5048 without damaging components 5020 and 5048. Consider, for example, the formation of the conformal thermally conductive structures over components 5020 and 5048 using metal-filled or ceramic-filled silicone. Initially, a layer of silicone in its fluid state may be deposited over components 5020 and 5048. Following curing, the silicone will form a solid elastomeric layer over components 5020 and 5048. If rework or repair is required, a technician may peel off the layer of silicone from the surfaces of components 5020 and 5048. Use of a layer of thermal grease such as grease 5050 may facilitate the release of the silicone structure from the surfaces of components 5020 and 5048. Thermal grease 5050, which is also sometimes referred to as thermal paste or heat sink compound, may be formed from a ceramic-based material, metal-based material, or mixtures based on carbon powder or carbon fibers, or other suitable materials.

In situations in which particular parts require more or less thermal conductivity, it may be desirable to form the thermally conductive structures from different types of material. For example, if components 5048 of FIG. 67 generate relatively large amounts of heat, structure 5054 may be formed from a material that has a higher thermal conductivity than material 5052 to facilitate heat dissipation.

Thermally conductive structures may also be formed from materials that have different physical properties (e.g., different elasticities, different hardnesses, etc.). As an example, if components 5020 have intricate or delicate surface features, it may be desirable to cover these components with a material (e.g., material 5052) that is softer and more elastic than other filler materials (e.g., material 5054).

FIG. 68 shows an illustrative arrangement that may be used for radio-frequency shielding structure 5016 in which a base layer (layer 5058) of thermally conductive material is used to cover components 5020 and 5048. This base layer may then be covered with a covering layer such as layer 5052. Layer 5058 may be formed from a material with one set of properties (i.e., sufficient elasticity to release satisfactorily from components 5020 and 5048 during rework while exhibiting average or below average thermal conductivity and superior electrical insulation), whereas layer 5052 may be formed from a material with a different set of properties (i.e., superior thermal conductivity). Conformal thermally conductive structures may also be formed using three or more layers of material (e.g., three or more “shots” of silicone or other polymers or materials).

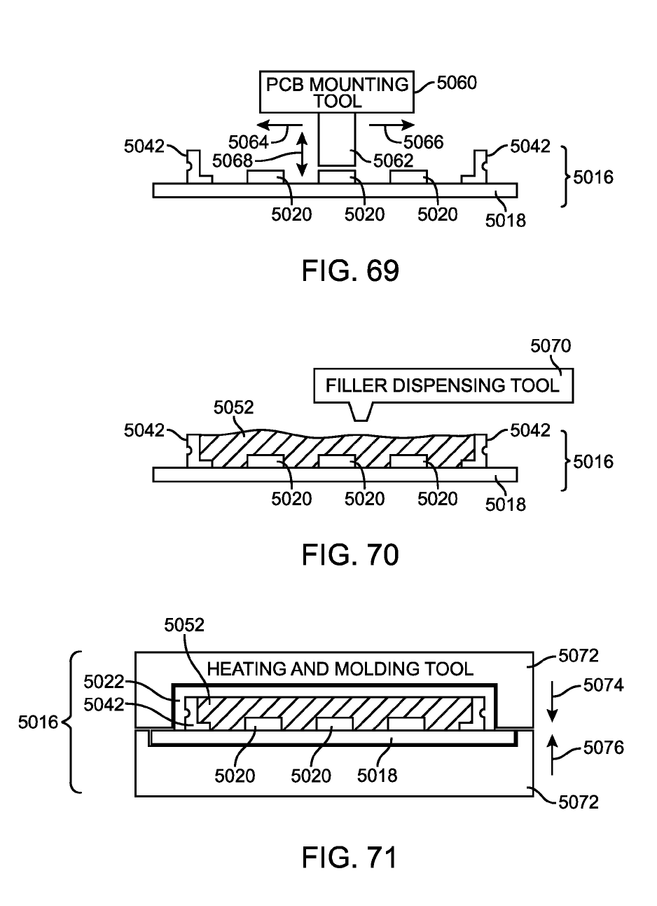

Illustrative tools and techniques that may be used in forming radio-frequency shielding structures with conformal thermally conductive filler are shown in FIGS. 69, 70, and 71.

In FIG. 69, structures 5016 are shown in an early phase of fabrication. A component mounting tool such as printed circuit board mounting tool 5060 is being used to mount components 5020 on printed circuit board 5018. Component mounting tool 5060 of FIG. 69 may have actuators that move mounting head 5062 in lateral directions 5060 and 5064 and in vertical direction 5068. Solder, conductive adhesive, fasteners, connectors, or other suitable arrangements may be used by mounting tool 5060 to electrically and mechanically connect electrical components 5020 to the surface of printed circuit board 5018. As shown in FIG. 69, tool 5060 may also mount structures such as structures 5042 to printed circuit board 5018 (e.g., to serve as frame structures that receive mating structures such as radio-frequency shielding can 5022).

After components 5020 have been mounted on printed circuit board 5018, filler may be used to cover components 5020 and printed circuit board 5018, as shown in FIG. 70. One or more filler materials may be dispensed using filler dispensing tool 5070. Tool 5070 may use injection molding techniques, spraying, dripping, dipping, or other suitable techniques to dispense filler materials onto printed circuit board 5018. As shown in FIG. 70, substantially all of the surface of board 5018 and the components on board 5018 are coated with filler 5052. The filler may be dispensed using one or more different materials (e.g., in one or more shots).

Optional heat and light curing operations may be performed after each different material has been deposited or after two or more materials have been deposited. For example, a heat cure operation may be performed after each deposition of filler material (as an example). One or more layers of thermal grease may also be deposited.

As shown in FIG. 71, a heating and molding tool such a tool 5072 may be used in performing heat curing operations. In particular, heating elements in tool 5072 may be used to heat the filler and thereby thermally cure the filler. Tool 5072 may also be used in attaching radio-frequency shielding lid 5022 on frame members 5042 (e.g., by press fitting lid 5022 to frame members 5042). For example, tool 5072 may have an upper portion and a lower portion. When the upper portion is moved in direction 5074 and the lower portion is moved in direction 5076, radio-frequency shielding lid 5022 may be pressed onto frame structure 5042. The filler may also be compressed within the cavity formed in radio-frequency shielding structures under shielding lid (can) 5022. This compression of the filler may help to remove air pockets and thereby ensure that the filler conforms to the entire exposed surface of components 5020 and printed circuit board 5018 within shield 5022. If desired, compression molding tools such a tool 5072 may be used at the same time as filler dispensing tool 5070 of FIG. 70 (e.g., to compress filler as the filler is being injected within the shield cavity or just after the filler has been injected).

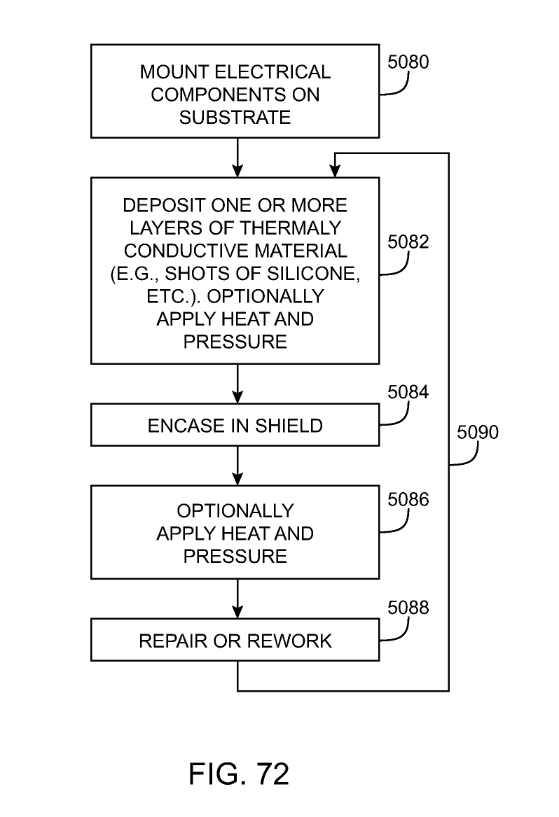

Illustrative steps involved in forming a radio-frequency shielding structure such as structure 5016 that includes thermally conductive conformal filler are shown in FIG. 72.

At step S080, electrical components such as integrated circuits and discrete components may be mounted on a substrate. The substrate may be, for example, a printed circuit board substrate. Frame members or other mounting structures may also be mounted to the substrate to facilitate subsequent attachment of a radio-frequency shielding can.

At step S082, one or more filler materials may be formed on the substrate. Filler may be formed from thermally conductive dielectrics and other materials that are thermally conductive. If desired, at least one of the filler layers may be electrically insulating (e.g., the lowermost layer such as layer 5058 of FIG. 68), to help prevent inadvertent short circuits between electrical conductors in the finished package. As each different filler material is deposited, an optional curing operation may be performed by exposing the workpiece to light and/or heat.

At step S084, radio-frequency shield 5022 (e.g., a metal can lid) may be attached to frame 5042 (FIG. 71) or other suitable radio-frequency shielding structure (e.g., a two-piece shield) may be formed surrounding substrate 5018 and the components and filler.

At step S086, optional heat and pressure may be applied to the workpiece to ensure that the filler is conforming to substantially all of the exposed surfaces within the interior of the shield and to ensure that the filler material cures and solidifies.

At step S088, optional rework or repair operations may be performed by removing the filler. For example, when the filler is formed from an elastomeric material, a technician may peel away all of the solidified elastomeric filler to expose the underlying electrical components and circuit board for repair. Once the repair has been made, operations may return to step S082, as indicated by line 5090.

The foregoing is merely illustrative of the principles of this invention and various modifications can be made by those skilled in the art without departing from the scope and spirit of the invention.

What is claimed is:

1. Shielded circuitry, comprising:
a substrate;
a plurality of electrical components mounted on the substrate;
a radio-frequency shield that is attached to the substrate and that covers the plurality of electrical components, wherein a cavity is formed between an inner surface of the radio-frequency shield and the electrical components and portions of the substrate; and
thermally conductive filler that substantially fills the cavity.

2. The shielded circuitry defined in claim 1 wherein the electrical components have surfaces at different heights above the substrate that form surface irregularities and wherein the thermally conductive filler conforms to the surface irregularities.

3. The shielded circuitry defined in claim 1 wherein the substrate comprises a printed circuit board.

4. The shielded circuitry defined in claim 1 wherein the electrical components include an integrated circuit.

5. The shielded circuitry defined in claim 1 wherein the electrical components comprises radio-frequency integrated circuits.

6. The shielded circuitry defined in claim 1 wherein the electrical components include at least one radio-frequency power amplifier.

7. The shielded circuitry defined in claim 1 wherein the thermally conductive filler comprises silicone.

8. The shielded circuitry defined in claim 1 wherein the thermally conductive filler comprises an elastomeric material containing particles of ceramic.

9. The shielded circuitry defined in claim 1 wherein the thermally conductive filler comprises an elastomeric material containing particles of material.

10. The shielded circuitry defined in claim 1 wherein the radio-frequency shield comprises a metal radio-frequency shield can lid.

11. An apparatus, comprising:
a printed circuit board;
at least one electrical component mounted to the printed circuit board;
a radio-frequency shielding structure that is attached to the printed circuit board and that covers the at least one electrical component; and
thermally conductive material that is interposed between the radio-frequency shielding structure and the at least one electrical component, wherein the thermally conductive material is formed from a malleable material that conforms to the shape of the at least one electrical component, and wherein the thermally conductive material forms a thermally conductive path between the at least one electrical component and the radio-frequency shielding structure.

12. The apparatus defined in claim 11 wherein the at least one electrical component comprises a radio-frequency integrated circuit.

13. The apparatus defined in claim 11 wherein at least one electrical component includes at least one radio-frequency power amplifier.

14. The apparatus defined in claim 11 wherein the thermally conductive material comprises silicone.

15. The apparatus defined in claim 11 wherein the thermally conductive material comprises an elastomeric material containing particles of ceramic.

16. The apparatus defined in claim 11 wherein the thermally conductive material comprises an elastomeric material containing particles of material.

17. The apparatus defined in claim 11 further comprising a frame mounted on the printed circuit board, wherein the radio-frequency shielding structure is coupled to the frame.

18. An apparatus, comprising:
a substrate;
a plurality of electrical components mounted on the substrate;
a metal radio-frequency shield can that is attached to the substrate and that covers the plurality of electrical components; and
thermally conductive filler that is interposed between the metal radio-frequency shield can and the plurality of electrical components, wherein the thermally conductive filler forms a thermally conductive path between the plurality of electrical components and the metal radio-frequency shield can.

19. The apparatus defined in claim 18 wherein the plurality of electrical components have surfaces at different heights above the substrate that form surface irregularities and wherein the thermally conductive filler conforms to the surface irregularities.

20. The apparatus defined in claim 19, wherein the thermally conductive filler comprises an elastomeric material.
